(19) United States
(12) Patent Application Publication
(10) Pub. No.: US 2016/0064226 A1
(43) Pub. Date: Mar. 3, 2016

(54) METHOD OF MANUFACTURING SEMICONDUCTOR DEVICE

(71) Applicant: Renesas Electronics Corporation, Tokyo (JP)

(72) Inventors: Yoshiyuki Kawashima, Tokyo (JP); Hiraku Chakihara, Tokyo (JP); Akio Nishida, Tokyo (JP)

(73) Assignee: Renesas Electronics Corporation

(21) Appl. No.: 14/829,614

(22) Filed: Aug. 18, 2015

(30) Foreign Application Priority Data
Aug. 28, 2014 (JP) 2014-174630

(51) Int. Cl. H01L 21/28; H01L 27/115

(52) U.S. Cl. CPC H01L 21/28282; H01L 21/28008; H01L 27/11568

(57) ABSTRACT

Improvements are achieved in the properties of a semiconductor device including a MISFET and a nonvolatile memory. Over a gate electrode included in the MISFET and a control gate electrode and a memory gate electrode each included in a memory cell, a stress application film is formed of a silicon nitride film. Then, by removing the silicon nitride film from over the control gate electrode and the memory gate electrode, an opening is formed over the control gate electrode and the memory gate electrode. Then, in a state where the opening is formed in the silicon nitride film, heat treatment is performed to apply a stress to the MISFET. By thus removing the stress application film (silicon nitride film) from over the memory cell, it is possible to avoid the degradation of the properties of the memory cell due to H (hydrogen) in the silicon nitride film.

### CROSS-REFERENCE TO RELATED APPLICATIONS

The disclosure of Japanese Patent Application No. 2014-174630 filed on Aug. 28, 2014 including the specification, drawings and abstract is incorporated herein by reference in its entirety.

### BACKGROUND

The present invention relates to a method of manufacturing a semiconductor device and can be used appropriately as a method of manufacturing a semiconductor device including, e.g., a nonvolatile memory cell, and a MISFET.

The manufacturing process of a semiconductor device including a nonvolatile memory cell, and a MISFET includes the step of forming a silicon nitride film and a heat treatment step.

For instance, an SMT step which applies a stress to a channel from above a gate electrode to distort the crystal of the channel and improve a carrier mobility in the channel includes the step of forming a silicon nitride film and a heat treatment step.

For example, Japanese Unexamined Patent Publication No. 2010-205951 (Patent Document 1) discloses a solid-state image sensing device formed using an SMT technique.

On the other hand, each of Japanese Unexamined Patent Publication No. 2009-32962 (Patent Document 2) and Japanese Unexamined Patent Publication No. 2009-252841 (Patent Document 3) discloses the influence of hydrogen on the performance of a transistor.

### RELATED ART DOCUMENTS

### Patent Documents

### [Patent Document 1]

Japanese Unexamined Patent Publication No. 2010-205951

### [Patent Document 2]

Japanese Unexamined Patent Publication No. 2009-32962

### [Patent Document 3]

Japanese Unexamined Patent Publication No. 2009-252841

### SUMMARY

The present inventors have been engaged in the research and development of a semiconductor device including a nonvolatile memory cell, and a MISFET and have actively studied about improvements in the properties thereof. In the process of the study, the present inventors have found that there is room for further improvements in the properties of a semiconductor device including a nonvolatile memory cell, and a MISFET.

Other problems and novel features of the present invention will become apparent from a statement in the present specification and the accompanying drawings.

The following is a brief description of the outline of a configuration shown in a representative embodiment disclosed in the present application.

In a method of manufacturing a semiconductor device shown in the representative embodiment disclosed in the present application, first, over a gate electrode included in a MISFET and first and second gate electrodes included in a nonvolatile memory cell, a silicon nitride film is formed. Then, by removing the silicon nitride film from over the first and second gate electrodes, an opening is formed over the first and second gate electrodes. Then, heat treatment is performed in a state where the opening is formed.

The method of manufacturing the semiconductor device shown in the representative embodiment disclosed in the present application allows a semiconductor device having excellent properties to be manufactured.

### BRIEF DESCRIPTION OF THE DRAWINGS

FIG. 1 is a main-portion cross-sectional view showing a configuration of a semiconductor device in Embodiment 1;

FIG. 2 is a main-portion cross-sectional view showing the manufacturing process of the semiconductor device in Embodiment 1;

FIG. 3 is a main-portion cross-sectional view showing the manufacturing process of the semiconductor device in Embodiment 1, which is subsequent to FIG. 2;

FIG. 4 is a main-portion cross-sectional view showing the manufacturing process of the semiconductor device in Embodiment 1, which is subsequent to FIG. 3;

FIG. 5 is a main-portion cross-sectional view showing the manufacturing process of the semiconductor device in Embodiment 1, which is subsequent to FIG. 4;

FIG. 6 is a main-portion cross-sectional view showing the manufacturing process of the semiconductor device in Embodiment 1, which is subsequent to FIG. 5;

FIG. 7 is a main-portion cross-sectional view showing the manufacturing process of the semiconductor device in Embodiment 1, which is subsequent to FIG. 6;

FIG. 8 is a main-portion cross-sectional view showing the manufacturing process of the semiconductor device in Embodiment 1, which is subsequent to FIG. 7;

FIG. 9 is a main-portion cross-sectional view showing the manufacturing process of the semiconductor device in Embodiment 1, which is subsequent to FIG. 8;

FIG. 10 is a main-portion cross-sectional view showing the manufacturing process of the semiconductor device in Embodiment 1, which is subsequent to FIG. 9;

FIG. 11 is a main-portion cross-sectional view showing the manufacturing process of the semiconductor device in Embodiment 1, which is subsequent to FIG. 10;

FIG. 12 is a main-portion cross-sectional view showing the manufacturing process of the semiconductor device in Embodiment 1, which is subsequent to FIG. 11;

FIG. 13 is a main-portion cross-sectional view showing the manufacturing process of the semiconductor device in Embodiment 1, which is subsequent to FIG. 12;

FIG. 14 is a main-portion cross-sectional view showing the manufacturing process of the semiconductor device in Embodiment 1, which is subsequent to FIG. 13;

FIG. 15 is a main-portion cross-sectional view showing the manufacturing process of the semiconductor device in Embodiment 1, which is subsequent to FIG. 14;

FIG. 16 is a main-portion cross-sectional view showing the manufacturing process of the semiconductor device in Embodiment 1, which is subsequent to FIG. 15;

FIG. 17 is a main-portion cross-sectional view showing the manufacturing process of the semiconductor device in Embodiment 1, which is subsequent to FIG. 16;

FIG. 18 is a main-portion cross-sectional view showing the manufacturing process of the semiconductor device in Embodiment 1, which is subsequent to FIG. 17;

FIG. 19 is a main-portion cross-sectional view showing the manufacturing process of the semiconductor device in Embodiment 1, which is subsequent to FIG. 18;

FIG. 20 is a view showing the respective properties of a MISFET (LT), a MISFET (HT), and a memory cell MC after the application of an SMT thereto;

FIG. 21 is a cross-sectional view of a MISFET in which a silicon nitride film as a stress application film is provided;

FIG. 22 is a cross-sectional view of a memory cell in which a silicon nitride film as a stress application film is provided;

FIG. 23 is a main-portion cross-sectional view of a semiconductor device in Embodiment 2;

FIG. 24 is an equivalent circuit diagram of a memory cell in the semiconductor device in Embodiment 2;

FIG. 25 is a table showing an example of conditions for the application of voltages to the individual parts of the memory cell during “write”, “erase”, and “read” operations;

FIG. 26 is a process flow chart showing a part of the manufacturing process of the semiconductor device in Embodiment 2;

FIG. 27 is a process flow chart showing a part of the manufacturing process of the semiconductor device in Embodiment 2;

FIG. 28 is a main-portion cross-sectional view showing the manufacturing process of the semiconductor device in Embodiment 2;

FIG. 29 is a main-portion cross-sectional view showing the manufacturing process of the semiconductor device in Embodiment 2, which is subsequent to FIG. 28;

FIG. 30 is a main-portion cross-sectional view showing the manufacturing process of the semiconductor device in Embodiment 2, which is subsequent to FIG. 29;

FIG. 31 is a main-portion cross-sectional view showing the manufacturing process of the semiconductor device in Embodiment 2, which is subsequent to FIG. 30;

FIG. 32 is a main-portion cross-sectional view showing the manufacturing process of the semiconductor device in Embodiment 2, which is subsequent to FIG. 31;

FIG. 33 is a main-portion cross-sectional view showing the manufacturing process of the semiconductor device in Embodiment 2, which is subsequent to FIG. 32;

FIG. 34 is a main-portion cross-sectional view showing the manufacturing process of the semiconductor device in Embodiment 2, which is subsequent to FIG. 33;

FIG. 35 is a main-portion cross-sectional view showing the manufacturing process of the semiconductor device in Embodiment 2, which is subsequent to FIG. 34;

FIG. 36 is a main-portion cross-sectional view showing the manufacturing process of the semiconductor device in Embodiment 2, which is subsequent to FIG. 35;

FIG. 37 is a main-portion cross-sectional view showing the manufacturing process of the semiconductor device in Embodiment 2, which is subsequent to FIG. 36;

FIG. 38 is a main-portion cross-sectional view showing the manufacturing process of the semiconductor device in Embodiment 2, which is subsequent to FIG. 37;

FIG. 39 is a main-portion cross-sectional view showing the manufacturing process of the semiconductor device in Embodiment 2, which is subsequent to FIG. 38;

FIG. 40 is a main-portion cross-sectional view showing the manufacturing process of the semiconductor device in Embodiment 2, which is subsequent to FIG. 39;

FIG. 41 is a main-portion cross-sectional view showing the manufacturing process of the semiconductor device in Embodiment 2, which is subsequent to FIG. 40;

FIG. 42 is a main-portion cross-sectional view showing the manufacturing process of the semiconductor device in Embodiment 2, which is subsequent to FIG. 41;

FIG. 43 is a main-portion cross-sectional view showing the manufacturing process of the semiconductor device in Embodiment 2, which is subsequent to FIG. 42;

FIG. 44 is a main-portion cross-sectional view showing the manufacturing process of the semiconductor device in Embodiment 2, which is subsequent to FIG. 43;

FIG. 45 is a main-portion cross-sectional view showing the manufacturing process of the semiconductor device in Embodiment 2, which is subsequent to FIG. 44;

FIG. 46 is a main-portion cross-sectional view showing the manufacturing process of the semiconductor device in Embodiment 2, which is subsequent to FIG. 45;

FIG. 47 is a main-portion cross-sectional view showing the manufacturing process of the semiconductor device in Embodiment 2, which is subsequent to FIG. 46;

FIG. 48 is a main-portion cross-sectional view showing the manufacturing process of the semiconductor device in Embodiment 2, which is subsequent to FIG. 47;

FIG. 49 is a main-portion cross-sectional view showing the manufacturing process of the semiconductor device in Embodiment 2, which is subsequent to FIG. 48;

FIG. 50 is a main-portion cross-sectional view of a semiconductor device in a comparative example during the manufacturing process thereof;

FIG. 51 is a main-portion cross-sectional view showing the manufacturing process of a semiconductor device in Application Example 2 of Embodiment 3;

FIG. 52 is a main-portion cross-sectional view showing the manufacturing process of the semiconductor device in Application Example 2 of Embodiment 3;

FIG. 53 is a main-portion cross-sectional view showing the manufacturing process of a semiconductor device in Application Example 3 of Embodiment 3;

FIG. 54 is a main-portion cross-sectional view showing the manufacturing process of the semiconductor device in Application Example 3 of Embodiment 3;

FIG. 55 is a main-portion cross-sectional view showing the manufacturing process of the semiconductor device in Application Example 3 of Embodiment 3;

FIG. 56 is a main-portion cross-sectional view showing the manufacturing process of the semiconductor device in Application Example 3 of Embodiment 3; and

FIG. 57 is a main-portion cross-sectional view showing the manufacturing process of the semiconductor device in Application Example 3 of Embodiment 3.

### DETAILED DESCRIPTION

In the following embodiments, if necessary for the sake of convenience, the embodiments will be each described by being divided into a plurality of sections or embodiments. However, they are by no means irrelevant to each other unless particularly explicitly described otherwise, but are in relations such that one of the sections or embodiments is a modification, an application example, a detailed description, a supplementary description, and so forth of part or the whole of the others. Also, in the following embodiments, when the number and the like (including the number, numerical value, amount, range, and the like) of elements are mentioned, they are not limited to specific numbers unless particularly explicitly described otherwise or unless they are obviously limited to specific numbers in principle. The number and the like of the elements may be not less than or not more than specific numbers.

Also in the following embodiments, the components thereof (including elements, steps, and the like) are not necessarily indispensable unless particularly explicitly described otherwise or unless the components are considered to be obviously indispensable in principle. Likewise, if the shapes, positional relationships, and the like of the components and the like are mentioned in the following embodiments, the shapes and the like are assumed to include those substantially proximate or similar thereto and the like unless particularly explicitly described otherwise or unless it can be considered that they obviously do not in principle. The same shall apply in regard to the foregoing number and the like (including the number, numerical value, amount, range, and the like).

Hereinbelow, the embodiments will be described in detail on the basis of the drawings. Note that, throughout all the drawings for illustrating the embodiments, members having the same functions are designated by the same or related reference numerals, and a repeated description thereof is omitted. When there are a plurality of similar members (portions), marks may be added to general reference numerals to show individual or specific portions. Also, in the following embodiments, a description of the same or like parts will not be repeated in principle unless particularly necessary.

In the drawings used in the embodiments, hatching may be omitted even in a cross-sectional view for improved clarity of illustration.

In a cross-sectional view, the sizes of individual portions do not correspond to those in a real device. For improved clarity of illustration, a specific portion may be shown in a relatively large size.

### Embodiment 1

Referring to the drawings, the following will describe a structure of a semiconductor device (semiconductor storage device) in Embodiment 1.

—Description of Structure—

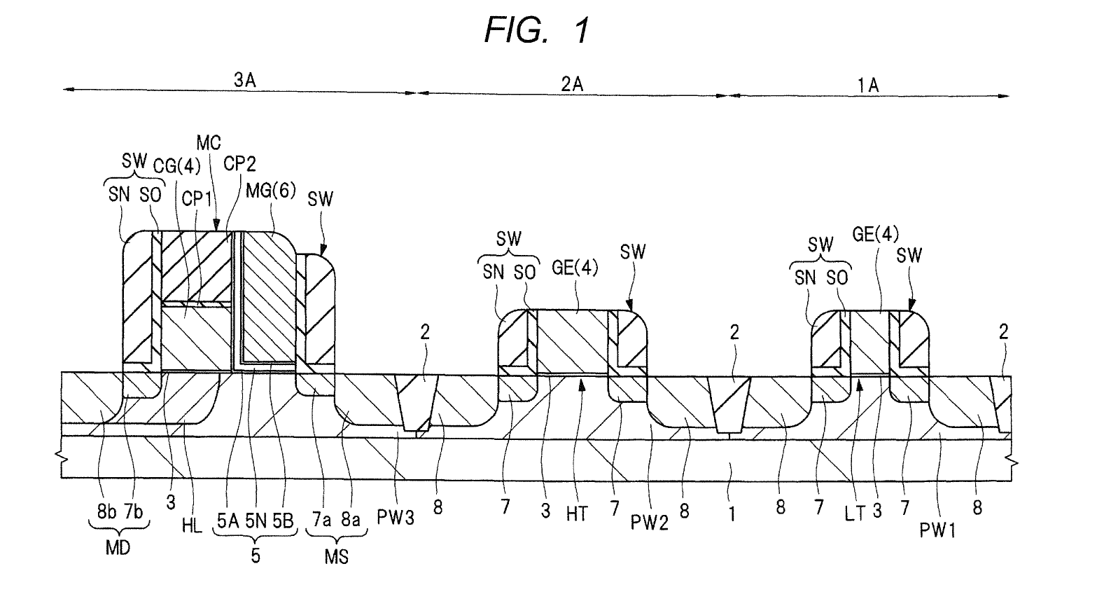

FIG. 1 is a main-portion cross-sectional view showing a configuration of the semiconductor device in the present embodiment. The semiconductor device in the present embodiment has a MISFET (LT), a MISFET (HT), and a memory cell (referred to also as a nonvolatile memory cell, a nonvolatile storage element, a nonvolatile semiconductor storage device, an EEPROM, or a flash memory) MC.

The MISFET (LT) is formed in a core MIS formation region 1A and has a gate length smaller than that of the MISFET (HT). For example, the gate length of the MISFET (LT) is about 40 nm. Such a MISFET having a relatively small gate length is used for, e.g., a circuit (referred to also as core circuit or peripheral circuit) for driving the memory cell MC or the like. The drive voltage of the MISFET (LT) tends to be lower than that of the MISFET (HT). The MISFET (LT) has an insulating film 3 which may be thinner than the insulating film 3 of the MISFET (HT).

On the other hand, the MISFET (HT) is formed in an I/O MIS formation region 2A and has a gate length larger than that of the MISFET (LT). For example, the gate length of the MISFET (HT) is about 1000 nm. Such a MISFET having a relatively large gate length is used for, e.g., an input/output circuit (referred to also as I/O circuit) or the like. The drive voltage of the MISFET (HT) tends to be higher than that of the MISFET (LT). The MISFET (HT) has the insulating film 3 which may be thicker than the insulating film 3 of the MISFET (LT).

The MISFET (LT) has a gate electrode GE disposed over a semiconductor substrate 1 (p-type well PW1) via the insulating film 3, and source/drain regions disposed in the semiconductor substrate 1 (p-type well PW1) located on both sides of the gate electrode GE. Over the side-wall portions of the gate electrode GE, side-wall insulating films SW each made of an insulating film are formed. Here, each of the side-wall insulating films SW is formed of a laminated body including a silicon dioxide film SO and a silicon nitride film SN. Each of the source/drain regions has an LDD structure and includes an n⁺-type semiconductor region 8 and an n⁻-type semiconductor region 7. The n⁻-type semiconductor region 7 is formed by self-alignment with the side wall of the gate electrodes GE. The n⁺-type semiconductor region 8 is formed by self-alignment with the side surface of the side-wall insulating film SW and has a junction depth deeper than that of the n⁻-type semiconductor region 7 and an impurity concentration higher than that thereof.

The MISFET (HT) has the gate length GE disposed over the semiconductor substrate 1 (p-type well PW2) via the insulating film 3, and source/drain regions disposed in the semiconductor substrate 1 (p-type well PW2) located on both sides of the gate electrode GE. Over the side-wall portions of the gate electrode GE, the side-wall insulating films SW each made of an insulating film are formed. Here, each of the side-wall insulating films SW is formed of a laminated body including the silicon dioxide film SO and the silicon nitride film SN. Each of the source/drain regions has an LDD structure and includes the n⁺-type semiconductor region 8 and the n⁻-type semiconductor region 7. The n⁻-type semiconductor region 7 is formed by self-alignment with the side wall of the gate electrode GE. The n⁺-type semiconductor region 8 is formed by self-alignment with the side surface of the side-wall insulating film SW and has a junction depth deeper than that of the n⁻-type semiconductor region 7 and an impurity concentration higher than that thereof.

The memory cell MC has a control gate electrode (gate electrode) CG located over the semiconductor substrate 1 (p-type well PW3), and a memory gate electrode (gate electrode) MG located over the semiconductor substrate 1 (p-type well PW3) to be adjacent to the control gate electrode CG. Over the control gate electrode CG, a thin silicon dioxide film CP1 and a silicon nitride film (cap insulating film) CP2 are disposed. The memory cell MC also has the insulating film 3 disposed between the control gate electrode CG and the semiconductor substrate 1 (p-type well PW3), and an insulating film 5 disposed between the memory gate electrode MG and the semiconductor substrate 1 (p-type well PW3) and disposed between the memory gate electrode MG and the control gate electrode CG.

The memory cell MC also has a source region MS and a drain region MD which are formed in the p-type well PW3 of the semiconductor substrate 1. Over the side-wall portions of a composite pattern of the memory gate electrode MG and the control gate electrode CG, the side-wall insulating films SW each made of an insulating film are formed. Here, each of the side-wall insulating films SW is formed of the laminated body including the silicon dioxide film SO, and the silicon nitride film SN. The source region MS includes an n⁺-type semiconductor region 8a, and an n⁻-type semiconductor region 7a. The n⁻-type semiconductor region 7a is formed by self-alignment with the side wall of the memory gate electrode MG. The n⁺-type semiconductor region 8a is formed by self-alignment with the side surface of the side-wall insulating film SW closer to the memory gate electrode MG and has a junction depth deeper than that of the n⁻-type semiconductor region 7a and an impurity concentration higher than that thereof. The drain region MD includes an n⁺-type semiconductor region 8b and an n⁻-type semiconductor region 7b. The n⁻-type semiconductor region 7b is formed by self-alignment with the side wall of the control gate electrode CG. The n⁺-type semiconductor region 8b is formed by self-alignment with the side surface of the side-wall insulating film SW closer to the control gate electrode CG and has a junction depth deeper than that of the n⁻-type semiconductor region 7b and an impurity concentration higher than that thereof.

In the present embodiment (FIG. 1), among the MISFET (LT), the MISFET (HT), and the memory cell MC, the MISFET (LT) and the MISFET (HT) have channel regions to each of which a stress is applied using a SMT. On the other hand, the memory cell MC has a channel region to which no stress is applied using the SMT.

As described above, the SMT is a technique which applies a stress to a channel region from above the gate electrode of a MISFET and from the side surface portion thereof to distort the crystal of the channel region and improve a carrier mobility in the channel region.

Specifically, a stress application film is formed over the gate electrode and performs heat treatment. By the heat treatment, a stress (compressive stress or tensile stress) is applied to the stress application film. The stress reaches the channel region under the gate electrode GE and changes a crystal interval in the channel region to allow an improvement in carrier mobility. The stress applied to the channel region is maintained even after the stress application film is removed.

Accordingly, in the present embodiment (FIG. 1), among the MISFET (LT), the MISFET (HT), and the memory cell MC, the MISFET (LT) and the MISFET (HT) have channel regions where crystal intervals have been changed using the SMT. On the other hand, in the channel region of the memory cell MC to which the SMT has not been applied, there is no change in crystal interval due to the SMT. Thus, in the semiconductor device in the present embodiment, the SMT is not applied to all the elements, but is selectively applied to be able to generally improve the properties of the semiconductor device. This will be described in greater detail in the following section “Description of Manufacturing Method”.

—Description of Manufacturing Method—

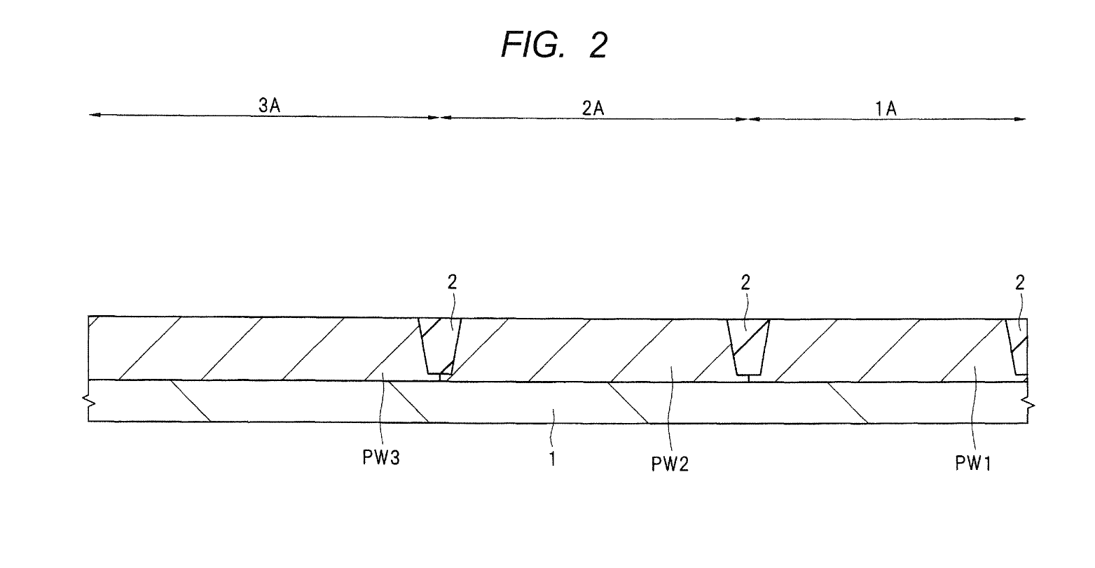

Next, referring to FIGS. 2 to 19, a method of manufacturing the semiconductor device in the present embodiment will be described. FIGS. 2 to 19 are main-portion cross-sectional views showing the manufacturing process of the semiconductor device in the present embodiment.

<Steps of Forming MISFET (LT), MISFET (HT), and Memory Cell MC>

First, a description will be given of an example of the steps of forming the MISFET (LT), the MISFET (HT), and the memory cell MC.

As shown in FIG. 2, as the semiconductor substrate 1, a silicon substrate made of p-type monocrystalline silicon having a specific resistance of, e.g., about 1 to 10 Ωcm is provided. Note that the semiconductor substrate 1 other than a silicon substrate may also be used.

Next, in the main surface of the semiconductor substrate 1, isolation regions 2 are formed. For example, in the semiconductor substrate 1, isolation trenches are formed and, in the isolation trenches, an insulating film such as a silicon dioxide film is embedded to form the isolation regions 2. Such an isolation method is referred to as a STI (Shallow Trench Isolation) method. Besides, a LOCOS (Local Oxidization of Silicon) method or the like may also be used to form the isolation regions 2.

Next, in the core MIS formation region 1A of the semiconductor substrate 1, the p-type well PW1 is formed and, in an I/O MIS formation region 2A, the p-type well PW2 is formed while, in a memory cell region 3A, the p-type well PW3 is formed. The p-type wells PW1, PW2, and PW3 are formed by ion-implanting a p-type impurity (such as, e.g., boron (B)).

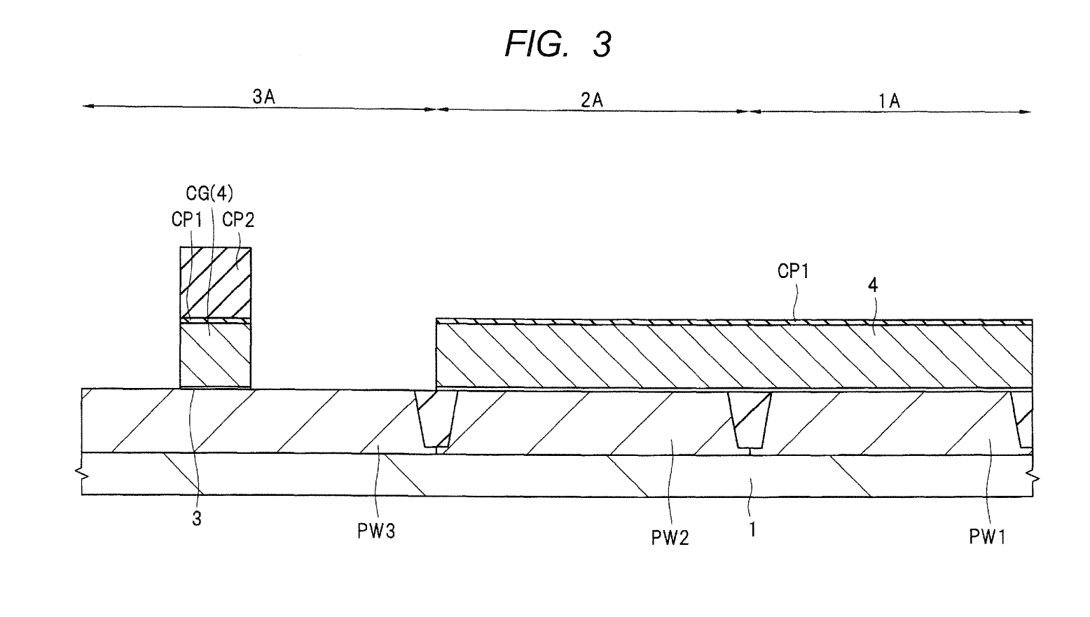

Next, by diluted hydrofluoric acid cleaning or the like, the top surface of the semiconductor substrate 1 (p-type wells PW1, PW2, and PW3) is cleaned. Then, as shown in FIG. 3, over the main surface of the semiconductor substrate 1 (top surfaces of the p-type wells PW1, PW2, and PW3), e.g., a silicon dioxide film is formed as the insulating film (gate insulating film) 3 to a thickness of about 2 to 3 nm by a thermal oxidation method. As the insulating films 3, another insulating film such as a silicon oxynitride film may also be used instead of the silicon dioxide film. Besides, a metal oxide film having a dielectric constant higher than that of a silicon nitride film such as a hafnium oxide film, an aluminum oxide (alumina) film, or a tantalum oxide film or a laminated film including an oxide film or the like and a metal oxide film may also be formed. Instead of a thermal oxidation method, a CVD (Chemical Vapor Deposition) method may also be used to form the insulating film 3. It may also be possible to form the insulating films (gate insulating films) 3 of different types to different thicknesses over the core MIS formation region 1A, over the I/O MIS formation region 2A, and over the memory cell regions 3A.

Next, over the entire surface of the semiconductor substrate 1, a silicon film 4 is formed as a conductive film (conductor film). As the silicon film 4, e.g., a polycrystalline silicon film is formed to a thickness of about 100 to 200 nm using a CVD method or the like. As the silicon film 4, an amorphous silicon film may also be deposited and subjected to heat treatment to be crystallized (crystallization treatment). The silicon film 4 serves as the gate electrode GE of the MISFET (LT) in the core MIS formation region 1A, serves as the gate electrode GE of the MISFET (HT) in the I/O MIS formation region 2A, and serves as the control gate electrode CG of the memory cell MC in the memory cell region 3A.

Then, into the silicon film 4 in the memory cell region 3A, an n-type impurity (such as, e.g., arsenic (As) or phosphorus (P)) is implanted.

Next, the top surface of the silicon film 4 is thermally oxidized to a depth of about 3 to 10 nm to form the thin silicon dioxide film CP1. Note that the silicon dioxide film CP1 may also be formed using a CVD method. Then, over the silicon dioxide film CP1, using a CVD method or the like, the silicon nitride film (cap insulating film) CP2 is formed to a thickness of about 50 to 150 nm.

Next, in the region where the control gate electrode CG is to be formed, using a photolithographic method, a photoresist film (not shown) is formed. Using the photoresist film as a mask, the silicon nitride film CP2, the silicon dioxide film CP1, and the silicon film 4 are etched. Then, the photoresist film is removed by asking or the like so that the control gate electrode CG (having a gate length of, e.g., about 80 nm) is formed. Such a series of steps from photolithography to the removal of the photoresist film is referred to as patterning. Thus, in the present embodiment, the cap insulating film (silicon nitride film CP2 and silicon dioxide film CP1) is formed over the control gate electrode CG. Accordingly, a control gate electrode portion (laminated film portion including the control gate electrode CG and the cap insulating film) is higher in level (thicker) than the gate electrode GE of the MISFET (LT) and the gate electrode GE of the MISFET (HT). It may also be possible to form the silicon film 4 thick and thus increase the height of the control gate electrode CG. In this case, the cap insulating film can be omitted. In this case, by removing the thick silicon film 4 from the core MIS formation region 1A and the I/O MIS formation region 2A and forming a thin silicon film again, the control gate electrode CG can be made higher (thicker) than the gate electrode GE of the MISFET (LT) and the gate electrode GE of the MISFET (HT). Note that, as an example of the foregoing step of forming the thin silicon film again, the step shown in Embodiment 2 can be used appropriately. By thus increasing the height of the control gate electrode portion (laminated film portion including the control gate electrode CG and the cap insulating film) or the control gate electrode CG, the memory gate electrode MG described later can be formed with high controllability into an excellent shape.

Here, the insulating film 3 remaining under the control gate electrode CG in the memory cell region 3A serves as the gate insulating film of the control transistor. Note that the insulating film 3 except for the portion thereof covered with the control electrode CG can be removed by the subsequent patterning step or the like. On the other hand, in the core MIS formation region 1A and the I/O MIS formation region 2A, the silicon nitride film CP2, the silicon dioxide film CP1, and the silicon film 4 are left.

Next, in the core MIS formation region 1A, the silicon nitride film CP2 is removed from over the silicon film 4.

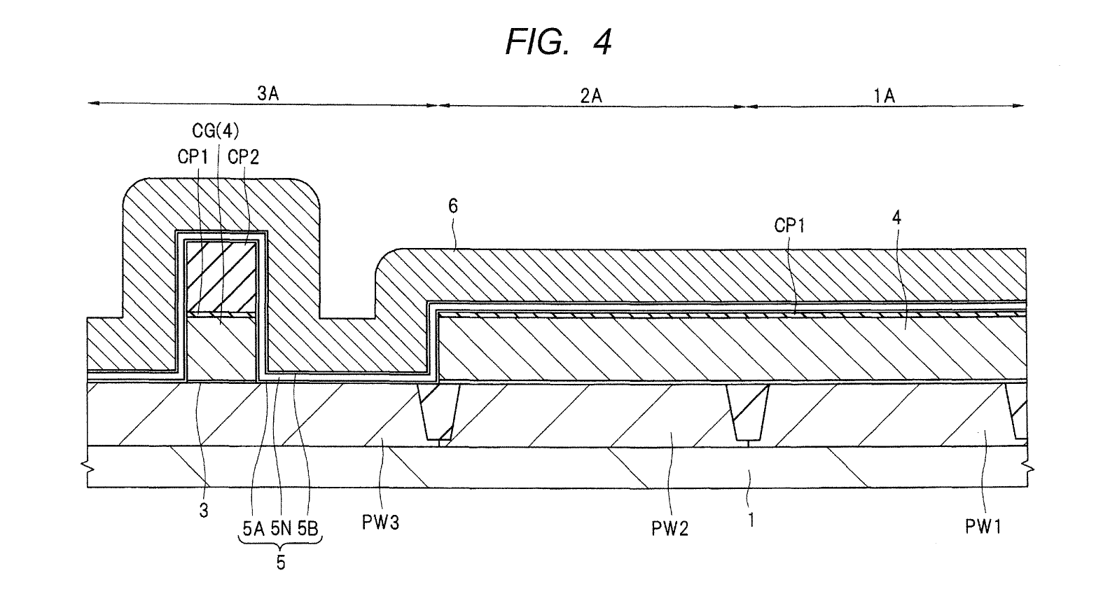

Then, as shown in FIG. 4, over the semiconductor substrate 1 including the silicon nitride film CP2 and the silicon oxide film CP1, the insulating film 5 (5A, 5N, and 5B) is formed. First, the main surface of the semiconductor substrate 1 is subjected to cleaning treatment. Then, as shown in FIG. 4, over the semiconductor substrate 1 including the silicon nitride film CP2 and the silicon dioxide film CP1, the silicon dioxide film 5A is formed. The silicon dioxide film 5A is formed by, e.g., a thermal oxidation method (preferably, by ISSG oxidation) to a thickness of, e.g., about 4 nm. Note that the silicon dioxide film 5A may also be formed using a CVD method. The drawing shows the shape of the silicon dioxide film 5A when the silicon dioxide film 5A is formed by an ISSG oxidation method. Then, over the silicon dioxide film 5A, the silicon nitride film 5N is deposited by a CVD method to a thickness of, e.g., about 10 nm. The silicon nitride film 5N serves as the charge storage portion of the memory cell and serves as the middle layer included in the insulating film (ONO film) 5.

Next, over the silicon nitride film 5N, the silicon dioxide film 5B is formed by a CVD method to a thickness of, e.g., about 5 nm.

By the foregoing steps, the insulating film (ONO film) 5 including the silicon dioxide film 5A, the silicon nitride film 5N, and the silicon dioxide film 5B can be formed. Note that, over the silicon nitride film (cap insulating film) CP2 in the core MIS formation region 1A and the I/O MIS formation region 2A shown in FIG. 4, the insulating film (ONO film) 5 may also remain.

In the present embodiment, as the internal charge storage portion (a charge storage layer or an insulating film having a trap level) of the insulating film 5, the silicon nitride film 5N is formed. However, another insulating film such as, e.g., a silicon oxynitride film, an aluminum oxide film, a hafnium oxide film, or a tantalum oxide film may also be used. Such a film is a high-dielectric-constant film having a dielectric constant higher than that of a silicon nitride film. Alternatively, the charge storage layer may also be formed using an insulating film having silicon nanodots.

The insulating film 5 formed in the memory cell region 3A functions as the gate insulating film of the memory gate electrode MG and has a charge retaining (charge storing) function. Accordingly, the insulating film 5 has a laminated structure including at least three layers and is configured such that the potential barrier height of the inner layer (silicon nitride film 5N) is lower than the potential barrier height of each of the outer layers (silicon dioxide films 5A and 5B). The film thicknesses of the individual layers have optimum values for each operation method of the memory cell.

Next, over the insulating film 5, a silicon film 6 is formed as a conductive film (conductor film). Over the insulating film 5, as the silicon film 6, e.g., a polycrystalline silicon film is formed using a CVD method or the like to a thickness of about 50 to 200 nm. As the silicon film 6, an amorphous silicon film may also be deposited and subjected to heat treatment to be crystallized (crystallization treatment). Note that, as necessary, an impurity may also be introduced into the silicon film 6. As will be described later, the silicon film 6 serves as the memory gate electrode MG (having a gate length of, e.g., about 50 nm) in the memory cell region 3A.

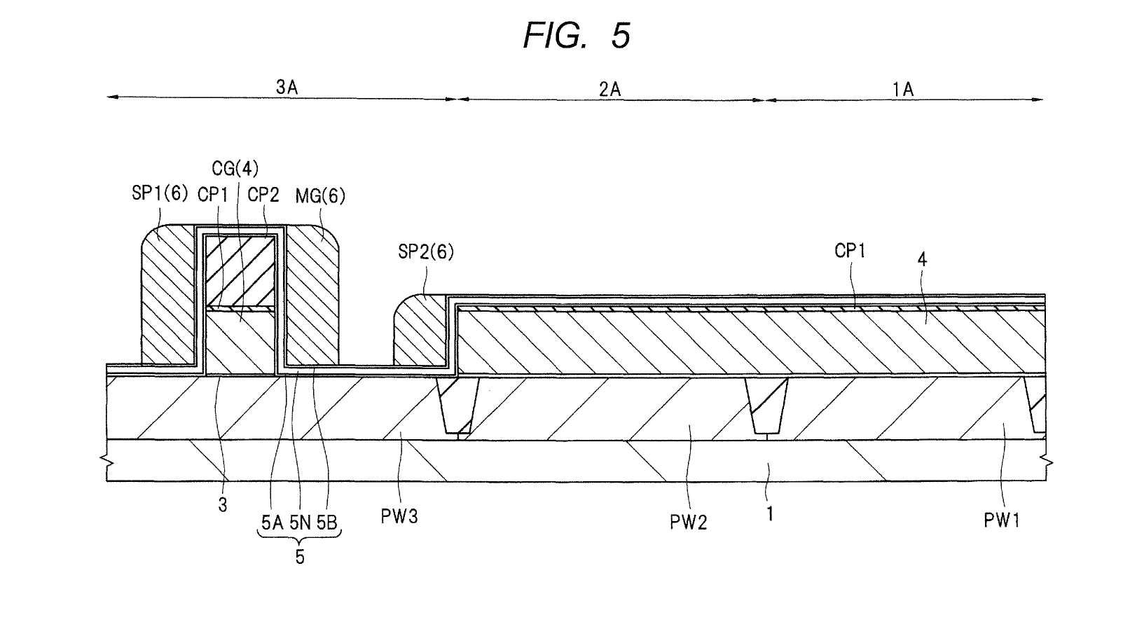

Next, as shown in FIG. 5, the silicon film 6 is etched back. In the etch-back step, the surface portion of the silicon film 6 corresponding to a predetermined thickness is removed from the top surface thereof by anisotropic dry etching. The process allows the silicon film 6 to be left into sidewall shapes (side-wall film shapes) over the both side-wall portions of the control gate electrode CG via the insulating films 5. At this time, in the core MIS formation region 1A and the I/O MIS formation region 2A, the silicon film 6 is etched to expose the insulating film 5. Note that, at the boundary portion between the I/O MIS formation region 2A and the memory cell region 3A, over the side wall of the laminated film including the silicon dioxide film CP1 and the silicon film 4, the silicon film 6 remains as a silicon spacer SP2 in a sidewall shape (side-wall film shape) via the insulating film 5.

The silicon film 6 remaining over one of the both side-wall portions of the foregoing control gate electrode CG forms the memory gate electrode MG. The silicon film 6 remaining over the other side-wall portion forms a silicon spacer SP1. The insulating film 5 under the foregoing memory gate electrode MG serves as the gate insulating film of the memory transistor. A memory gate length (gate length of the memory gate electrode MG) is determined in correspondence to the thickness of the deposited silicon film 6.

Thus, the memory gate electrode MG is formed in the sidewall shape (side-wall film shape) over the side wall of the control gate electrode portion (laminated film portion including the control gate electrode CG, and the cap insulating film) via the insulating film 5. Accordingly, by forming the high control gate electrode portion, the memory gate electrode MG can be formed with high controllability into an excellent shape. Since it is possible to ensure a sufficient height for the memory gate electrode MG, the side-wall insulating film SW formed over the side wall of the memory gate electrode MG can be formed with high controllability into an excellent shape. In addition, the n⁻-type semiconductor region 7a and the n⁺-type semiconductor region 8a which are formed by implanting an n-type impurity using the memory gate electrode MG and the side-wall insulating film SW as a mask can be formed with high controllability into excellent shapes.

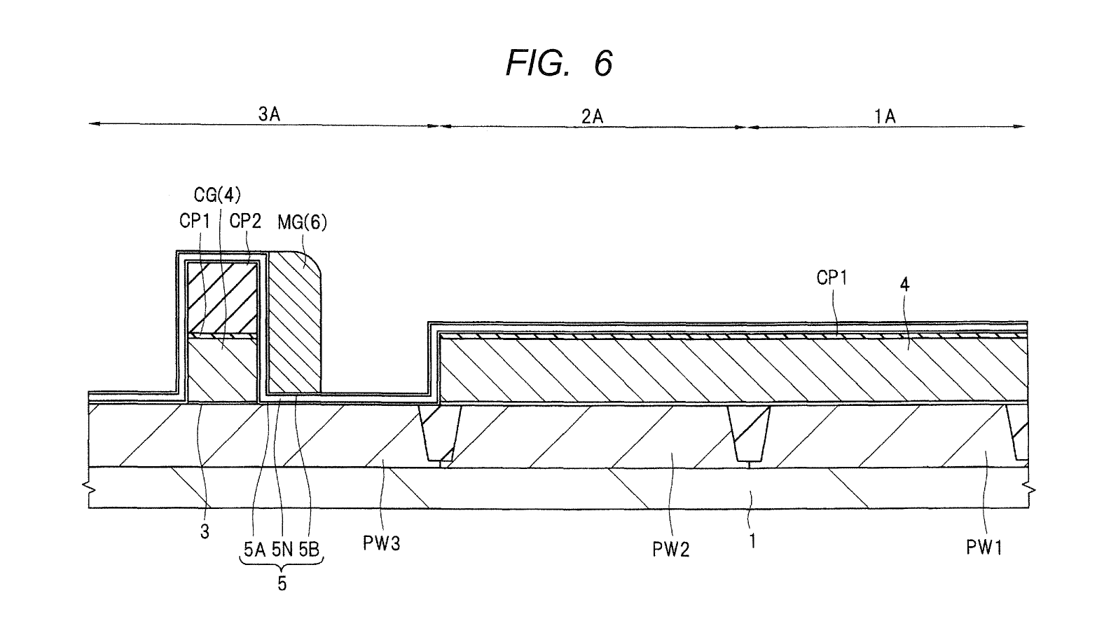

Next, as shown in FIG. 6, the silicon spacer SP1 over the side-wall portion of the control gate electrode CG where the memory gate electrode MG is not formed and the silicon spacer SP2 (silicon film 6) at the boundary portion between the core MIS formation region 1A and the memory cell region 3A are removed.

Next, the insulating film 5 is removed by etching. As a result, in the memory cell region 3A, the silicon nitride film CP2 over the control gate electrode CG is exposed, and the p-type well PW3 is exposed. In the core MIS formation region 1A, the silicon dioxide film CP1 is also removed to expose the silicon film 4.

Next, in the core MIS formation region 1A, an impurity is introduced into the silicon film 4. For example, into the silicon film 4, an n-type impurity such as phosphorus is implanted.

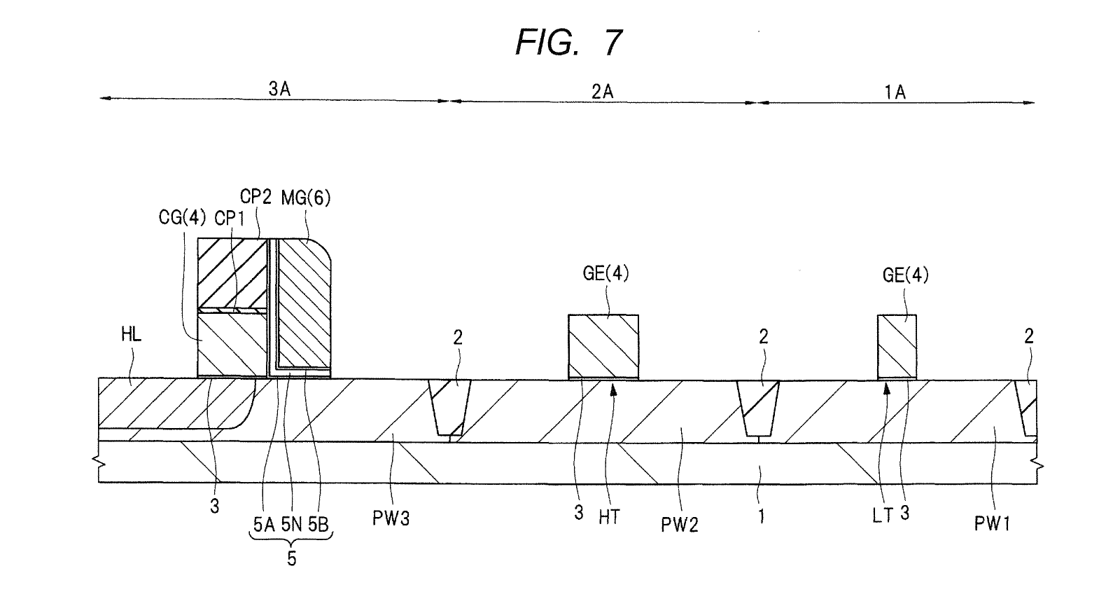

Next, over the region of the silicon film 4 which is to be formed into the gate electrode GE of the MISFET (LT) and the region of the silicon film 4 which is to be formed into the gate electrode GE of the MISFET (HT), using a photolithographic method, a photoresist film (not shown) is formed. Using the photoresist film as a mask, the silicon film 4 is etched. Then, the photoresist film (not shown) is removed by asking or the like to form the gate electrode GE of the MISFET (LT) in the core MIS formation region 1A and form the gate electrode GE of the MISFET (HT) in the I/O MIS formation region 2A, as shown in FIG. 7. The gate length of the gate electrode GE of the MISFET (LT) is, e.g., about 40 nm. The gate length of the gate electrode GE of the MISFET (HT) is, e.g., about 1000 nm.

The insulating films 3 remaining under the individual gate electrodes GE serve as the respective gate insulating films of the individual MISFETs (LT and HT). Note that the insulating films 3 except for the portions thereof covered with the gate electrodes GE may be removed during the formation of the foregoing gate electrodes GE or removed by the subsequent patterning step or the like.

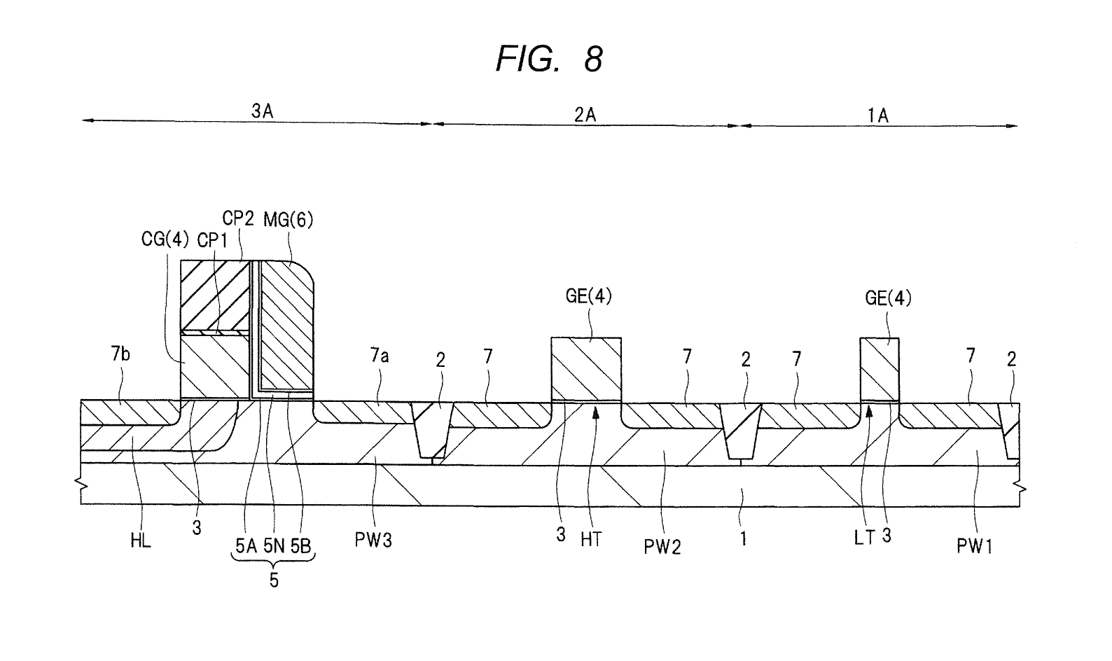

Next, as shown in FIG. 8, using a photoresist film (not shown) having an opening on one side (opposite to the memory gate electrode) of the control gate electrode CG as a mask, a p-type impurity is obliquely implanted (oblique implantation is performed). Thus, in the semiconductor substrate 1 located under the control gate electrode CG, a p-type halo region (p-type impurity region) HL is formed. The p-type halo region HL need not necessarily be formed but, when formed, the p-type halo region HL suppresses the extension of a depletion layer from the drain region MD to the channel region of the memory transistor and suppresses a short-channel effect in the memory transistor. This can suppress a reduction in the threshold voltage of the memory transistor. By further implanting an n-type impurity such as arsenic (As) or phosphorus (P) into the semiconductor substrate 1 (p-type well PW1) in the presence of the foregoing photoresist film (not shown), the n⁻-type semiconductor region 7b is formed. The n⁻-type semiconductor region 7b is formed by self-alignment with the side wall (side wall opposite to that adjacent to the memory gate electrode MG via the insulating film 5) of the control gate electrode CG. Then, the foregoing photoresist film (not shown) is removed.

Next, as shown in FIG. 8, using a photoresist film (not shown) having an opening on the memory gate electrode MG side as a mask, an n-type impurity such as arsenic (As) or phosphorus (P) is implanted into the semiconductor substrate 1 (p-type well PW1) to form the n⁻-type semiconductor region 7a. At this time, the n⁻-type semiconductor region 7a is formed by self-alignment with the side wall (side wall opposite to that adjacent to the control gate electrode CG via the insulating film 5) of the memory gate electrode MG. Also, in the core MIS formation region 1A and the I/O MIS formation region 2A, an n-type impurity such as arsenic (As) or phosphorus (P) is implanted into the semiconductor substrate 1 (p-type wells PW1 and PW2) located on both sides of the gate electrodes GE to form the n⁻-type semiconductor regions 7. At this time, the n⁻-type semiconductor regions 7 are formed by self-alignment with the side walls of the gate electrodes GE.

The n⁻-type semiconductor region 7a, the n⁻-type semiconductor region 7b, and the n⁻-type semiconductor regions 7 may be formed by the same ion implantation step, but are formed herein by different ion implantation steps. By thus forming the n⁻-type semiconductor regions 7a, 7b, and 7 by the different ion implantation steps, the n⁻-type semiconductor regions 7a, 7b, and 7 can be formed to have intended impurity concentrations and intended junction depths. The n⁻-type semiconductor regions 7 in the core MIS formation region 1A and the n⁻-type semiconductor regions 7 in the I/O MIS formation region 2A may also be formed to have different impurity concentrations and different junction depths.

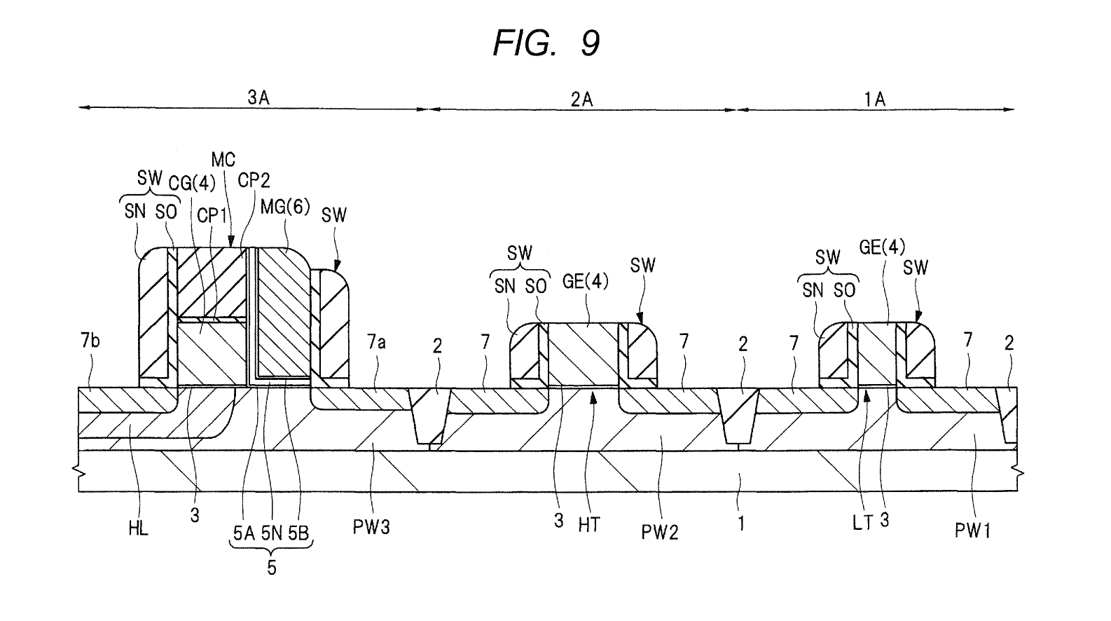

Next, as shown in FIG. 9, in the memory cell region 3A, over the side-wall portion of the composite pattern of the control gate electrode CG and the memory gate electrode MG, the side-wall insulating film SW is formed. Also, in the core MIS formation region 1A and the I/O MIS formation region 2A, over the side-wall portions of the gate electrodes GE, the side-wall insulating films SW are formed. For example, over the entire main surface of the semiconductor substrate 1, the silicon dioxide film SO is deposited. Over the silicon dioxide film SO, the silicon nitride film SN is further deposited to form an insulating film made of a laminated film including the silicon dioxide film SO and the silicon nitride film SN. By etching back the insulating film, over the side-wall portion of the foregoing composite pattern (CG and MG) and over the side-wall portions of the gate electrodes GE, the side-wall insulating films SW are formed. As each of the side-wall insulating films SW, besides the laminated film including the silicon dioxide film and the silicon nitride film, an insulating film such as a single-layer silicon dioxide film or a single-layer silicon nitride film may also be used.

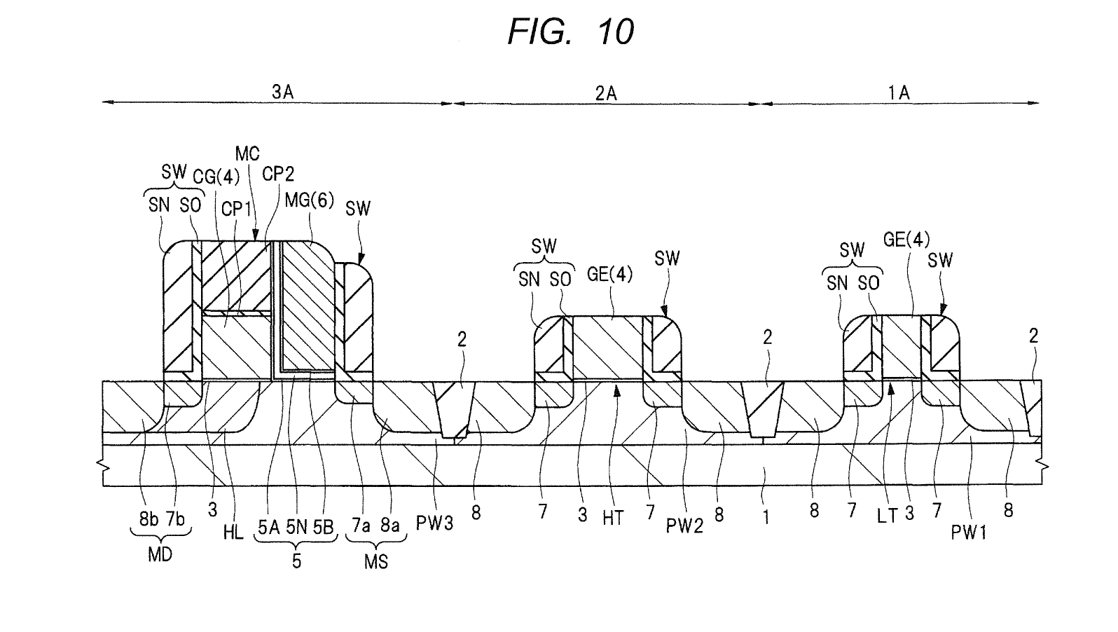

Next, as shown in FIG. 10, using the control gate electrode CG, the memory gate electrode MG, and the side-wall insulating films SW as a mask, an n-type impurity such as arsenic (As) or phosphorus (P) is implanted into the semiconductor substrate 1 (p-type well PW3) to form the higher-impurity-concentration n⁺-type semiconductor regions 8a and 8b. At this time, the n⁺-type semiconductor region 8a is formed in the memory cell region 3A by self-alignment with the side-wall insulating film SW closer to the memory gate electrode MG. On the other hand, the n⁺-type semiconductor region 8b is formed in the memory cell region 3A by self-alignment with the side-wall insulating film SW closer to the control gate electrode CG. The n⁺-type semiconductor region 8a is formed as a semiconductor region having an impurity concentration higher than that of the n⁻-type semiconductor region 7a and a junction depth deeper than that thereof. The n⁺-type semiconductor region 8b is formed as a semiconductor region having an impurity concentration higher than that of the n⁻-type semiconductor region 7b and a junction depth deeper than that thereof. On the other hand, in the core MIS formation region 1A and the I/O MIS formation region 2A, an n-type impurity such as arsenic (As) or phosphorus (P) is implanted into the semiconductor substrate 1 (p-type wells PW1 and PW2) located on both sides of the gate electrodes GE to form the n⁺-type semiconductor regions 8. At this time, the n⁺-type semiconductor regions 8 are formed by self-alignment with the side-wall insulating films SW over the side wall portions of the gate electrodes GE. The n⁺-type semiconductor regions 8 are formed as semiconductor regions having impurity concentrations higher than those of the n⁻-type semiconductor regions 7 and junction depths deeper than those thereof. The n⁺-type semiconductor regions 8a, 8b, and 8 may also be formed to have different impurity concentrations and different junction depths. The n⁺-type semiconductor regions 8 in the core MIS formation region 1A and the n⁺-type semiconductor regions 8 in the I/O MIS formation region 2A may also be formed to have different impurity concentrations and different junction depths.

By the foregoing process, in the memory cell region 3A, the n-type drain region MD including the n⁻-type semiconductor region 7b and the n⁺-type semiconductor region 8b and functioning as the drain region of the memory transistor is configured, and the n-type source region MS including the n⁻-type semiconductor region 7a and the n⁺-type semiconductor region 8a and functioning as the source region of the memory transistor is configured. On the other hand, in the core MIS formation region 1A and the I/O MIS formation region 2A, the source/drain regions having the LDD structures including the n⁻-type semiconductor regions 7 and the n⁺-type semiconductor regions 8 are formed.

Next, heat treatment (activation treatment) for activating the impurities introduced into the source region MS (the n⁻-type semiconductor region 7a and the n⁺-type semiconductor region 8a), the drain region MD (the n⁻-type semiconductor region 7b and the n⁺-type semiconductor region 8b), and the source/drain regions (7 and 8) is performed.

By the foregoing process, in the core MIS formation region 1A, the MISFET (LT) is formed and, in the I/O MIS formation region 2A, the MISFET (HT) is formed while, in the memory cell region 3A, the memory cell MC is formed (FIG. 10).

Note that the steps of forming the MISFET (LT), the MISFET (HT), and the memory cell MC are not limited to the foregoing steps.

<SMT and Silicide Process>

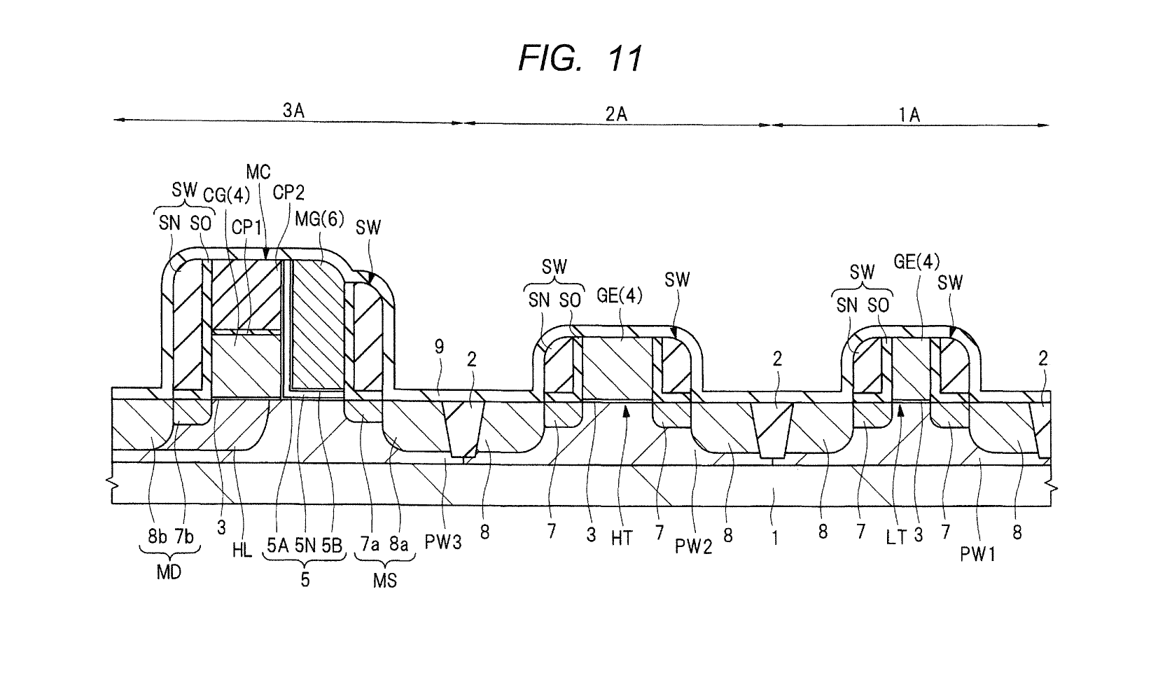

Next, as shown in FIG. 11, over the semiconductor substrate 1 including the MISFET (LT), the MISFET (HT), and the memory cell MC, a silicon dioxide film is formed as a stopper film 9 to a thickness of about 13 nm using a CVD method. For example, the silicon dioxide film is formed by a CVD method using TEOS (tetra ethoxy silane) and ozone (O₃) as raw material gases. The stopper film 9 performs the role of an etching stopper in the etching of a stress application film 10 described later. The stopper film 9 can prevent unintended etching of the individual patterns (such as, e.g., portions each made of the silicon film) forming the MISFET (LT), the MISFET (HT), and the memory cell MC.

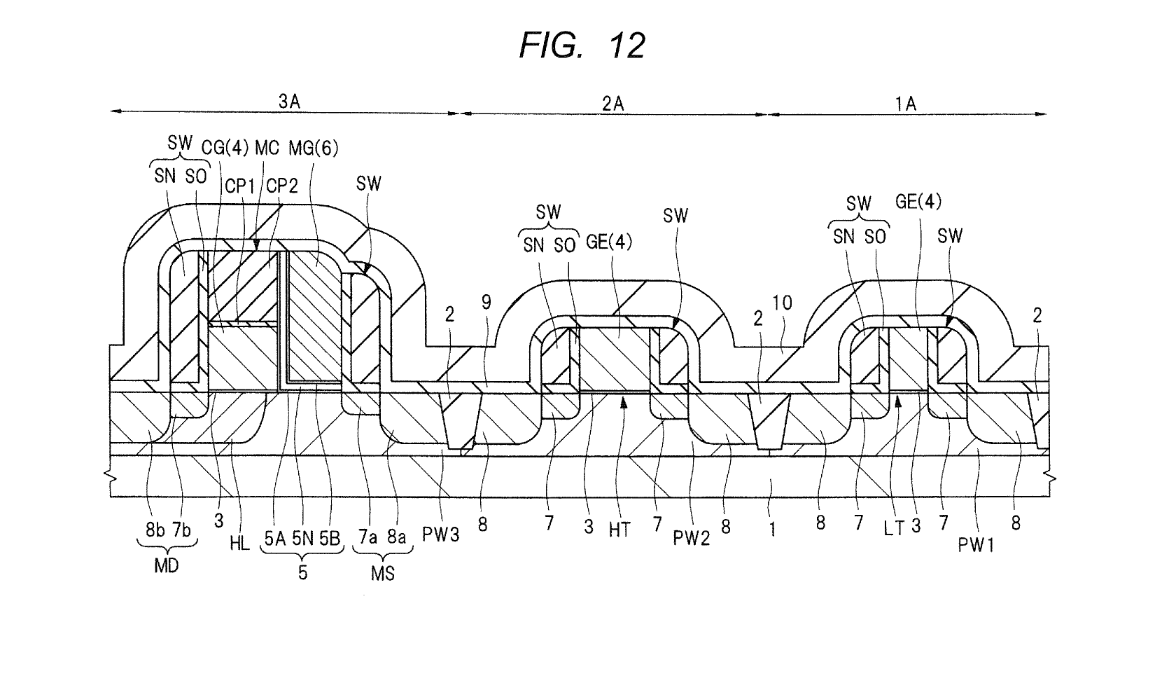

Next, as shown in FIG. 12, over the stopper film 9, a silicon nitride film is formed as the stress application film 10 over the stopper film 9 to a thickness of about 20 nm using a CVD method. For example, by a CVD method using HCD (disilicon hexachloride) and NH₃ (ammonia) as raw-material gases, the silicon nitride film is formed.

Here, the control gate electrode portion (laminated film portion including the control gate electrode CG and the cap insulating film) is formed higher than the gate electrodes GE of the MISFETs (LT) and (HT). Accordingly, the bottom portion of the stress application film 10 over the control gate electrode CG is located at a position higher than that of the bottom portion of the stress application film 10 over each of the gate electrodes GE. Also, the top surface of the stress application film 10 over the control gate electrode CG is located at a position higher than that of the top surface of the stress application film 10 over each of the gate electrodes GE.

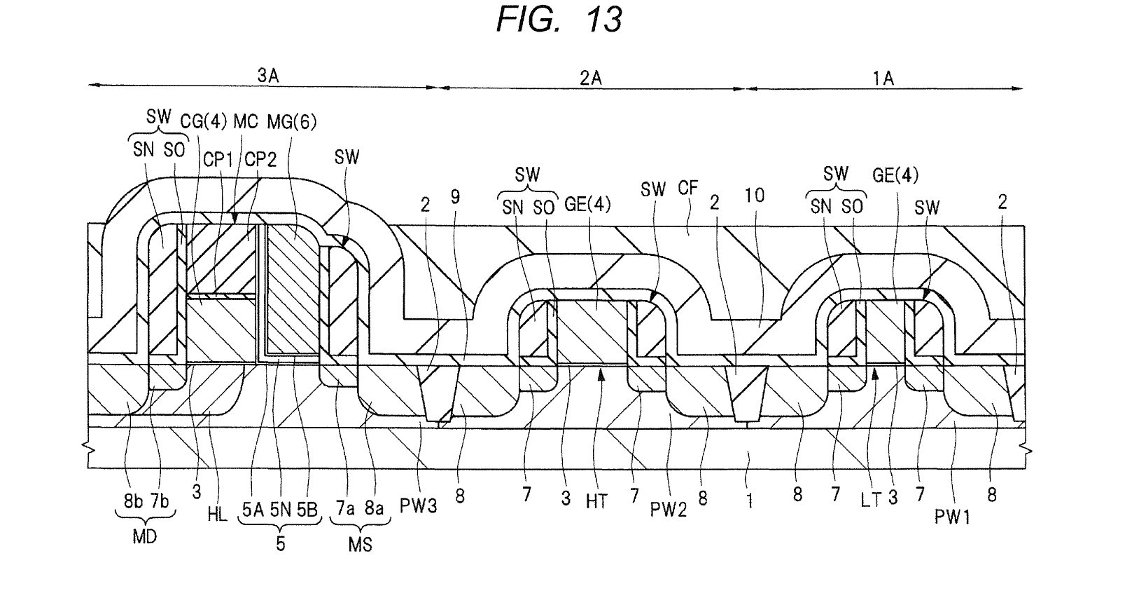

Next, as shown in FIG. 13, over the semiconductor substrate 1 (in the core MIS formation region 1A, the I/O MIS formation region 2A, and the memory cell region 3A), a coating film CF is formed. For example, as the coating film CF, an antireflection film (BARC: Bottom Anti-Reflective Coating) is formed. A material for the antireflection film is a coating agent in the form of a solution or gel and can be applied to the upper surface of the semiconductor substrate 1 using, e.g., a spin coating method or the like. At this time, the antireflection film material in the form of a solution or gel spreads so as to smooth away the surface roughness of the semiconductor substrate 1. Accordingly, by adjusting the amount of the antireflection film material to be applied, coating can be performed so as to cover the stress application film 10 in each of the core MIS formation region 1A and the I/O MIS formation region 2A and expose the stress application film 10 over the control gate electrode portion (laminated film portion including the control gate electrode CG and the cap insulating film) in the memory cell region 3A, as shown in FIG. 13. Thus, the coating film CF is formed to cover the stress application film 10 in each of the core MIS formation region 1A and the I/O MIS formation region 2A and expose the stress application film over the control gate electrode portion (laminated film portion including the control gate electrode CG and the cap insulating film) in the memory cell region 3A. Such a process allows the coating film CF which partially exposes the stress application film 10 to be formed in a so-called maskless manner without performing exposure/development treatment. Note that, as the coating film CF, the antireflection film is used herein, but another coating agent in the form of a solution or gel (e.g., photoresist film) may also be used. However, the antireflection film is easily controlled even in the state of a relatively thin film and allows easy adjustment of the thickness of the coating film CF. As such an antireflection film material, e.g., a polymer compound material containing an organic substance is used.

When it is difficult to adjust the thickness of the coating film CF, it may also be possible to form the coating film CF to a thickness sufficient to cover the stress application film 10 over the control gate electrode portion (laminated film portion including the control gate electrode CG and the cap insulating film), then etch back the entire surface of the coating film CF to retreat the top surface thereof, and expose the stress application film 10 over the control gate electrode portion (laminated film portion including the control gate electrode CG and the cap insulating film).

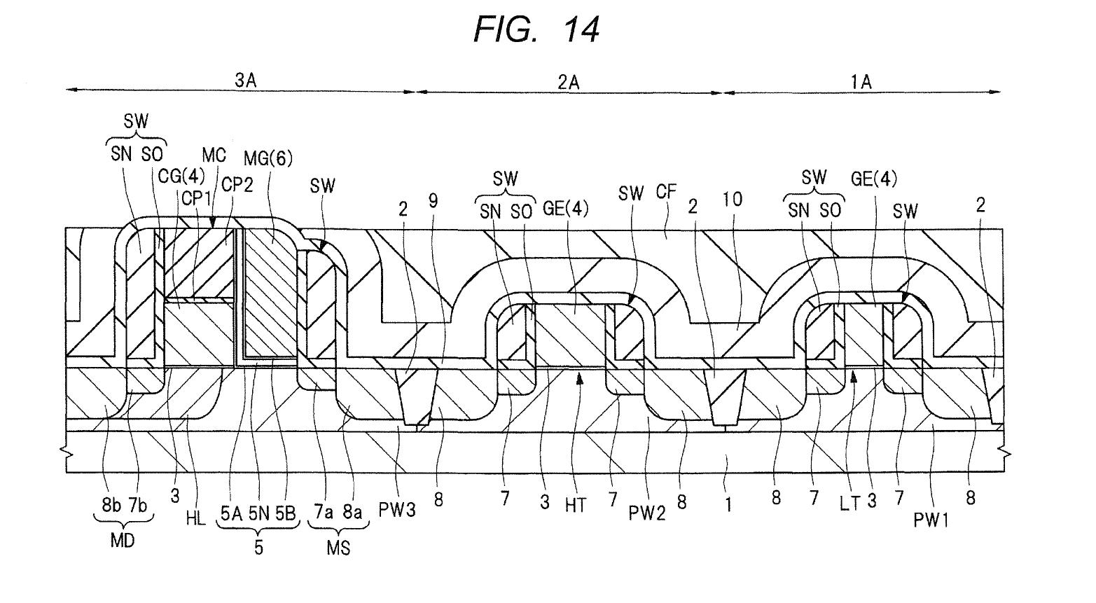

Next, as shown in FIG. 14, using the coating film CF as a mask, the stress application film 10 is etched. Here, the silicon nitride film forming the stress application film 10 is dry-etched. For example, using CH₄ as an etching gas, isotropic dry etching is performed. As a result, the core MIS formation region 1A and the I/O MIS formation region 2A are covered with the stress application film 10, while the stress application film 10 is removed from a part of the memory cell region 3A. In other words, it is possible to form an opening in the stress application film (silicon nitride film) 10 over the control gate electrode portion (laminated film portion including the control gate electrode CG and the cap insulating film) and the memory gate electrode MG. From the opening, the stopper film 9 is exposed.

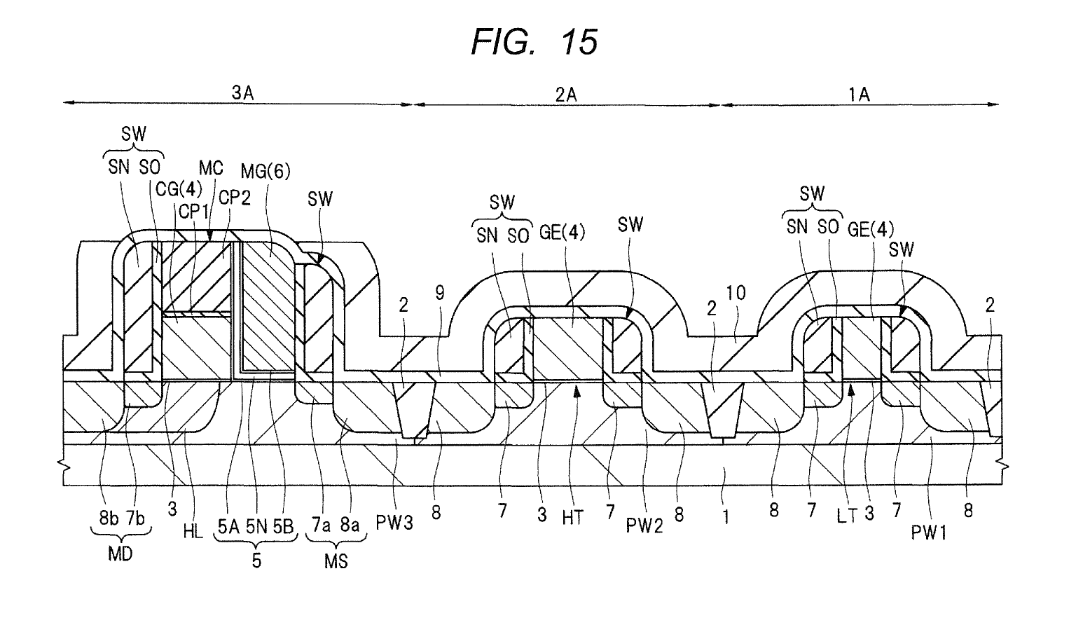

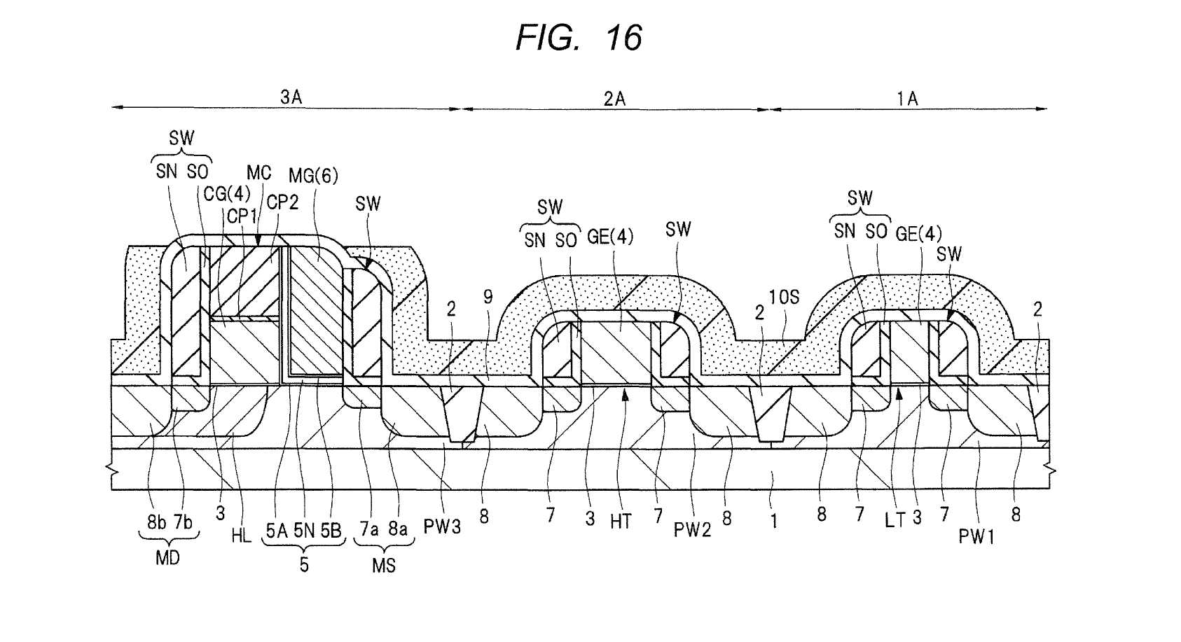

Next, as shown in FIG. 15, the coating film CF is etched to be removed. Then, as shown in FIG. 16, heat treatment (referred to also as anneal) is performed. For example, as first treatment, momentary anneal (referred to also as spike RTA) is performed at about 1000° C. for 1 second or less. Then, as second treatment, laser anneal is performed at about 1200° C. This causes a stress in the stress application film 10. The stress application film after the heat treatment, i.e., the stress application film to which the stress has been applied is designated by “10S”. The stress application film 10S applies the stress to each of the MISFET (LT) in the core MIS formation region 1A and the MISFET (HT) in the I/O MIS formation region 2A. On the other hand, the stress application film 10 has been partially removed from the memory cell region 3A so that no stress is applied to the memory cell MC.

Note that it may also be possible to activate the impurities introduced into the source region MS (the n⁻-type semiconductor region 7a and the n⁺-type semiconductor region 8a), the drain region MD (the n⁻-type semiconductor region 7b and the n⁺-type semiconductor region 8b), and the source/drain regions (7 and 8) and omit the previous heat treatment (activation treatment). It may also be possible to crystallize the silicon films 4 and 6 each made of an amorphous silicon film by the heat treatment (crystallization treatment).

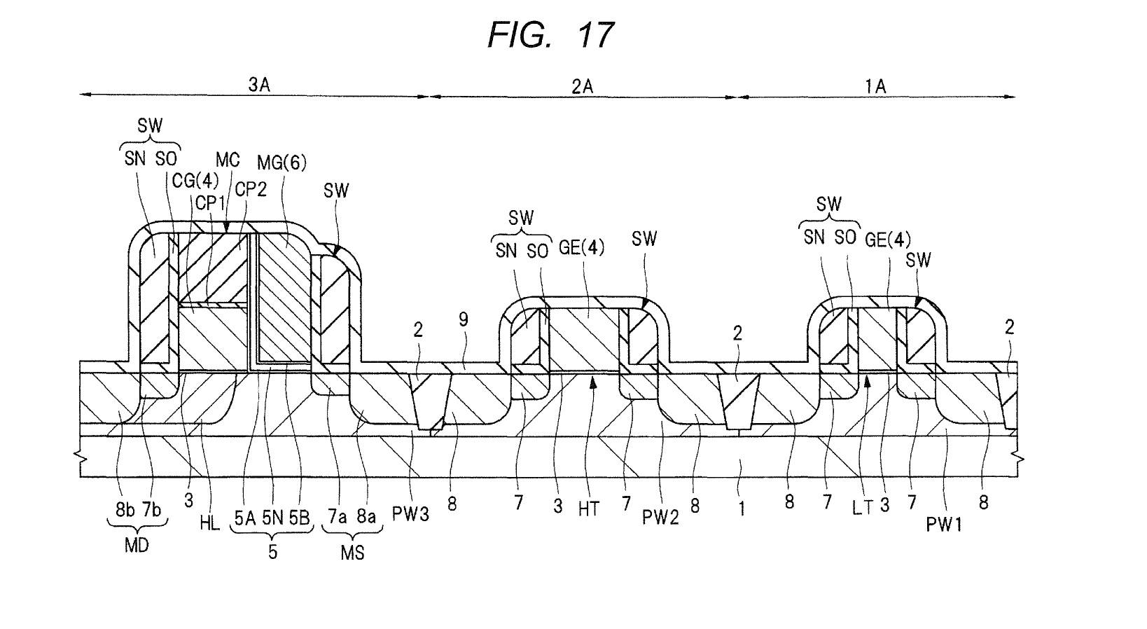

Next, as shown in FIG. 17, the stress application film 10S is removed. Here, the silicon nitride film forming the stress application film 10S is wet-etched under conditions which increase the etching selectivity, i.e., increase the ratio of the speed of etching the stopper film 9 to the speed of etching the stress application film 10S. For example, using a phosphoric acid (H₃PO₄) solution as an etchant, wet etching is performed at 155° C. for 600 seconds. This exposes the stopper film 9 in each of the core MIS formation region 1A, the I/O MIS formation region 2A, and the memory cell region 3A.

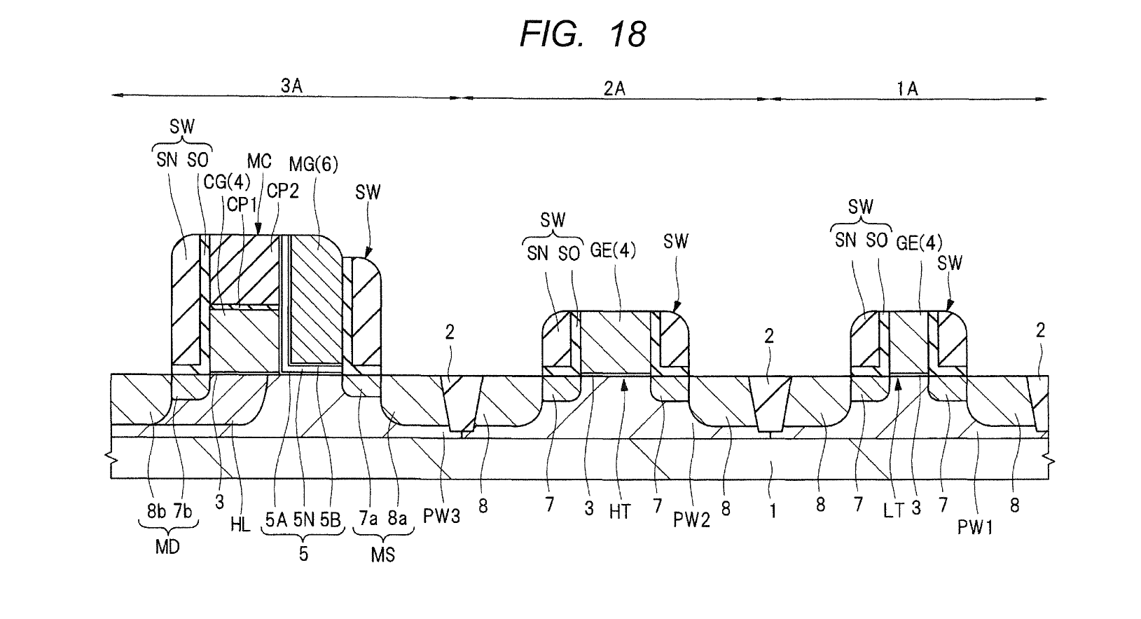

Next, as shown in FIG. 18, the foregoing stopper film 9 is removed. Here, the silicon dioxide film forming the stopper film 9 is etched under conditions which increase the etching selectivity, i.e., increase the ratio of the speed of etching the semiconductor substrate 1 to the speed of etching the stopper film 9. For example, using a HF solution as an etchant, wet etching is performed at 25° C. for 100 seconds.

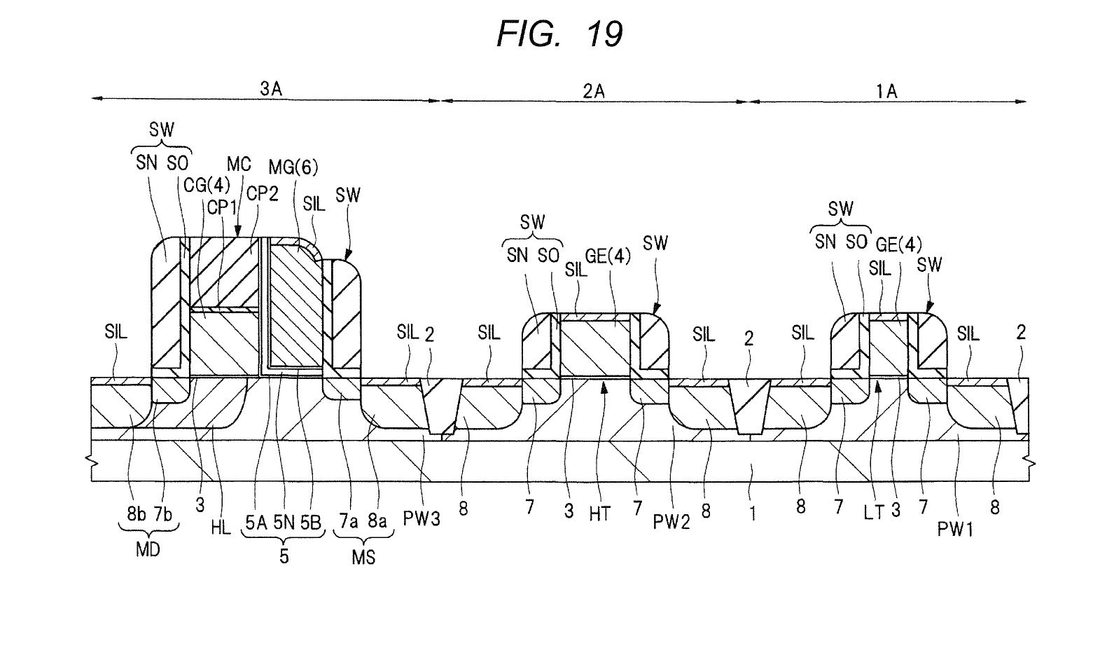

Next, as shown in FIG. 19, using a salicide technique, in the memory cell region 3A, metal silicide layers (metal silicide films) SIL are formed in the respective upper portions of the memory gate electrode MG, the n⁺-type semiconductor region 8a, and the n⁺-type semiconductor region 8b. Also, in the core MIS formation region 1A and the I/O MIS formation region 2A, the metal silicide layers SIL are formed in the respective upper portions of the gate electrodes GE and the n⁺-type semiconductor regions 8.

The metal silicide layers SIL can reduce diffusion resistance, contact resistance, and the like. The metal silicide layers SIL can be formed as follows.

For example, over the entire main surface of the semiconductor substrate 1, a metal film (not shown) is formed. By subjecting the semiconductor substrate 1 to heat treatment, the respective upper-layer portions of the memory gate electrode MG, the gate electrodes GE, and the n⁺-type semiconductor regions 8, 8a, and 8b are caused to react with the foregoing metal film. Thus, over the memory gate electrode MG, the gate electrodes GE, and the n⁺-type semiconductor regions 8, 8a, and 8b, the metal silicide layers SIL are formed. The foregoing metal film is made of, e.g., a cobalt (Co) film, a nickel (Ni) film, or the like and can be formed using a sputtering method or the like. Then, the unreacted metal film is removed.

Thereafter, over the entire main surface of the semiconductor substrate 1, an interlayer insulating film (not shown) is formed, though the illustration thereof is omitted. Then, in the interlayer insulating film, contact holes (not shown) are formed to expose, e.g., the top surfaces of the n⁺-type semiconductor regions 8, 8a, and 8b. In the contact holes, a conductive film is embedded to form plugs (not shown). Then, over the interlayer insulating film in which the plugs are embedded, wires (not shown) are formed (see Embodiment 2 described later).

Thus, according to the present embodiment, the SMT is applied to the MISFET (LT) and the MISFET (HT) among the MISFET (LT), the MISFET (HT), and the memory cell MC. This can generally improve the properties of the semiconductor device.

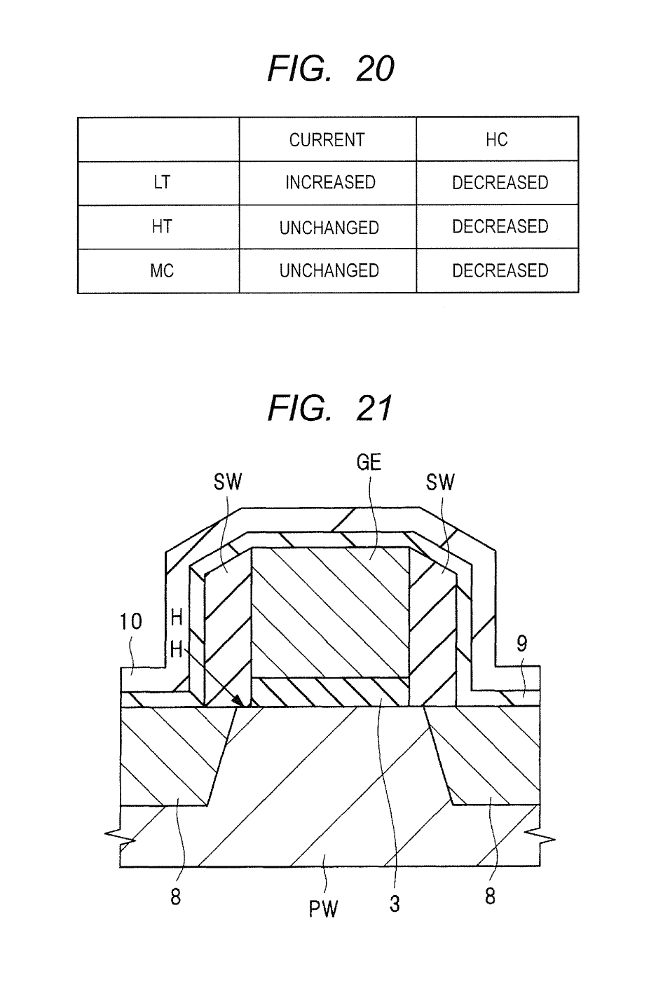

As a result of examining the case where the SMT is applied to each of the MISFET (LT), the MISFET (HT), and the memory cell MC, the present inventors have obtained the result shown in FIG. 20. FIG. 20 is a view showing the properties of the MISFET (LT), the MISFET (HT), and the memory cell MC after the application of the SMT thereto.

That is, the present inventors have examined the case where heat treatment was performed in a state where the silicon nitride film as the stress application film 10 was present over each of the core MIS formation region 1A, the I/O MIS formation region 2A, and the memory cell region 3A to apply a stress to each of the elements.

As shown in FIG. 20, in the MISFET (LT), an increase in channel current (simply shown as “Current” in FIG. 20) due to the effect of the SMT could be recognized. However, channel currents in the MISFET (HT) and the memory cell MC remained unchanged. This may be conceivably because, in the MISFET (HT) and the memory cell MC each having a relatively large gate length, the effect of the SMT is insufficient and the channel currents did not increase.

On the other hand, HC decreased in each of the elements which are the MISFET (LT), the MISFET (HT), and the memory cell MC. Here, “HC” shows deterioration caused by hot carriers. For example, the time required for a 10% reduction in channel current is defined as a HC lifetime. It can be considered that HC is under the influence of hydrogen (H) contained in the silicon nitride film used as the stress application film 10.

FIG. 21 is a cross-sectional view of a MISFET provided with a silicon nitride film as a stress application film. The members of the MISFET shown in FIG. 21 which have the same functions as those of the MISFET (HT) shown in FIG. 1 are designated by the same reference numerals and a repeated description thereof is omitted. Note that PW shows a p-type well.

As shown in FIG. 21, the silicon nitride film used as the stress application film 10 contains a large number of H (hydrogen) elements. When the silicon nitride film 10 is formed by a CVD method using a hydrogen compound as a raw material, the film contains a particularly large number of H (hydrogen) elements.

By the heat treatment for applying a stress, H (hydrogen) in the silicon nitride film is diffused into the MISFET. For example, when H (hydrogen) reaches the interface between the semiconductor substrate 1 (p-type well) and the insulating film 3, H (hydrogen) is bonded to silicon (Si) to generate a Si—H bond. When hot carriers are generated in the drain region to which a high potential is applied while the MISFET is driven, the Si—H bond is broken to result in an interface state. When a larger number of such interface states are formed, the carriers are trapped thereby, which degrades the driving ability of the MISFET.

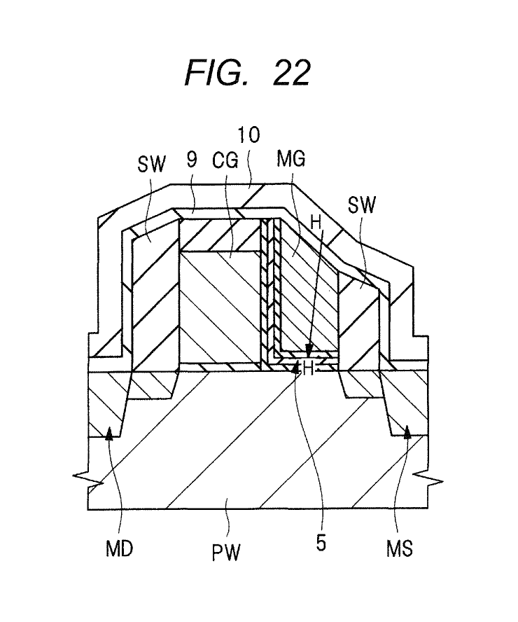

FIG. 22 is a cross-sectional view of a memory cell provided with a silicon nitride film as a stress application film. The members of the memory cell shown in FIG. 22 which have the same functions as those of the memory cell MC shown in FIG. 1 are designated by the same reference numerals and a repeated description thereof is omitted. Note that PW shows a p-type well.

As shown in FIG. 22, H (hydrogen) in the silicon nitride film used as the stress application film 10 is diffused into the memory cell by the heat treatment for applying a stress. For example, when H (hydrogen) reaches the silicon nitride film 5N as the middle layer included in the insulating film (ONO film) 5, shallow trap levels increase in the charge storage portion of the memory cell. When charges to be written to the memory cell are retained by such shallow trap levels, the charges are more likely to leak away to degrade the retaining property of the memory cell.

By contrast, in the present embodiment, the SMT is not applied to the memory cell MC on which the SMT exerts a poor effect. Since the stress application film (silicon nitride film) 10 has been removed from over the memory cell MC, it is possible to avoid the degradation of the properties of the memory cell MC due to H (hydrogen) in the foregoing silicon nitride film. That is, it is possible to allow H (hydrogen) to escape from the opening of the stress application film (silicon nitride film) 10 over the memory cell MC.

In the case of using an SSI method or a BTBT phenomenon which uses driving using hot carriers (e.g., when hot carriers (hot electrons or hot holes) are used for a write operation or an erase method), the influence of H (hydrogen) is large (see also Embodiment 2). By contrast, in the case of using a FN (Fowler Nordheim) tunneling phenomenon, the effect of H (hydrogen) is small. In the case of thus using hot carriers for a write or erase method, the application of the present embodiment is effective.

It will easily be appreciated that, in the MISFET (LT), the SMT allows an improvement in channel current.

In the MISFET (HT), the effect of the SMT is poor. The HC decreases due to H (hydrogen) in the silicon nitride film (see FIG. 20), but the degree of the HC decrease is not so large as in the memory cell MC and is, e.g., about 10% of the HC decrease in the memory cell. Accordingly, even when the stress application film (silicon nitride film) 10 is left over the MISFET (HT), the influence of the HC decrease is small. Therefore, in the present embodiment, the SMT is applied also to the MISFET (HT).

Note that the opening of the stress application film (silicon nitride film) 10 over the control gate electrode portion (laminated film portion including the control gate electrode CG and the cap insulating film) and the memory gate electrode MG may also be formed by patterning (etching using an exposed photoresist film as a mask).

In the present embodiment, the SMT is applied also to the MISFET (HT). However, it may also be possible not to apply the SMT to the MISFET (HT) by, e.g., removing the stress application film 10 from the I/O MIS formation region 2A. Alternatively, as shown in Embodiment 3 described later, the application of the SMT to the MISFET (HT) may also be avoided similarly to the application of the SMT to the memory cell MC.

Thus, of the stress application film (silicon nitride film) 10 formed over the entire surface, the stress application film (silicon nitride film) 10 over the control gate electrode portion (laminated film portion including the control gate electrode CG and the cap insulating film) and the memory gate electrode MG is partially removed. This allows selective application of the SMT and allows general improvements in the properties of the semiconductor device.

Also, in the present embodiment, the MISFET (LT) and the MISFET (HT) have been described using the n-channel MISFETs as an example. However, by the study conducted by the present inventors, it has been confirmed that the same effects are achieved also by p-channel MISFETs. That is, in the case of using p-channel MISFETs as the MISFET (LT) and the MISFET (HT) also, the same effects are achieved.

### Embodiment 2

### Structure of Semiconductor Device

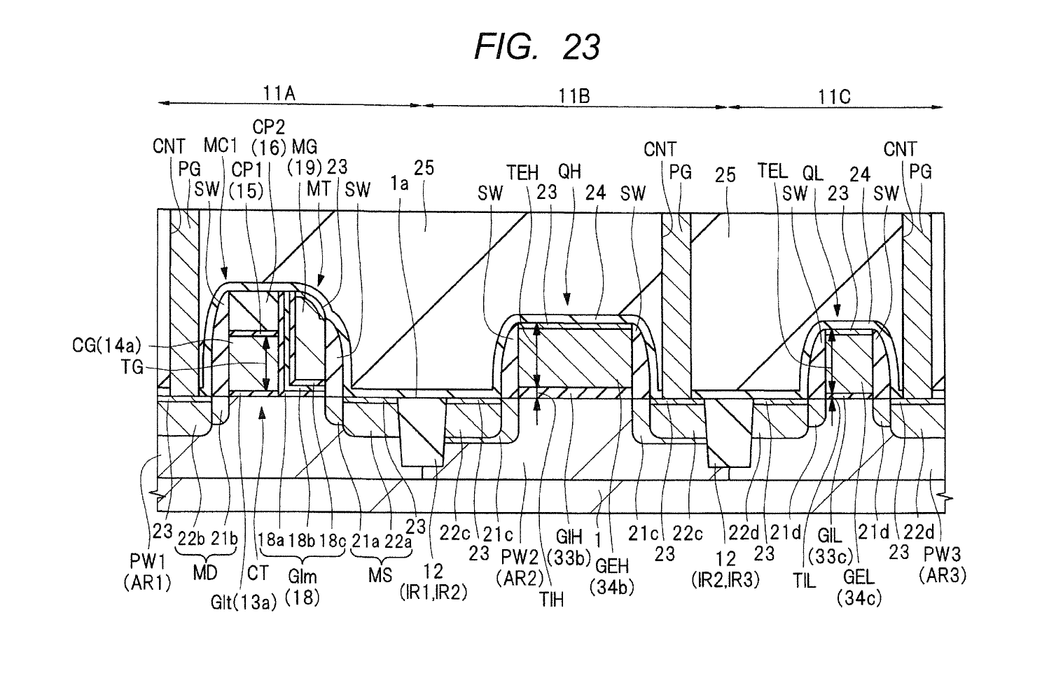

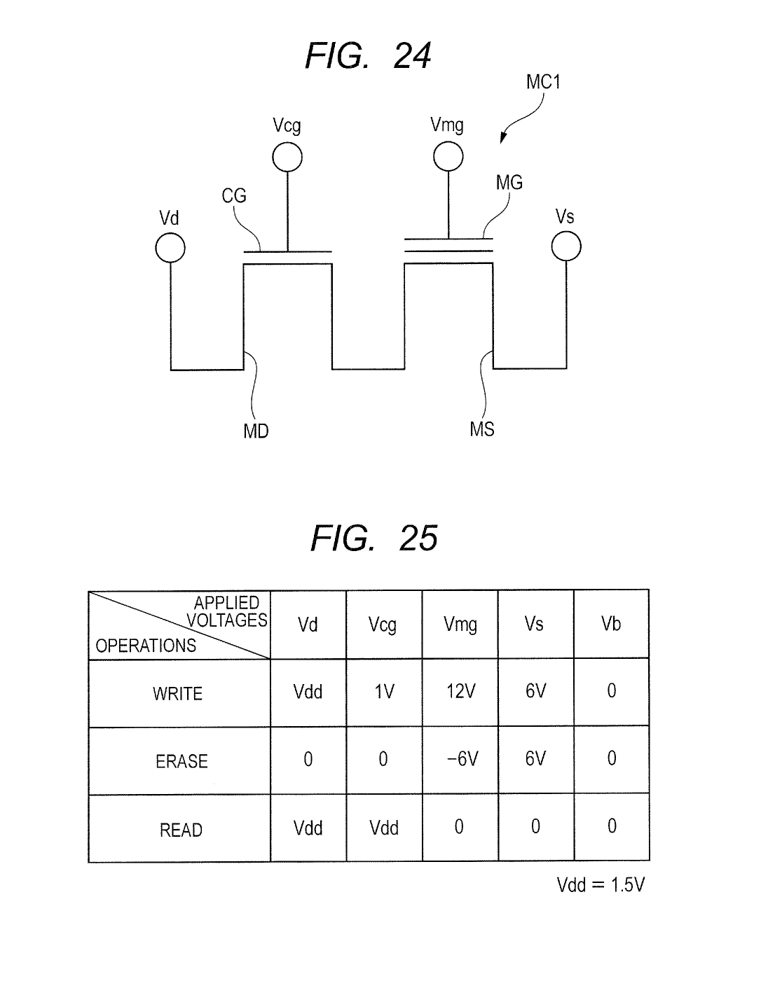

First, a structure of a semiconductor device in Embodiment 2 will be described with reference to the drawings. FIG. 23 is a main-portion cross-sectional view of the semiconductor device in Embodiment 2. FIG. 24 is an equivalent circuit diagram of a memory cell in the semiconductor device in Embodiment 2.

As shown in FIG. 23, the semiconductor device includes the semiconductor substrate 1. The semiconductor substrate 1 is a semiconductor wafer made of, e.g., p-type monocrystalline silicon having a specific resistance of, e.g., about 1 to 10 Ωcm or the like.

The semiconductor device has a memory cell region 11A, and peripheral circuit regions 11B and 11C as local areas of the main surface 1a of the semiconductor substrate 1. In the memory cell region 11A, a memory cell MC1 is formed. In the peripheral circuit region 11B, a MISFET QH is formed. In the peripheral circuit region 11C, a MISFET QL is formed. The memory cell region 11A and the peripheral circuit region 11B need not be adjacent to each other. The memory cell region 11A and the peripheral circuit region 11C need not be adjacent to each other. The peripheral circuit regions 11B and 11C need not be adjacent to each other. However, for easier understanding, in the cross-sectional view of FIG. 23, the peripheral circuit region 11B is shown next to the memory cell region 11A, and the peripheral circuit region 11C is shown next to the peripheral circuit region 11B.

Here, peripheral circuits are circuits other than a nonvolatile memory, such as, e.g., a processor such as a CPU (Central Processing Unit), a control circuit, a sense amplifier, a column decoder, a row decoder, and an input/output circuit. The MISFET QH formed in the peripheral circuit region 11B and the MISFET QL formed in the peripheral circuit region 11C are MISFETs for peripheral circuits.

The peripheral circuit region 11B is a higher-voltage MIS (Metal Insulator Semiconductor) region, while the peripheral circuit region 11C is a lower-voltage MIS region. Accordingly, the MISFET QH formed in the peripheral circuit region 11B is a higher-breakdown-voltage MISFET, while the MISFET QL formed in the peripheral circuit region 11C is a lower-breakdown-voltage MISFET. By including the higher-voltage MIS region and the lower-voltage MIS region, the peripheral circuit regions allow various circuits to be formed therein.

First, a configuration of the memory cell MC1 formed in the memory cell region 11A will specifically be described.

In the memory cell region 11A, the semiconductor device has an active region AR1, and an isolation region IR1. The isolation region IR1 is for isolating an element. In the isolation region IR1, an isolation film 12 is formed. The active region AR1 is defined, i.e., demarcated by the isolation region IR1 and electrically isolated from another active region by the isolation region IR1. In the active region AR1, the p-type well PW1 is formed. That is, the active region AR1 is a region where the p-type well PW1 is formed. The p-type well PW1 has a p-type conductivity type.

As shown in FIG. 23, in the p-type well PW1 of the memory cell region 11A, the memory cell MC1 including a memory transistor MT, and a control transistor CT is formed. In the memory cell region 11A, a plurality of the memory cells MC1 are actually formed in an array configuration, and FIG. 23 shows a cross section of one of the memory cells MC1. The memory cell MC1 is included in the nonvolatile memory provided in the semiconductor device.

The memory cell MC1 is a split-gate memory cell. That is, as shown in FIG. 23, the memory cell MC1 includes the control transistor CT having the control gate electrode CG, and the memory transistor MT coupled to the control transistor CT and having the memory gate electrode MG.

As shown in FIG. 23, the memory cell MC1 includes the n-type semiconductor region MS, the n-type semiconductor region MD, the control gate electrode CG, and the memory gate electrode MG. Each of the n-type semiconductor regions MS and MD has an n-type conductivity type opposite to the p-type conductivity type. The memory cell MC1 also includes the cap insulating film CP1 formed over the control gate electrode CG, and the cap insulating film CP2 formed over the cap insulating film CP1. The memory cell MC1 also includes a gate insulating film GIt formed between the control gate electrode CG and the p-type well PW1 of the semiconductor substrate 1, and a gate insulating film GIm formed between the memory gate electrode MG and the control gate electrode CG.

The control gate electrodes CG and the memory gate electrode MG are juxtaposed to extend along the main surface 1a of the semiconductor substrate 1 in a state where the gate insulating film GIm is interposed between the respective side surfaces, i.e., side walls thereof facing each other. The directions in which the control gate electrode CG and the memory gate electrode MG extend are perpendicular to the surface of a paper sheet with FIG. 23. The control gate electrode CG is formed over the portion of the p-type well PW1 which is located between the semiconductor regions MD and MS, i.e., over the main surface 1a of the semiconductor substrate 1 via the gate insulating film GIt. The memory gate electrode MG is formed over the portion of the p-type well PW1 which is located between the semiconductor regions MD and MS, i.e., over the main surface 1a of the semiconductor substrate 1 via the gate insulating film GIm. The memory gate electrode MG is disposed closer to the semiconductor region MS, while the control gate electrode CG is disposed closer to the semiconductor region MD. The control gate electrode CG and the memory gate electrode MG are gate electrodes forming the memory cell MC1, i.e., the nonvolatile memory.

Note that the cap insulating films CP1 and CP2 formed over the control gate electrode CG also extend along the main surface 1a of the semiconductor substrate 1.

The control gate electrode CG and the memory gate electrode MG are adjacent to each other with the gate insulating film GIm being interposed therebetween. The memory gate electrode MG is formed in a sidewall spacer shape over the side surface, i.e., side wall of the control gate electrode CG via the gate insulating film GIm. The gate insulating film GIm extends over two regions which are the region between the memory gate electrode MG and the p-type well PW1 of the semiconductor substrate 1 and the region between the memory gate electrode MG and the control gate electrode CG.

The gate insulating film GIt formed between the control gate electrode CG and the p-type well PW1 functions as the gate insulating film of the control transistor CT. The gate insulating film GIm formed between the memory gate electrode MG and the p-type well PW1 functions as the gate insulating film of the memory transistor MT.

The gate insulating film GIt is made of an insulating film 13a. The insulating film 13a is made of a silicon dioxide film, a silicon nitride film, a silicon oxynitride film, or a high-dielectric-constant film having a specific permittivity higher than that of a silicon nitride film, i.e., so-called High-k film. Note that, when a High-k film or high-dielectric-constant film is mentioned in the present application, the film means a film having a dielectric constant (specific permittivity) higher than that of a silicon nitride film. As the insulating film 13a, a metal oxide film such as, e.g., a hafnium oxide film, a zirconium oxide film, an aluminum oxide film, a tantalum oxide film, or a lanthanum oxide film can be used.

The gate insulating film GIm is made of an insulating film 18. The insulating film 18 is made of a laminated film including a silicon dioxide film 18a, a silicon nitride film 18b as a charge storage portion over the silicon dioxide film 18a, and a silicon dioxide film 18c over the silicon nitride film 18b and referred to as an ONO film. Note that, as described above, the gate insulating film GIm between the memory gate electrode MG and the p-type well PW1 functions as the gate insulating film of the memory transistor MT. On the other hand, the gate insulating film GIm between the memory gate electrode MG and the control gate electrode CG functions as an insulating film for providing insulation, i.e., electrical isolation between the memory gate electrode MG and the control gate electrode CG.

Of the insulating film 18, the silicon nitride film 18b is an insulating film for storing therein charges and functions as the charge storage portion. That is, the silicon nitride film 18b is a trapping insulating film formed in the insulating film 18. Therefore, the insulating film 18 can be regarded as an insulating film having an internal charge storage portion.

Each of the silicon dioxide films 18c and 18a located over and under the silicon nitride film 18b can function as a charge blocking layer which confines charges. By providing a structure in which the silicon nitride film 18b is interposed between the silicon dioxide films 18c and 18a, charges can be stored in the silicon nitride film 18b. As described above, the silicon dioxide film 18a, the silicon nitride film 18b, and the silicon dioxide film 18c can also be regarded as the ONO film.

The control gate electrode CG is made of a conductive film 14a. The conductive film 14a is made of silicon and made of, e.g., an n-type polysilicon film as a polycrystalline silicon film into which an n-type impurity has been introduced or the like. Specifically, the control gate electrode CG is made of the patterned conductive film 14a.

The memory gate electrode MG is made of a conductive film 19. The conductive film 19 is made of silicon and made of, e.g., an n-type polysilicon film as a polycrystalline silicon film into which an n-type impurity has been introduced or the like. The memory gate electrode MG is formed by anisotropically etching, i.e., etching back the conductive film 19 formed over the semiconductor substrate 1 so as to cover the control gate electrode CG and leaving the conductive film 19 over the side wall of the control gate electrode CG via the insulating film 18. Consequently, the memory gate electrode MG is formed in a sidewall spacer shape over the side wall of the control gate electrode CG adjacent to the memory gate electrode MG which is located on a first side thereof via the insulating film 18.

Over the control gate electrode CG, the cap insulating film CP2 is formed via the cap insulating film CP1. Consequently, the memory gate electrode MG is formed in a sidewall spacer shape over the side wall of the cap insulating film CP2 formed over the control gate electrode CG adjacent to the memory gate electrode MG which is located on the first side thereof via the insulating film 18.

The cap insulating film CP1 is made of an insulating film containing silicon and oxygen. The insulating film 15 is made of, e.g., a silicon dioxide film or the like. The cap insulating film CP2 is made of an insulating film 16 containing silicon and nitrogen. The insulating film 16 is made of, e.g., a silicon nitride film or the like.

The cap insulating film CP2 is a protective film which protects the control gate electrode CG, and is also a hard mask film when the conductive film 14 is patterned to form the control gate electrode CG or a spacer film for adjusting the height of the memory gate electrode MG when the conductive film is etched back to form the memory gate electrode MG. By forming the cap insulating film CP2 as the spacer film, the film thickness of the control gate electrode CG can be set smaller than the height of the memory gate electrode MG.

The semiconductor region MS functions as one of a source region and a drain region. The semiconductor region MD functions as the other of the source region and the drain region. Here, the semiconductor region MS functions as, e.g., the source region, and the semiconductor region MD functions as, e.g., the drain region. Each of the semiconductor regions MS and MD is made of a semiconductor region into which an n-type impurity has been introduced and has an LDD (Lightly doped drain) structure.

The source semiconductor region MS includes an n⁻-type semiconductor region 21a, and an n⁺-type semiconductor region 22a having an impurity concentration higher than that of the n⁻-type semiconductor region 21a. The drain semiconductor region MD includes an n⁻-type semiconductor region 21b, and an n⁺-type semiconductor region 22b having an impurity concentration higher than that of the n⁻-type semiconductor region 21b. The n⁺-type semiconductor region 22a has a junction depth deeper than that of the n⁻-type semiconductor region 21a and an impurity concentration higher than that thereof. The n⁺-type semiconductor region 22b has a junction depth deeper than that of the n⁻-type semiconductor region 21b and an impurity concentration higher than that thereof.

Over the respective side walls of the memory gate electrode MG and the control gate electrode CG which are not adjacent to each other, the sidewall spacers SW each made of an insulating film such as a silicon dioxide film, a silicon nitride film, or a laminated film thereof are formed. That is, over the side wall, i.e., side surface of the memory gate electrode MG opposite to the side surface thereof adjacent to the control gate electrode CG via the gate insulating film GIm and over the side wall, i.e., side surface of the control gate electrode CG opposite to the side surface thereof adjacent to the memory gate electrode MG via the gate insulating film GIm, the sidewall spacers SW are formed.

Note that, between the memory gate electrode MG and the sidewall spacer SW, between the control gate electrode CG and the sidewall spacer SW, and between the control gate electrode CG and the gate insulating film GIm, sidewall insulating films not shown may also be interposed.

The n⁻-type semiconductor region 21a is formed by self-alignment with the side surface of the memory gate electrode MG. The n⁺-type semiconductor region 22a is formed by self-alignment with the side surface of the sidewall spacer SW. Accordingly, the lower-concentration n⁻-type semiconductor region 21a is formed under the sidewall spacer SW over the side wall of the memory gate electrode MG, while the higher-concentration n⁺-type semiconductor region 22a is formed outside the lower-concentration n⁻-type semiconductor region 21a. Consequently, the lower-concentration n⁻-type semiconductor region 21a is formed so as to be adjacent to the p-type well PW1 as the channel region of the memory transistor MT. On the other hand, the higher-concentration n⁺-type semiconductor region 22a is formed in contact with the lower-concentration n⁻-type semiconductor region 21a so as to be spaced apart from the p-type well PW1 as the channel region of the memory transistor MT by the distance corresponding to the n⁻-type semiconductor region 21a.

The n⁻-type semiconductor region 21b is formed by self-alignment with the side surface of the control gate electrode CG. The n⁺-type semiconductor region 22b is formed by self-alignment with the side surface of the sidewall spacer SW. Accordingly, the lower-concentration n⁻-type semiconductor region 21b is formed under the sidewall spacer SW over the side wall of the control gate electrode CG, while the higher-concentration n⁺-type semiconductor region 22b is formed outside the lower-concentration n⁻-type semiconductor region 21b. Consequently, the lower-concentration n⁻-type semiconductor region 21b is formed so as to be adjacent to the p-type well PW1 as the channel region of the control transistor CT. On the other hand, the higher-concentration n⁺-type semiconductor region 22b is formed in contact with the lower-concentration n⁻-type semiconductor region 21b so as to be spaced apart from the p-type well PW1 as the channel region of the control transistor CT by the distance corresponding to the n⁻-type semiconductor region 21b.

Under the gate insulating film GIm under the memory gate electrode MG, the channel region of the memory transistor is formed. Under the gate insulating film GIt under the control gate electrode CG, the channel region of the control transistor CT is formed.

Over the n⁺-type semiconductor region 22a or n⁺-type semiconductor region 22b, i.e., over the upper surface of the n⁺-type semiconductor region 22a or n⁺-type semiconductor region 22b, a metal silicide layer 23 is formed using a salicide (Self Aligned Silicide) technique or the like. The metal silicide layer 23 is made of, e.g., a cobalt silicide layer, a nickel silicide layer, a platinum-added nickel silicide layer, or the like. The metal silicide layer 23 allows a reduction in diffusion resistance or contact resistance. Note that the metal silicide layer 23 may also be formed over the memory gate electrode MG.

Next, a configuration of the higher-breakdown-voltage MISFET QH formed in the peripheral circuit region 11B will specifically be described.

In the peripheral circuit region 11B, the semiconductor device includes an active region AR2, and an isolation region IR2. The isolation region IR2 is for isolating an element. In the isolation region IR2, the isolation film 12 is formed. The active region AR2 is defined, i.e., demarcated by the isolation region IR2 and electrically isolated from another active region by the isolation region IR2. In the active region AR2, the p-type well PW2 is formed. That is, the active region AR2 is a region where the p-type well PW2 is formed. The p-type well PW2 has the p-type conductivity type.

Note that, as previously stated, in the cross-sectional view of FIG. 23, for easier understanding, the peripheral circuit region 11B is shown next to the memory cell region 11A. Accordingly, the cross-sectional view of FIG. 23 shows an example in which the isolation region IR1 of the memory cell region 11A also serves as the isolation region IR2 of the peripheral circuit region 11B.

As shown in FIG. 23, in the p-type well PW2 of the peripheral circuit region 11B, the higher-breakdown-voltage MISFET QH is formed. In the peripheral circuit region 11B, a plurality of the higher-breakdown-voltage MISFETs QH are actually formed, and FIG. 23 shows a cross section of one of the higher-breakdown-voltage MISFETs QH perpendicular to a gate width direction.

As shown in FIG. 23, the higher-breakdown-voltage MISFET QH includes semiconductor regions each including an n⁻-type semiconductor region 21c, and an n⁺-type semiconductor region 22c, a gate insulating film GIH formed over the p-type well PW2, and a gate electrode GEH formed over the gate insulating film GIH. Each of the n⁻-type semiconductor region 21c and the n⁺-type semiconductor region 22c is formed in the upper-layer portion of the p-type well PW2 of the semiconductor substrate 1. Each of the n⁻-type semiconductor region 21c and the n⁺-type semiconductor region 22c has the n-type conductivity type opposite to the p-type conductivity type.

The gate insulating film GIH functions as the gate insulating film of the MISFET QH. The gate insulating film GIH is made of an insulating film 33b. The insulating film 33b is made of a silicon dioxide film, a silicon nitride film, a silicon oxynitride film, or a high-dielectric-constant film having a relative permittivity higher than that of a silicon nitride film, i.e., so-called High-k film. As the insulating film 33b made of a High-k film, a metal oxide film such as, e.g., a hafnium oxide film, a zirconium oxide film, an aluminum oxide film, a tantalum oxide film, or a lanthanum oxide film can be used.

The gate electrode GEH is made of a conductive film 34b. The conductive film 34b is made of silicon and made of, e.g., an n-type polysilicon film as a polycrystalline silicon film into which an n-type impurity has been introduced or the like.

Specifically, the gate electrode GEH is made of the patterned conductive film 34b. As the conductive film 34b, another conductive film other than the conductive film 14a included in the control gate electrode CG can be used. This allows a film thickness TEH of the gate electrode GEH to have a value different from that of a film thickness TG of the control gate electrode CG.

Note that, when the metal silicide layer 23 is formed over the gate electrode GEH, the film thickness TEH of the gate electrode GEH can be defined as the distance from the lower surface of the gate electrode GEH to the upper surface of the metal silicide layer 23 formed over the gate electrode GEH.

Each of the semiconductor regions including the n⁻-type semiconductor region 21c and the n⁺-type semiconductor region 22c is a source or drain semiconductor region into which an n-type impurity has been introduced. Similarly to the semiconductor regions MS and MD of the memory cell MC1, the semiconductor region has an LDD structure. That is, the n⁺-type semiconductor region 22c has a junction depth deeper than that of the n⁻-type semiconductor region 21c and an impurity concentration higher than that thereof.

Over the side walls of the gate electrode GEH, the sidewall spacers SW each made of an insulating film such as a silicon dioxide film, a silicon nitride film, or a laminated film thereof are formed.

Over each of the n⁺-type semiconductor regions 22c, i.e., over the upper surface of each of the n⁺-type semiconductor regions 22c, the metal silicide layer 23 is formed using a salicide technique or the like, in the same manner as over the n⁺-type semiconductor region 22a or the n⁺-type semiconductor region 22b in the memory cell MC1. Note that the metal silicide layer 23 may also be formed over the gate electrode GEH.

Next, a configuration of the lower-breakdown-voltage MISFET QL formed in the peripheral circuit region 11c will specifically be described.

In the peripheral circuit region 11C, the semiconductor device includes an active region AR3, and an isolation region IR3. The isolation region IR3 is for isolating an element. In the isolation region IR3, the isolation film 12 is formed. The active region AR3 is defined, i.e., demarcated by the isolation region IR3 and electrically isolated from another active region by the isolation region IR3. In the active region AR3, the p-type well PW3 is formed. That is, the active region AR3 is a region where the p-type well PW3 is formed. The p-type well PW3 has the p-type conductivity type.

Note that, as previously stated, in the cross-sectional view of FIG. 23, for easier understanding, the peripheral circuit region 11C is shown next to the peripheral circuit region 11B. Accordingly, the cross-sectional view of FIG. 23 shows an example in which the isolation region IR2 of the peripheral circuit region 11C also serves as the isolation region IR3 of the peripheral circuit region 11C.

As shown in FIG. 23, in the p-type well PW3 of the peripheral circuit region 11C, the lower-breakdown-voltage MISFET QL is formed. In the peripheral circuit region 11C, a plurality of the MISFETs QL are actually formed, and FIG. 1 shows a cross section of one of the MISFETs QL perpendicular to the gate width direction.

As shown in FIG. 23, the lower-breakdown-voltage MISFET QL includes semiconductor regions each including an n⁻-type semiconductor region 21d, and an n⁺-type semiconductor region 22d, a gate insulating film GIL formed over the p-type well PW3, and a gate electrode GEL formed over the gate insulating film GIL. Each of the n⁻-type semiconductor region 21d and the n⁺-type semiconductor region 22d is formed in the upper-layer portion of the p-type well PW3 of the semiconductor substrate 1. Each of the n⁻-type semiconductor region 21d and the n⁺-type semiconductor region 22d has the n-type conductivity type opposite to the p-type conductivity type.

The gate insulating film GIL functions as the gate insulating film of the MISFET QL. The gate insulating film GIL is made of an insulating film 33c. As the insulating film 33c, an insulating film formed in the same layer as that of the insulating film 33b included in the gate insulating film GIH of the MISFET QH can be used.

The gate electrode GEL is made of a conductive film 34c. As the conductive film 34c, a conductive film formed in the same layer as that of the conductive film 34b included in the gate electrode GEH of the MISFET QH can be used. In addition, a film thickness TEL of the gate electrode GEL can be set equal to the film thickness TEH of the gate electrode GEH.

Note that, when the metal silicide layer 23 is formed over the gate electrode GEL, the film thickness TEL of the gate electrode GEL can be defined as the distance from the lower surface of the gate electrode GEL to the upper surface of the metal silicide layer 23 formed over the gate electrode GEL.

Each of the semiconductor regions including the n⁻-type semiconductor region 21d and the n⁺-type semiconductor region 22d is a source or drain semiconductor region into which an n-type impurity has been introduced. Similarly to the semiconductor regions MS and MD of the memory cell MC1, the semiconductor region has an LDD structure. That is, the n⁺-type semiconductor region 22d has a junction depth deeper than that of the n⁻-type semiconductor region 21d and an impurity concentration higher than that thereof.

Over the side walls of the gate electrode GEL, the sidewall spacers SW each made of an insulating film such as a silicon dioxide film, a silicon nitride film, or a laminated film thereof are formed.

Over each of the n⁺-type semiconductor regions 22d, i.e., over the upper surface of each of the n⁺-type semiconductor regions 22d, the metal silicide layer 23 is formed using a salicide technique or the like, in the same manner as over the n⁺-type semiconductor region 22a or the n⁺-type semiconductor region 22b in the memory cell MC1. Note that the metal silicide layer 23 may also be formed over the gate electrode GEL.

Note that the lower-breakdown-voltage MISFET QL may also have a halo region, though the illustration thereof is omitted. The conductivity type of the halo region is opposite to the conductivity type of the n⁻-type semiconductor region 21d and the same as the conductivity type of the p-type well PW3. The halo region is formed so as to suppress a short-channel property (punch-through). The halo region is formed so as to wrap around the n⁻-type semiconductor region 21d. The p-type impurity concentration in the halo region is higher than the p-type impurity concentration in the p-type well PW3.

As previously stated, the MISFET QH formed in the peripheral circuit region 11B is the higher-breakdown-voltage MISFET, and the MISFET QL formed in the peripheral circuit region 11c is the lower-breakdown-voltage MISFET. The higher-breakdown-voltage MISFET QH is, e.g., an element used in a circuit which receives/outputs a current between the semiconductor device and a device outside the semiconductor device. On the other hand, the lower-breakdown-voltage MISFET QL is, e.g., an element included in a logic circuit or the like and required to operate at a high speed. Accordingly, the gate length of the higher-breakdown-voltage MISFET QH is larger than the gate length of the lower-breakdown-voltage MISFET QL. Also, the drive voltage of the higher-breakdown-voltage MISFET QH is higher than that of the lower-breakdown-voltage MISFET QL, and the breakdown voltage of the higher-breakdown-voltage MISFET QH is higher than the breakdown voltage of the lower-breakdown-voltage MISFET QL.

A film thickness TIH of the gate insulating film GIH is preferably larger than a film thickness TIL of the gate insulating film GIL. This allows the drive voltage of the higher-breakdown-voltage MISFET QH to be higher than the drive voltage of the lower-breakdown-voltage MISFET QL.

Alternatively, a p-type impurity concentration in the p-type well PW2 is preferably lower than a p-type impurity concentration in the p-type well PW3. This allows the drive voltage of the higher-breakdown-voltage MISFET QH to be higher than the drive voltage of the lower-breakdown-voltage MISFET QL.

Note that the depth position of the lower surface of each of the n⁻-type semiconductor regions 21c can be set deeper than the depth position of the lower surface of each of the n⁻-type semiconductor regions 22d, and the depth position of the lower surface of each of the n⁺-type semiconductor regions 22c can be set deeper than the depth position of the lower surface of each of the n⁺-type semiconductor regions 22d. At this time, in the higher-breakdown-voltage MISFET QH, the depth position of the lower surface of the n⁺-type semiconductor region 22c is shallower than the depth position of the lower surface of the n⁻-type semiconductor region 21c. On the other hand, in the lower-breakdown-voltage MISFET QL, the depth position of the lower surface of the n⁺-type semiconductor region 22d is deeper than the depth position of the lower surface of the n⁻-type semiconductor region 21d.

Next, a configuration above each of the memory cell MC1 formed in the memory cell region 11A, the MISFET QH formed in the peripheral circuit region 11B, and the MISFET QL formed in the peripheral circuit region 11C will specifically be described.

Over the semiconductor substrate 1, an insulating film 24 is formed so as to cover the cap insulating film CP2, the gate insulating film GIm, the memory gate electrode MG, the gate electrode GEH, the gate electrode GEL, and the sidewall spacers SW. The insulating film 24 is made of, e.g., a silicon nitride film or the like.

Over the insulating film 24, an interlayer insulating film 25 is formed. The interlayer insulating film 25 is made of a single-layer silicon dioxide film, a laminated film including a silicon nitride film, and a silicon dioxide film, or the like. The upper surface of the interlayer insulating film 25 has been planarized.

In the interlayer insulating film 25, contact holes CNT are formed. In the contact holes CNT, conductive plugs PG are embedded each as a conductor portion.

Each of the plugs PG is formed of a thin barrier conductor film formed over the bottom portion of the contact hole CNT and the side wall, i.e., side surface thereof, and a main conductor film formed over the barrier conductor film so as to be embedded in the contact hole CNT. In FIG. 23, for simpler illustration, the barrier conductor film and the main conductor film which are included in the plug PG are integrally shown. Note that, as the barrier conductor film included in the plug PG, e.g., a titanium (Ti) film, a titanium nitride (TiN) film, or a laminated film thereof can be used while, as the main conductor film included in the plug PG, a tungsten (W) film can be used.

The contact holes CNT and the plugs PG embedded therein are formed over the n⁺-type semiconductor regions 22a, 22b, 22c, and 22d, the control gate electrode CG, the memory gate electrode MG, the gate electrodes GEH and GEL, and the like. At the bottom portion of each of the contact holes CNT, e.g., a part of the metal silicide layer 23 over the top surface of the n⁺-type semiconductor region 22a, 22b, 22c, or 22d, a part of the metal silicide layer 23 over the top surface of the control gate electrode CG, or a part of the metal silicide layer 23 over the top surface of the memory gate electrode MG is exposed. Alternatively, at the bottom portion of each of the contact holes CNT, e.g., a part of the metal silicide layer 23 over the top surface of the gate electrode GEH or GEL is exposed. Then, to the exposed portion, the plug PG is coupled. Note that FIG. 23 shows a cross section in which parts of the metal silicide layers 23 over the respective top surfaces of the n⁺-type semiconductor regions 22b, 22c, and 22d are exposed at the bottom portions of the contact holes CNT and electrically coupled to the plugs PG embedded in the contact holes CNT.

Over the interlayer insulating film 25 in which the plugs PG are embedded, as damascene wires as embedded wires using, e.g., copper (Cu) as a main conductive material, first-layer wires are formed. Above the first-layer wires, upper-layer wires are also formed as damascene wires, but the illustration and description thereof is omitted herein. The first-layer wires and the wires in the layers located thereabove are not limited to the damascene wires, but can also be formed by patterning conductive films for wires. For example, tungsten (W) wires, aluminum (Al) wires, or the like can also be used.

Next, operations to the memory cell MC1 formed in the memory cell region 11A will be described. FIG. 25 is a table showing an example of conditions for the application of voltages to the individual parts of the memory cell during “write”, “erase”, and “read” operations.

The table in FIG. 25 shows voltages Vmg applied to the memory gate electrode MG, voltages Vs applied to the semiconductor region MS, voltages Vcg applied to the control gate electrode CG, and voltages Vd applied to the semiconductor region MD during the “write”, “erase”, and “read” operations. The table in FIG. 25 also shows voltages Vb applied to the p-type well PW1 during the “write”, “erase”, and “read” operations. Note that the example shown in the table in FIG. 25 is a preferred example of the conditions for the application of the voltages. The conditions for the application of the voltages are not limited thereto, and can variously be changed as necessary.

In the present embodiment, the injection of electrons into the silicon nitride film 18b as the internal charge storage portion of the insulating film 18 of the memory transistor is defined as a “write operation”. Also, the injection of holes, i.e., positive holes into the silicon nitride film 18b is defined as an “erase operation”. It is also assumed that a power source voltage Vdd is 1.5 V.

As a write method, hot electron writing referred to as a so-called source-side injection (SSI) method can be used. For example, such voltages as shown in the “Write” row in FIG. 25 are applied to the individual parts of the memory cell MC1 to which a write operation is performed to inject electrons into the silicon nitride film 18b in the gate insulating film GIm of the memory cell MC1. Hot electrons are generated mainly in the portion of the channel region which is located under the memory gate electrode MG via the gate insulating film GIm and injected into the silicon nitride film 18b as the internal charge storage portion of the gate insulating film GIm. The injected hot electrons are trapped by a trap level in the silicon nitride film 18b in the gate insulating film GIm. As a result, the threshold voltage (Vth) of the memory transistor rises.

As an erase method, a hot-hole-injection erase method using a band-to-band tunneling (BTBT) phenomenon can be used. That is, by injecting holes, i.e., positive holes generated using the BTBT phenomenon into the charge storage portion, i.e., into the silicon nitride film 18b in the gate insulating film GIm, an erase operation is performed. For example, such voltages as shown in the “Erase” row in FIG. 25 are applied to the individual parts of the memory cell MC1 to which an erase operation is performed to generate holes using the BTBT phenomenon and subject the holes to high-gradient acceleration. In this manner, the holes are injected into the silicon nitride film 18b in the gate insulating film GIm of the memory cell MC1 to thus reduce the threshold voltage of the memory transistor.

As the erase method, an erase method based on hole injection using a direct tunneling phenomenon can also be used. That is, an erase operation is performed by injecting holes into the charge storage portion, i.e., the silicon nitride film 18b in the gate insulating film GIm using the direct tunneling phenomenon. It is assumed that the voltage Vmg applied to the memory gate electrode MG is set to, e.g., 12 V as a positive voltage and the voltage Vb applied to the p-type well PW1 is set to, e.g., 0 V, though the illustration thereof is omitted in the “Erase” row in FIG. 25. As a result, due to the direct tunneling phenomenon, holes are injected from the memory gate electrode MG into the charge storage portion, i.e., the silicon nitride film 18b via the silicon dioxide film 18c to cancel out the electrons in the silicon nitride film 18b so that an erase operation is performed. Alternatively, the holes injected into the silicon nitride film 18b are trapped by the trap level in the silicon nitride film 18b so that an erase operation is performed. This reduces the threshold voltage of the memory transistor to provide an erased state. When such an erase method is used, a larger reduction can be achieved in consumed current than when then erase method based on the BTBT phenomenon is used.

During a read operation, such voltages as shown in, e.g., the “Read” row in FIG. 25 are applied to the individual parts of the memory cell MC1 to which the read operation is performed. By setting the voltage Vmg applied to the memory gate electrode MG during the read operation to a value between the threshold voltage of the memory transistor in a written state and the threshold voltage of the memory transistor in the erased state, it is possible to discriminate the written state from the erased state.

<Method of Manufacturing Semiconductor Device>

Next, a description will be given of a method of manufacturing the semiconductor device in the present embodiment.

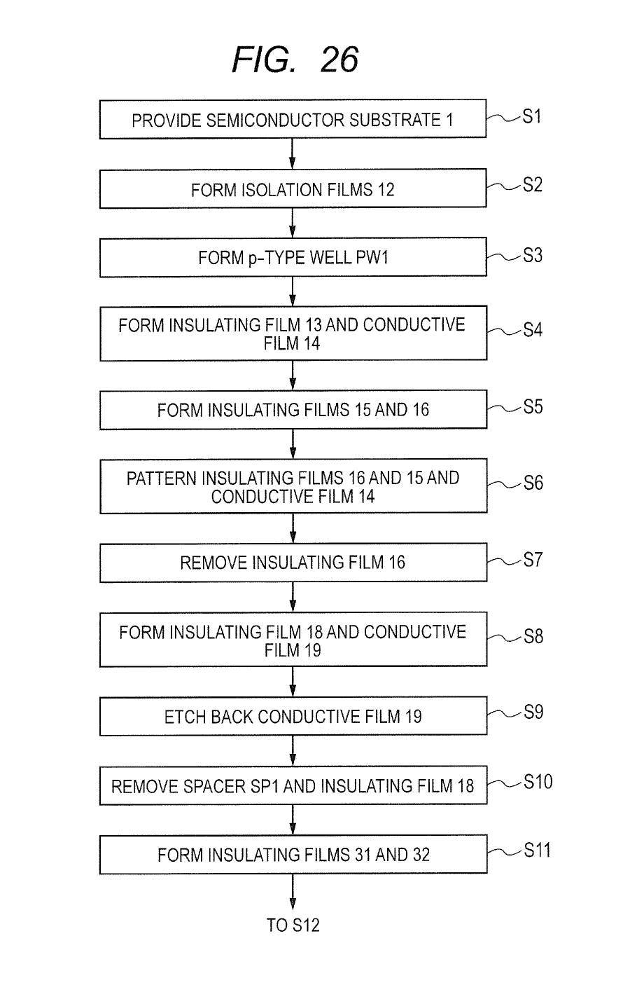

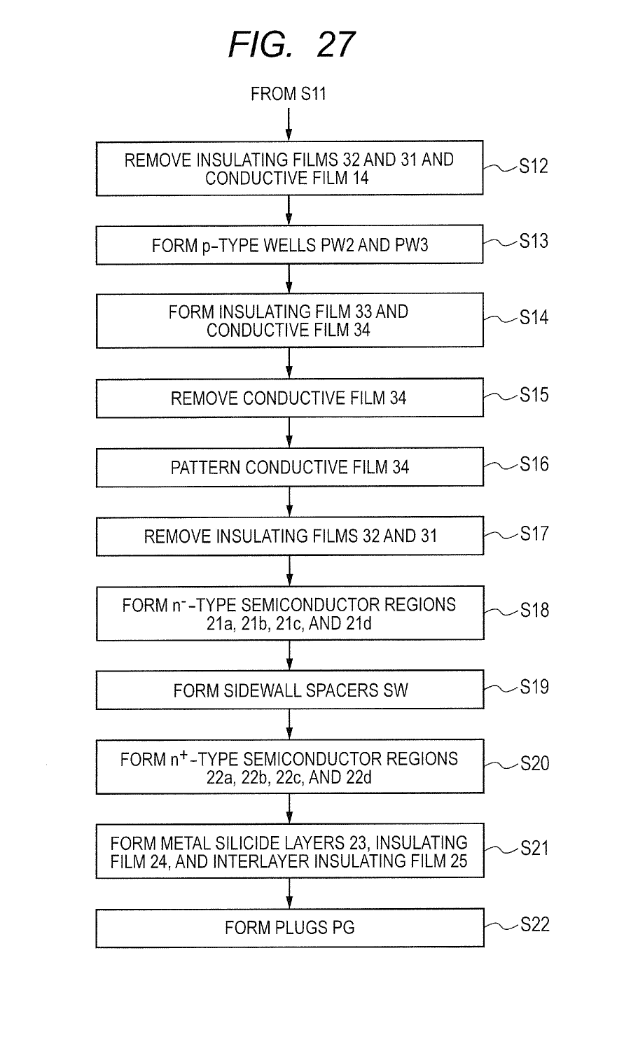

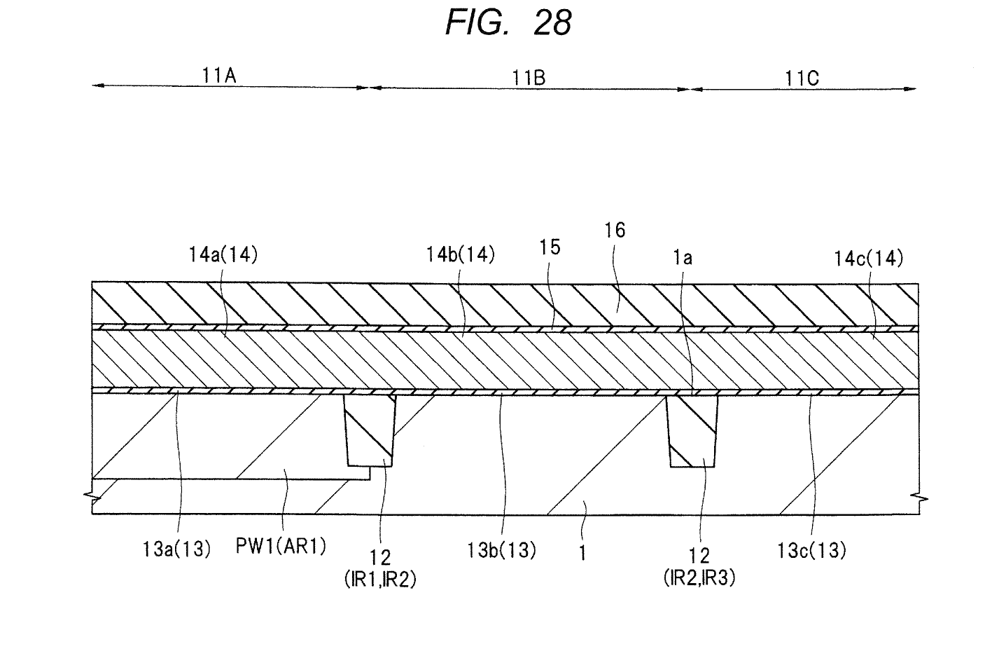

FIGS. 26 and 27 are process flow charts each showing a part of the manufacturing process of the semiconductor device in Embodiment 2. FIGS. 28 to 49 are main-portion cross-sectional views of the semiconductor device in Embodiment 2. In the cross-sectional views of FIGS. 28 to 49, the main-portion cross-sectional views of the memory cell region 11A and the peripheral circuit regions 11B and 11C are shown, and the respective formation of the memory cell MC1, the MISFET QH, and the MISFET QL in the memory cell region 11A, the peripheral circuit region 11B, and the peripheral circuit region 11C is shown.

As stated previously, the memory cell region 11A and the peripheral circuit region 11B need not be adjacent to each other, the memory cell region 11A and the peripheral circuit region 11C need not be adjacent to each other, and the peripheral circuit regions 11B and 11C need not be adjacent to each other. However, for easier understanding, in the cross-sectional views of FIGS. 28 to 49, the peripheral circuit region 11B is shown next to the memory cell region 11A, and the peripheral circuit region 11C is shown next to the peripheral circuit region 11B.

In Embodiment 2, a description is given of the case where, in the memory cell region 11A, the n-channel control transistor CT and the n-channel memory transistor MT are formed. However, it is also possible to invert the conductivity type and form the p-channel control transistor CT and the p-type memory transistor MT in the memory cell region 11A.

Likewise, in the present embodiment, a description is given of the case where, in the peripheral circuit region 11B, the n-channel MISFET QH is formed. However, it is also possible to invert the conductivity type and form the p-channel MISFET QH in the peripheral circuit region 11B. It is also possible to form a CMISFET (Complementary MISFET) or the like in the peripheral circuit region 1B. Likewise, in the present embodiment, a description is given of the case where, in the peripheral circuit region 11C, the n-channel MISFET QL is formed. However, it is also possible to invert the conductivity type and form the p-channel MISFET QL in the peripheral circuit region 11C. It is also possible to form a CMISFET or the like in the peripheral circuit region 11C.

As shown in FIG. 28, first, the semiconductor substrate 1 as a semiconductor wafer made of p-type monocrystalline silicon having a specific resistance of, e.g., about 1 to 10 Ωcm or the like is provided, i.e., prepared (Step S1 in FIG. 26).

Next, as shown in FIG. 28, the isolation films 12 are formed (Step S2 in FIG. 26). The isolation film 12 serves as the isolation region IR1 defining the active region AR1 in the memory cell region 11A of the main surface 1a of the semiconductor substrate 1. The isolation films 12 also serve as the isolation region IR2 defining the active region AR2 in the peripheral circuit region 11B of the main surface 1a of the semiconductor substrate 1 and as the isolation region IR3 defining the active region AR3 in the peripheral circuit region 11C of the main surface 1a of the semiconductor substrate 1.

Each of the isolation films 12 is made of an insulator such as silicon dioxide and can be formed by, e.g., a STI (Shallow Trench Isolation) method, a LOCOS (Local Oxidization of Silicon) method, or the like. For example, after isolation trenches are formed in the isolation regions IR1, IR2, and IR3, an insulating film made of, e.g., silicon dioxide is embedded in each of the isolation trenches to thus allow the isolation films 12 to be formed.

Next, as shown in FIG. 28, in the memory cell region 1A, the p-type well PW1 is formed in the active region AR1 (Step S3 in FIG. 26). The p-type well PW1 can be formed by introducing a p-type impurity such as, e.g., boron (B) into the semiconductor substrate 1 by an ion implantation method or the like. The p-type well PW1 is formed to extend from the main surface 1a of the semiconductor substrate 1 over a predetermined depth.

Next, a natural oxide film over the top surface of the semiconductor substrate 1 is removed by wet etching using, e.g., an aqueous hydrofluoric acid (HF) solution or the like. The top surface of the semiconductor substrate 1 is washed to be cleaned. This exposes the top surface of the semiconductor substrate 1 and exposes the top surface of the p-type well PW1 in the memory cell region 11A.

Next, as shown in FIG. 28, over the entire main surface 1a of the semiconductor substrate 1, an insulating film 13 and a conductive film 14 are formed (Step S4 in FIG. 26).

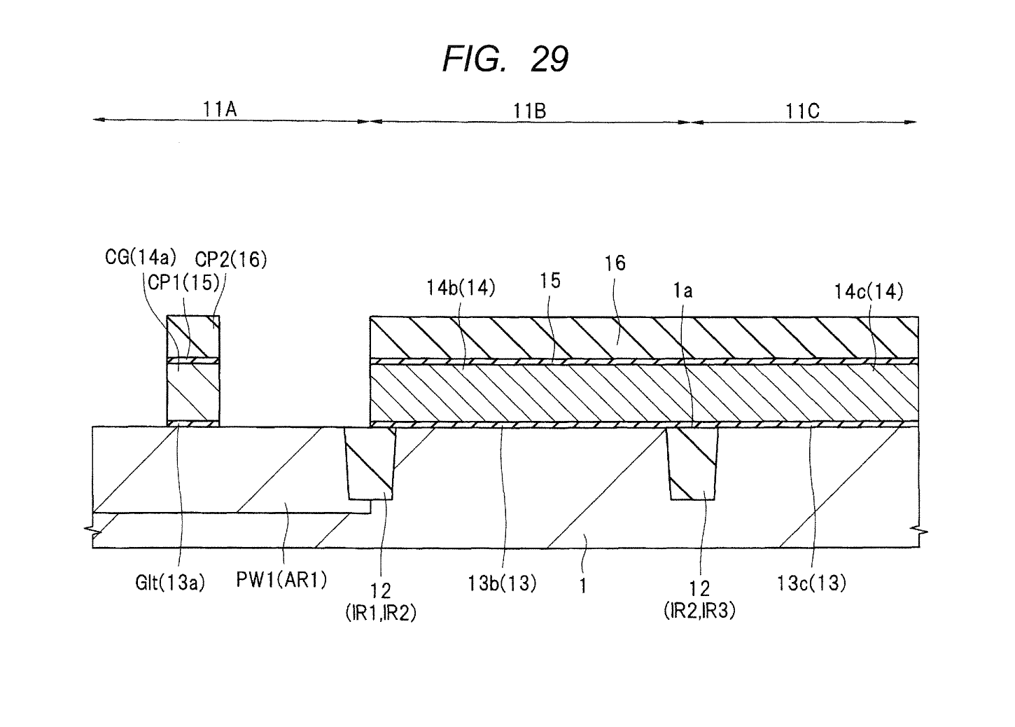

In Step S4, first, as shown in FIG. 28, in each of the memory cell region 11A and the peripheral circuit regions 11B and 11C, over the main surface 1a of the semiconductor substrate 1, the insulating film 13 is formed. Of the insulating film 13, the portion formed in the memory cell region 11A is referred to as the insulating film 13a, the portion formed in the peripheral circuit region 11B is referred to as an insulating film 13b, and the portion formed in the peripheral circuit region 11C is referred to as an insulating film 13c. The insulating film 13b is formed in the same layer as that of the insulating film 13a. The insulating film 13c is formed in the same layer as that of the insulating film 13a. The insulating film 13a is for the gate insulating film GIt (see FIG. 29 described later) of the memory cell MC1. The insulating film 13a is formed over the p-type well PW1.

In the example shown in FIG. 28, the insulating film 13b is formed integrally with the insulating film 13a, and the insulating film 13c is formed integrally with the insulating film 13a. However, the insulating film 13b may also be formed separately from the insulating film 13a, and the insulating film 13c may also be formed separately from the insulating film 13a.

As described above as the insulating film 13a, as the insulating film 13, a silicon dioxide film, a silicon nitride film, a silicon oxynitride film, or a High-k film, i.e., high-dielectric-constant film can be used. Examples of the material that can be used for the insulating film 13 are as described above as the material for the insulating film 13a. The insulating film 13 can be formed using a thermal oxidation method, a sputtering method, an atomic layer deposition (ALD) method, a chemical vapor deposition (CVD) method, or the like.

In Step S4, next, as shown in FIG. 28, in each of the memory cell region 11A and the peripheral circuit regions 11B and 1C, the conductive film 14 is formed over the insulating film 13. Of the conductive film 14, the portion formed in the memory cell region 11A is referred to as the conductive film 14a, the portion formed in the peripheral circuit region 11B is referred to as a conductive film 14b, and the portion formed in the peripheral circuit region 11C is referred to as a conductive film 14c. The conductive film 14b is formed in the same layer as that of the conductive film 14a. The conductive film 14c is formed in the same layer as that of the conductive film 14a. The conductive film 14a is for the control gate electrode CG (see FIG. 29 described later) of the memory cell MC1.

In the example shown in FIG. 28, the conductive film 14b is formed integrally with the conductive film 14a, and the conductive film 14c is formed integrally with the conductive film 14a. However, the conductive film 14b may also be formed separately from the conductive film 14a, and the conductive film 14c may also be formed separately from the conductive film 14a.

Preferably, the conductive film 14 is made of a polycrystalline silicon film, i.e., polysilicon film. The conductive film 14 can be formed using a CVD method or the like. The conductive film 14 is allowed to have a sufficient thickness to cover the insulating film 13. It may also be possible to deposit an amorphous silicon film as the conductive film 14 and then change the amorphous silicon film to a polycrystalline silicon film.

As the conductive film 14, a conductive film having a low resistivity due to, e.g., an n-type impurity such as phosphorus (P) or arsenic (As) or a p-type impurity such as boron (B) introduced therein is preferably used. The impurity can be introduced during or after the deposition of the conductive film 14. When the impurity is introduced during the deposition of the conductive film 14, by causing a gas for depositing the conductive film 14 to include a doping gas, the conductive film 14 into which the impurity has been introduced can be deposited. On the other hand, when the impurity is introduced after the deposition of the silicon film, the silicon film is deposited without intentional introduction of the impurity. Then, the impurity is introduced into the silicon film by an ion implantation method or the like to allow the conductive film 14 into which the impurity has been introduced to be formed.

Next, as shown in FIG. 28, over the entire main surface 1a of the semiconductor substrate 1, i.e., over the conductive film 14, the insulating films 15 and 16 are formed (Step S5 in FIG. 26).

In Step S5, first, as shown in FIG. 28, in each of the memory cell region 11A and the peripheral circuit regions 11B and 11C, the insulating film 15 is formed over the conductive film 14. The insulating film 15 is for the cap insulating film CP1 (see FIG. 29 described later).

For example, by thermally oxidizing the top surface of the conductive film 14 made of a silicon film, the insulating film 15 made of a silicon dioxide film having a thickness of, e.g., about 6 nm can be formed. The insulating film 15 made of a silicon dioxide film can also be formed using a CVD method instead of thermally oxidizing the top surface of the conductive film 14 made of a silicon film.

As a material for the insulating film 15, an insulating film made of another material can be used instead of the silicon dioxide film. Alternatively, it is also possible to form the insulating film 16 directly over the conductive film 14 without forming the insulating film 15.

In Step S5, next, as shown in FIG. 28, in each of the memory cell region 11A and the peripheral circuit regions 11B and 11C, the insulating film 16 is formed over the insulating film 15. For example, the insulating film 16 made of, e.g., a silicon nitride film can be formed using, e.g., a CVD method or the like.

Next, as shown in FIG. 29, the insulating films 16 and 15 and the conductive film 14 are patterned (Step S6 in FIG. 26). In Step S6, using, e.g., photolithography and etching, the insulating films 16 and 15 and the conductive film 14 are patterned.

First, over the insulating film 16, a resist film is formed. Then, in the area of the memory cell region 11A other than the area thereof where the control gate electrode CG is to be formed, an opening is formed to extend through the resist film and reach the insulating film 16. Thus, a resist pattern made of the resist film formed with the opening is formed. At this time, the portion of the insulating film 16 which is located in the area of the memory cell region 11A where the control gate electrode CG is to be formed and the portions of the insulating film 16 which are located in the peripheral circuit regions 11B and 11C are covered with the resist film.

Next, using the resist pattern as an etching mask, the insulating films 16 and 15 and the conductive film 14 are etched by, e.g., dry etching or the like to be patterned. Consequently, in the memory cell region 11A, the control gate electrode CG made of the conductive film 14a is formed and the gate insulating film GIt made of the insulating film 13a located between the control gate electrode CG and the p-type well PW1 of the semiconductor substrate 1 is formed. That is, in the memory cell region 11A, the control gate electrode CG is formed over the p-type well PW1 of the semiconductor substrate 1 via the gate insulating film GIt.

Also, the cap insulating film CP1 made of the portion of the insulating film 15 which is formed over the control gate electrode CG is formed, and the cap insulating film CP2 made of the portion of the insulating film 16 which is formed over the control gate electrode CG via the cap insulating film CP1 is formed. On the other hand, in the peripheral circuit regions 11B and 11C, the insulating films 16 and 15 and the conductive film 14 are left. In the peripheral circuit region 11B, the conductive film 14b is left and, in the peripheral circuit region 11C, the conductive film 14c is left. Then, the resist pattern, i.e., the resist film is removed.

Note that, in the memory cell region 11A, the portion of the insulating film 13a which is uncovered with the control gate electrode CG can be removed by performing dry etching in Step S6 or performing wet etching after the dry etching in Step S6. As a result, in the portion of the memory cell region 11A where the control gate electrode CG is not formed, the p-type well PW1 of the semiconductor substrate 1 is exposed.

Note that, in Step S6, after the control gate electrode CG and the cap insulating film CP1 are formed, an n-type impurity may also be introduced into the p-type well PW1 by an ion implantation method using the cap insulating film CP1 and the control gate electrode CG as a mask, though the illustration thereof is omitted.

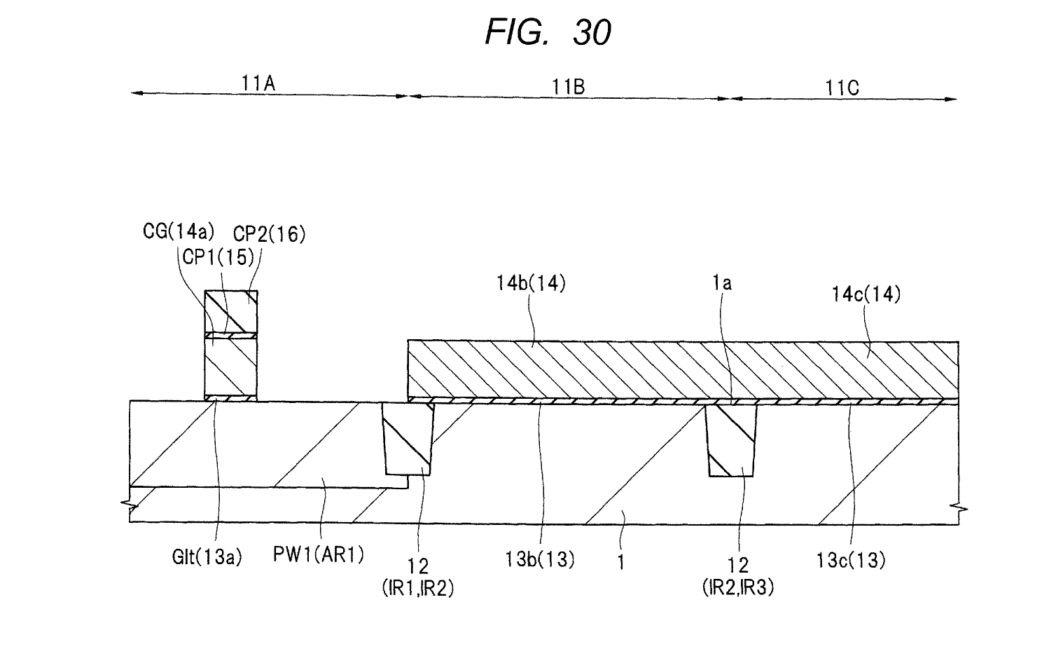

Next, as shown in FIG. 30, in the peripheral circuit regions 11B and 11C, the insulating film 16 is removed (Step S7 in FIG. 26).

In Step S7, first, in the memory cell region 11A, a resist film (not shown) is formed so as to cover the cap insulating film CP2 and the control gate electrode CG. The resist film (not shown) is also formed so as to cover the portion of the insulating film 16 which is left in the peripheral circuit regions 11B and 11C and the portions of the conductive film 14 which is left in the peripheral circuit regions 11B and 11C, i.e., the conductive films 14b and 14c.

Next, the resist film is subjected to pattern exposure and then developed to be patterned. Thus, the resist film is removed from the peripheral circuit regions 11B and 11C and left in the memory cell region 11A. In this manner, a resist pattern made of the portion of the resist film which is left in the memory cell region 11A is formed.

Next, using the resist pattern as an etching mask, the insulating film 16 is etched by, e.g., dry etching or the like to be removed. This can completely remove the portion of the insulating film 16 which is left in the peripheral circuit regions 11B and 11C, as shown in FIG. 30. Then, the portion of the resist film which is left in the memory cell region 11A, i.e., the resist pattern is removed.

Note that, as shown in FIG. 30, the thickness of the insulating film 15 is smaller than the thickness of the insulating film 16. Accordingly, when the portion of the insulating film 16 which is left in the peripheral circuit regions 11B and 11C is etched to be removed, the portion of the insulating film 15 which is left in the peripheral circuit regions 11B and 11C is also removed.

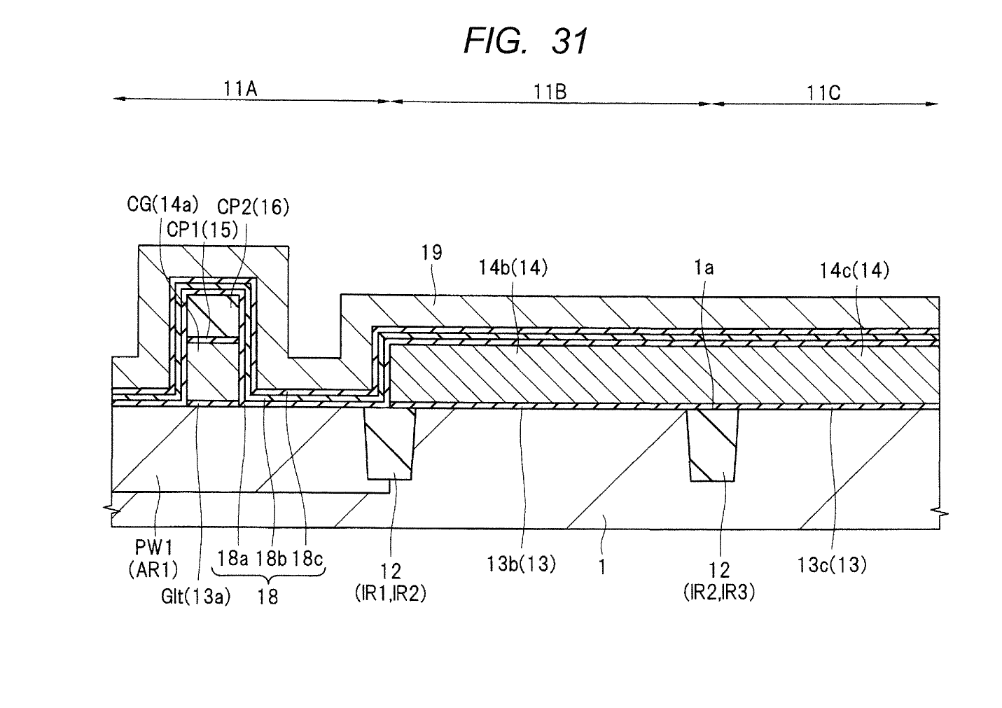

Next, as shown in FIG. 31, the insulating film 18 and the conductive film 19 are formed (Step S8 in FIG. 26).

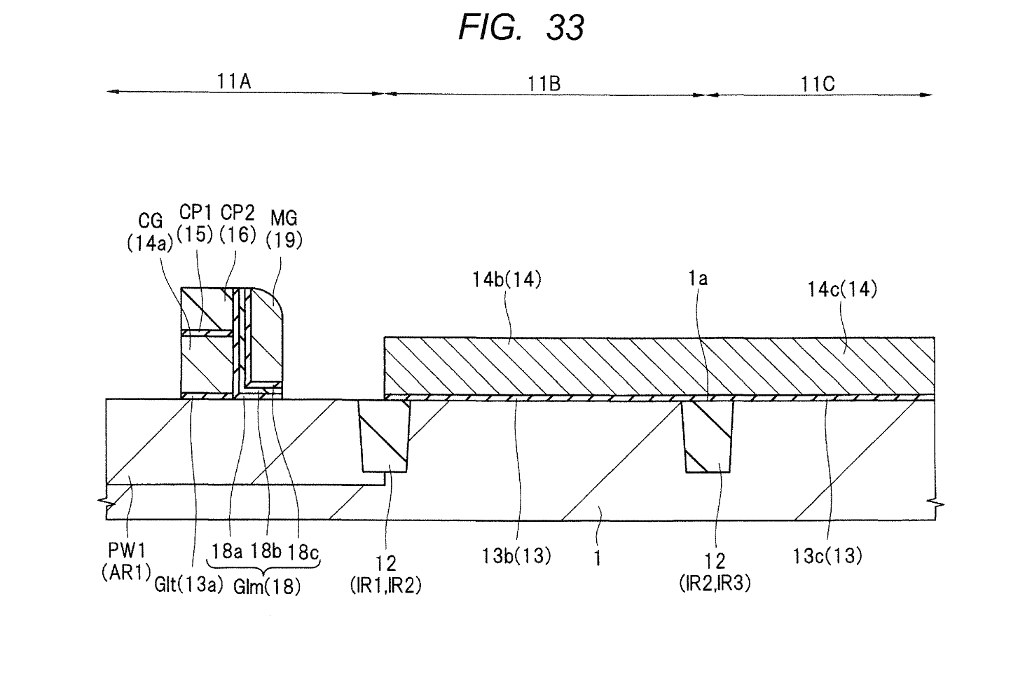

In Step S8, first, as shown in FIG. 31, the insulating film 18 for the gate insulating film GIm (see FIG. 33 described later) of the memory transistor MT is formed over the main surface 1a of the semiconductor substrate 11 in the memory cell region 11A and the peripheral circuit regions 11B and 11B. At this time, in the memory cell region 11A, the insulating film 18 is formed over the main surface 1a of the exposed portion of the semiconductor substrate 1, the side surface of the control gate electrode CT, and the upper and side surfaces of the cap insulating film CP2. The insulating film 18 is also formed over the upper and side surfaces of the portion of the conductive film 14 which is left in the peripheral circuit regions 11B and 11C. That is, the insulating film 18 is formed so as to cover the main surface 1a of the semiconductor substrate 1, the side surface of the control gate electrode CG, the top surface of the cap insulating film CP2, and the top surface of the portion of the conductive film 14 which is left in the peripheral circuit regions 11B and 11C.

As described above, the insulating film 18 has the internal charge storage portion and is made of a laminated film including the silicon dioxide film 18a, the silicon nitride film 18b, and the silicon dioxide film 18c which are formed successively as insulating films in ascending order.

Of the insulating film 18, the silicon dioxide film 18a can be formed at a temperature of, e.g., about 900° C. by a thermal oxidation method, an ISSG oxidation method, or the like. Then, nitridation treatment may also be performed at a high temperature of, e.g., about 1025° C. Also, of the insulating film 18, the silicon nitride film 18b can be formed by, e.g., a CVD method. Also, of the insulating film 18, the silicon dioxide film 18c can be formed by, e.g., a CVD method.

First, over the main surface 1a of the exposed portion of the semiconductor substrate 1, the side surface of the control gate electrode CG, the upper and side surfaces of the cap insulating film CP1, and the upper and side surfaces of the portion of the conductive film 14 which is left in the peripheral circuit regions 11B and 11C, the silicon dioxide film 18a is formed by, e.g., a thermal oxidation method or an ISSG oxidation method. At this time, the main surface 1a of the exposed portion of the semiconductor substrate 1, the side surface of the control gate electrode CG, the upper and side surfaces of the cap insulating film CP2, and the upper and side surfaces of the portion of the conductive film 14 which is left in the peripheral circuit regions 11B and 11C are oxidized. The thickness of the silicon dioxide film 18a can be set to, e.g., about 4 nm.

In another embodiment, the silicon dioxide film 18a can also be formed by an ALD method. At this time, silicon dioxide grows over the main surface 1a of the exposed portion of the semiconductor substrate 1, the side surface of the control gate electrode CG, the upper and side surfaces of the cap insulating film CP2, and the upper and side surfaces of the portion of the conductive film 14 which is left in the peripheral circuit regions 11B and 11C. Consequently, at this time also, the main surface 1a of the exposed portion of the semiconductor substrate 1, the side surface of the control gate electrode CG, the upper and side surfaces of the cap insulating film CP2, and the upper and side surfaces of the portion of the conductive film 14 which is left in the peripheral circuit regions 11B and 11C are covered with the oxide film.

Next, over the silicon dioxide film 18a, the silicon nitride film 18b is formed by, e.g., a CVD method. Further, over the silicon nitride film 18b, the silicon dioxide film 18c is formed by, e.g., a CVD method, a thermal oxidation method, or both of the methods. Thus, the insulating film 18 made of the laminated film including the silicon dioxide film 18a, the silicon nitride film 18b, and the silicon dioxide film 18c can be formed.

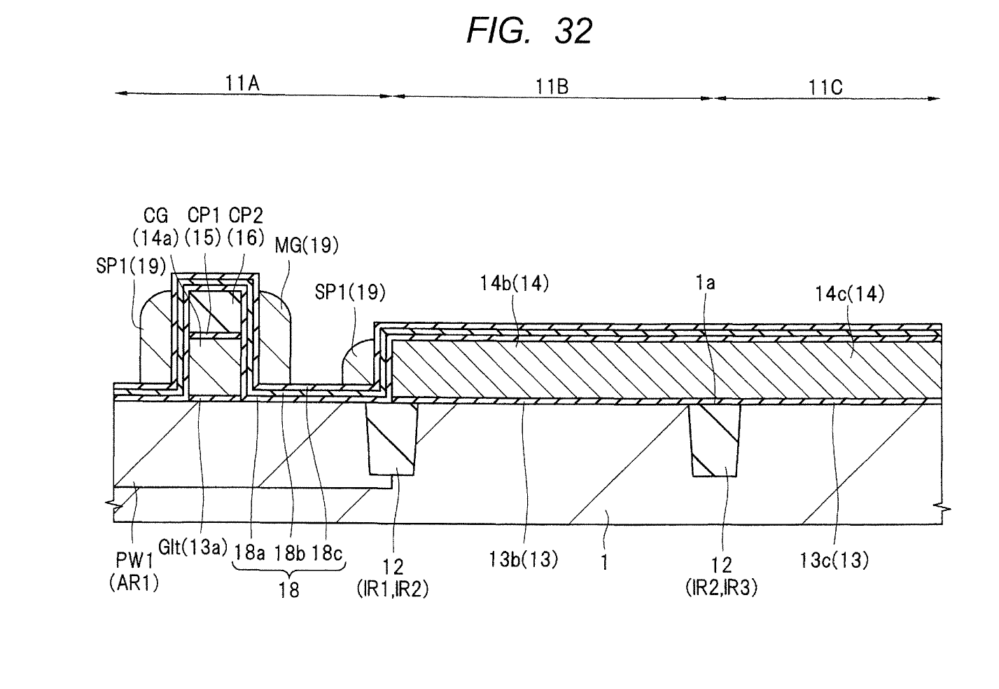

The insulating film 18 formed in the memory cell region 11A functions as the gate insulating film of the memory gate electrode MG (see FIG. 32 described later) and has a charge retaining function. The insulating film 18 has a structure in which the silicon nitride film 18b as the charge storage portion is interposed between the silicon dioxide films 18a and 18c as the charge blocking layer. A potential barrier height in the charge blocking layer including the silicon dioxide films 18a and 18c is higher than a potential barrier height in the charge storage portion made of the silicon nitride film 18b.

Note that, in the present embodiment, as the insulating film having the trap level, the silicon nitride film 18b is used. The use of the silicon nitride film 18b is preferable in terms of reliability. However, the insulating film having the trap level is not limited to a silicon nitride film, and a high-dielectric-constant film having a dielectric constant higher than that of a silicon nitride film such as, e.g., an aluminum oxide (alumina) film, a hafnium oxide film, or a tantalum oxide film can be used.

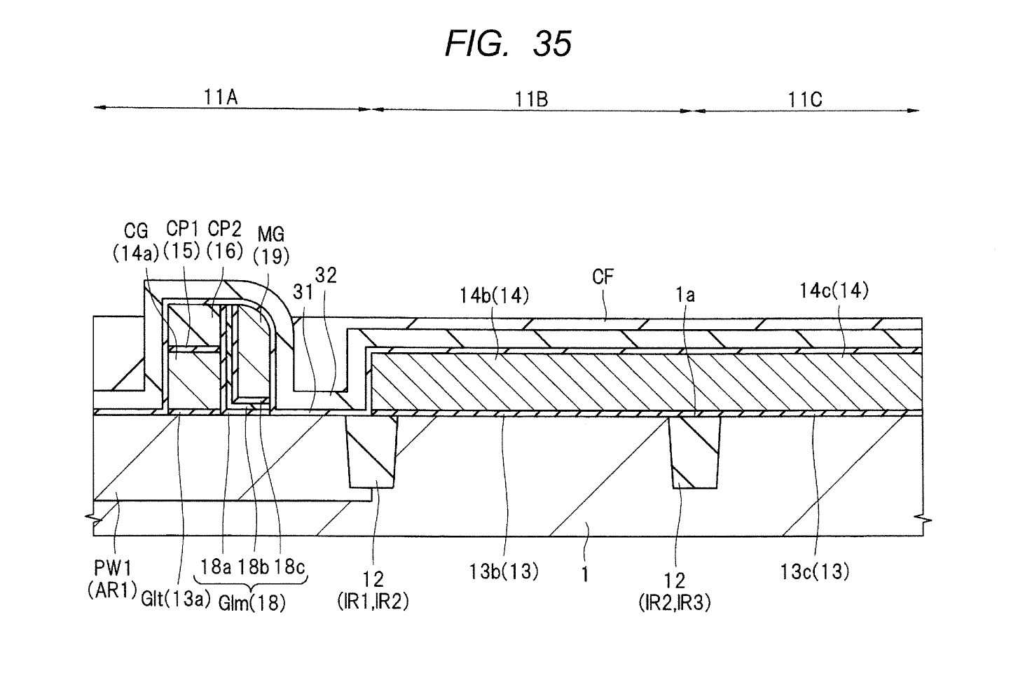

In the present embodiment, after the step of insulating film 18 included in Step S8 is performed, the portion of the conductive film 14 which is left in the peripheral circuit regions 11B and 11C is removed, the p-type well PW2 (see FIG. 35 described later) is formed in the peripheral circuit region 11B, and the p-type well PW3 (see FIG. 35 described later) is formed in the peripheral circuit region 11C. As described above, in the step of forming the insulating film 18, high-temperature treatment at, e.g., about 1025° C. is performed. Accordingly, in the present embodiment which forms the insulating film 18 and then forms the p-type wells PW2 and PW3, it is possible to prevent the n-type impurity introduced in the p-type wells PW2 and PW3 from being diffused at a high temperature during the formation of the insulating film 18. It is also possible to prevent a change in the distribution of an impurity concentration in the p-type well PW2 or a change in the distribution of an impurity concentration in the p-type well PW3.

In Step S8, next, as shown in FIG. 31, the conductive film 19 is formed over the insulating film 18 in each of the memory cell region 11A and the peripheral circuit regions 11B and 11C.

Preferably, the conductive film 19 is made of, e.g., a polycrystalline silicon film, i.e., a polysilicon film. The conductive film 19 can be formed using a CVD method or the like. It is also possible to deposit an amorphous silicon film as the conductive film 19 and then change the amorphous silicon film to a polycrystalline silicon film by the subsequent heat treatment.

As the conductive film 19, a conductive film having a low resistivity due to, e.g., an n-type impurity such as phosphorus (P) or arsenic (As) or a p-type impurity such as boron (B) introduced therein is preferably used. The impurity can be introduced during or after the deposition of the conductive film 19. The impurity can be introduced into the conductive film 19 by ion implantation after the deposition thereof or can also be introduced into the conductive film 19 during the deposition thereof. When the impurity is introduced during the deposition of the conductive film 19, by causing a gas for depositing the conductive film 19 to include a doping gas, the conductive film 19 into which the impurity has been introduced can be deposited.

Next, as shown in FIG. 32, using an anisotropic etching technique, the conductive film 19 is etched back to form the memory gate electrode MG (Step S9 in FIG. 26).

In Step S9, the conductive film 19 is etched back by the thickness of the conductive film 19 to be left in sidewall spacer shapes over the both side walls, i.e., both side surfaces of the control gate electrode CG via the insulating film 18 and removed from the other region.

Thus, as shown in FIG. 32, in the memory cell region 11A, over the one of the both side walls of the control gate electrode CG which is located on the first side thereof, i.e., over the side wall of the control gate electrode CG over which the memory gate electrode MG adjacent to the control gate electrode CG is disposed, the memory gate electrode MG made of the conductive film 19 left in the sidewall spacer shape is formed via the insulating film 18. Over the other of the both side walls of the control gate electrode CG which is located on the side thereof opposite to the first side, i.e., over the side wall of the control gate electrode CG opposite to the side wall thereof over which the memory gate electrode MG adjacent to the control gate electrode CG is disposed, the spacer SP1 made of the conductive film 19 left in the sidewall spacer shape is formed via the insulating film 18.

The memory gate electrode MG is formed over the insulating film 18 so as to be adjacent to the control gate electrode CG via the insulating film 18. The memory gate electrode MG and the spacer SP1 are formed over the respective side walls of the control gate electrode CG opposite to each other and have substantially symmetrical structures relative to the control gate electrode CG interposed therebetween.

Over the control gate electrode CG, the cap insulating film CP2 is formed via the cap insulating film CP1. Accordingly, the memory gate electrode MG is made of the conductive film 19 left in the sidewall spacer shape over the side wall of the cap insulating film CP2 which is located on the first side thereof via the insulating film 18. The spacer SP1 is made of the conductive film 19 left in the sidewall spacer shape over the sidewall of the cap insulating film CP2 which is located on the side thereof opposite to the first side via the insulating film 18.

Note that, over the side surface of the portion of the conductive film 14 which is left in the peripheral circuit region 11B, i.e., the conductive film 14b and over the side surface of the portion of the conductive film 14 which is left in the peripheral circuit region 11C, i.e., the conductive film 14c also, the spacers SP1 are formed of the conductive film 19 left in sidewall spacer shapes via the insulating films 18.

Between the memory gate electrode MG formed in Step S9 and the p-type well PW1 of the semiconductor substrate 1 and between the memory gate electrode MG and the control gate electrode CG, the insulating film 18 is interposed. The memory gate electrode MG is made of the conductive film 19 in contact with the insulating film 18.

At the stage where the etch-back step in Step S9 is performed, the portion of the insulating film 18 which is covered with neither the memory gate electrode MG nor the spacer SP1, i.e., the portion of the insulating film 18 which is uncovered with each of the memory gate electrode MG and the spacer SP1 is exposed. The insulating film 18 under the memory gate electrode MG in the memory cell region 11A serves as the gate insulating film GIm (see FIG. 33 described later) of the memory transistor MT. By adjusting the thickness of the conductive film 19 formed in Step S8, the memory gate length can be adjusted.

Next, as shown in FIG. 33, the spacer SP1 and the insulating film 18 are removed (Step S10 in FIG. 26).

In Step S10, first, using photolithography, a resist pattern (not shown) is formed over the semiconductor substrate 1 to cover the memory gate electrode MG and expose the spacer SP1. Then, by dry etching using the formed resist pattern as an etching mask, the spacer SP1 is removed. On the other hand, the memory gate electrode MG that has been covered with the resist pattern remains without being etched. Then, the resist pattern is removed.

In Step S10, next, the portion of the insulating film 18 which is uncovered with the memory gate electrode MG is removed by etching such as, e.g., wet etching. At this time, in the memory cell region 11A, the insulating film 18 located between the memory gate electrode MG and the p-type well PW1 and between the memory gate electrode MG and the control gate electrode CG is left without being removed, while the insulating film 18 located in the other region is removed. At this time, in the memory cell region 11A, the gate insulating film GIm including the respective portions of the insulating film 18 which are left between the memory gate electrode MG and the p-type well PW1 and between the memory gate electrode MG and the control gate electrode CG is formed.

Note that, in Step S10, the etching may also be performed such that, of the insulating film 18, the silicon dioxide film 18c and the silicon nitride film 18b are removed and the silicon dioxide film 18a is left without being removed.

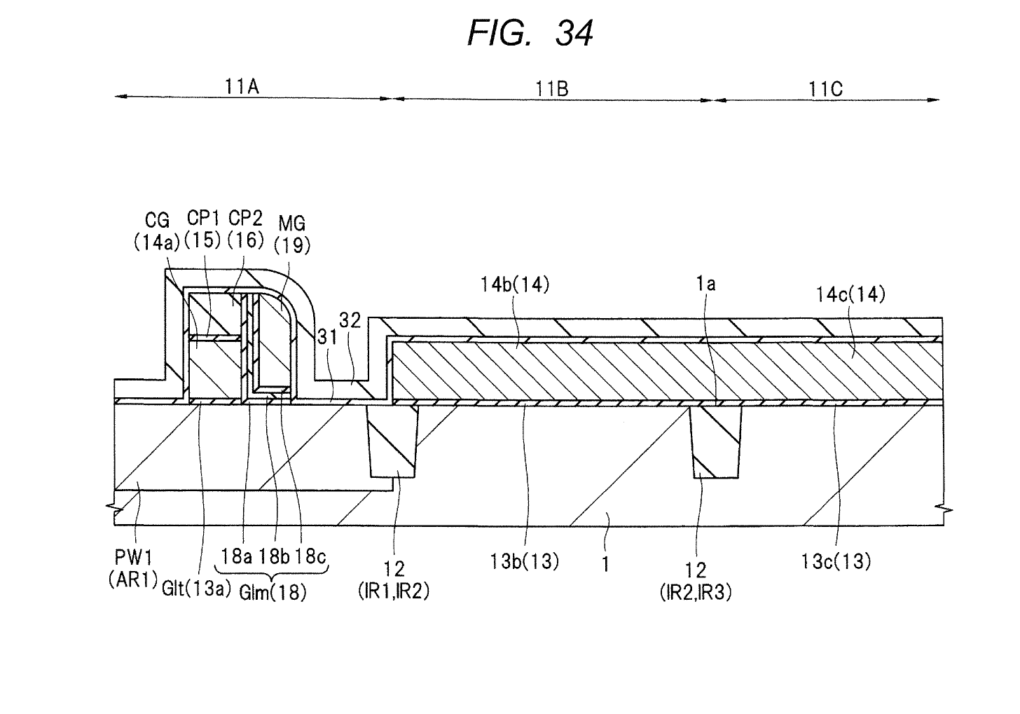

Next, as shown in FIG. 34, insulating films 31 and 32 are formed (Step S11 in FIG. 26).

In Step S11, first, over the main surface 1a of the semiconductor substrate 1 in each of the memory cell region 11A and the peripheral circuit regions 11B and 11C, the insulating film 31 is formed. At this time, the insulating film 31 is formed so as to cover the main surface 1a of the exposed portion of the semiconductor substrate 1a, the control gate electrode CG, the cap insulating film CP2, and the memory gate electrode MG in the memory cell region 11A. The insulating film 31 is also formed so as to cover the portion of the conductive film 14 which is left in the peripheral circuit region 11B, i.e., the conductive film 14b and the portion of the conductive film 14 which is left in the peripheral circuit region 11C, i.e., the conductive film 14c.

For example, over the main surface 1a of the exposed portion of the semiconductor substrate 1, the side surface of the control gate electrode CG, the upper and side surfaces of the cap insulating film CP2, the top surface of the memory gate electrode MG, and the upper and side surfaces of the portion of the conductive film 14 which is left in the peripheral circuit regions 11B an 11C, the insulating film 31 made of a silicon dioxide film is formed by a CVD method. At this time, the main surface 1a of the exposed portion of the semiconductor substrate 1, the side surface of the control gate electrode CG, the upper and side surfaces of the cap insulating film CP2, the top surface of the memory gate electrode MG, and the upper and side surfaces of the portion of the conductive film 14 which is left in the peripheral circuit regions 11B and 11C are covered with an oxide film.

In another embodiment, the insulating film 31 made of a silicon dioxide film can also be formed by an ALD method. At this time, the main surface 1a of the exposed portion of the semiconductor substrate 1, the side surface of the control gate electrode CG, the upper and side surfaces of the cap insulating film CP2, the top surface of the memory gate electrode MG, and the upper and side surfaces of the portion of the conductive film 14 which is left in the peripheral circuit regions 11B and 11C are subjected to heat treatment in an oxidizing atmosphere. Consequently, at this time also, the main surface 1a of the exposed portion of the semiconductor substrate 1, the side surface of the control gate electrode CG, the upper and side surfaces of the cap insulating film CP2, the top surface of the memory gate electrode MG, and the upper and side surfaces of the portions of the conductive film 14 which are left in the peripheral circuit regions 11B and 11C are oxidized.

In Step S11, next, in each of the memory cell region 11A and the peripheral circuit regions 11B and 11C, over the insulating film 31, the insulating film 32 is formed. For example, the insulating film 32 made of, e.g., a silicon nitride film can be formed using, e.g., a CVD method or the like.

Next, as shown in FIGS. 35 to 37, over the semiconductor substrate 1 (the memory cell region 11A and the peripheral circuit regions 11B and 11C), the coating film CF is formed. For example, as the coating film CF, an antireflection film is formed. A material for the antireflection film is a coating agent in the form of a solution or gel and can be applied to the upper surface of the semiconductor substrate 1 using, e.g., a spin coating method or the like. At this time, the antireflection film material in the form of a solution or gel spreads so as to smooth away the surface roughness of the semiconductor substrate 1. Accordingly, by adjusting the amount of the antireflection film material to be applied, coating can be performed so as to cover the insulating film (silicon nitride film) 32 in each of the peripheral circuit regions 11B and 11C and expose the insulating film 32 over the control gate electrode portion (laminated film portion including the control gate electrode CG and the cap insulating film) in the memory cell region 11A. Thus, the coating film CF is formed to cover the insulating film 32 in each of the peripheral circuit regions 11B and 11C and expose the insulating film 32 over the control gate electrode portion (laminated film portion including the control gate electrode CG and the cap insulating film) in the memory cell region 11A. Such a process allows the coating film CF which partially exposes the insulating film 32 to be formed in a so-called maskless manner without performing exposure/development treatment (without using a reticle mask). Note that, as the coating film CF, the antireflection film is used herein, but another coating agent in the form of a solution or gel (e.g., photoresist film) may also be used. However, the antireflection film is easily controlled even in the state of a relatively thin film and allows easy adjustment of the thickness of the coating film CF.

When it is difficult to adjust the thickness of the coating film CF, it may also be possible to form the coating film CF to a thickness sufficient to cover the insulating film 32 over the control gate electrode portion (laminated film portion including the control gate electrode CG and the cap insulating film), then etch back the entire surface of the coating film CF to retreat the top surface thereof, and expose the insulating film 32 over the control gate electrode portion (laminated film portion including the control gate electrode CG and the cap insulating film).

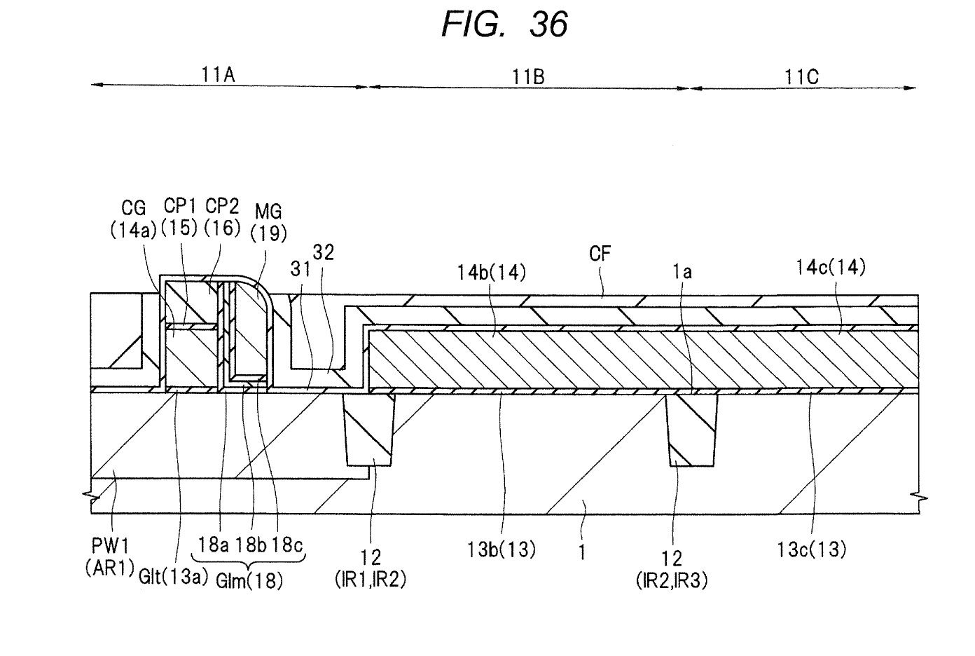

Next, as shown in FIG. 36, using the coating film CF as a mask, the insulating film 32 is etched. Here, the silicon nitride film forming the insulating film 32 is dry-etched. For example, using CH₄ as an etching gas, isotropic dry etching is performed. As a result, the peripheral circuit regions 11B and 11C are covered with the insulating film 32, while the insulating film 32 is removed from a part of the memory cell region 11A. In other words, it is possible to form an opening in the insulating film (silicon nitride film) 32 over the control gate electrode portion (laminated film portion including the control gate electrode CG and the cap insulating film) and the memory gate electrode MG. From the opening, the insulating film (silicon dioxide film) 31 is exposed.

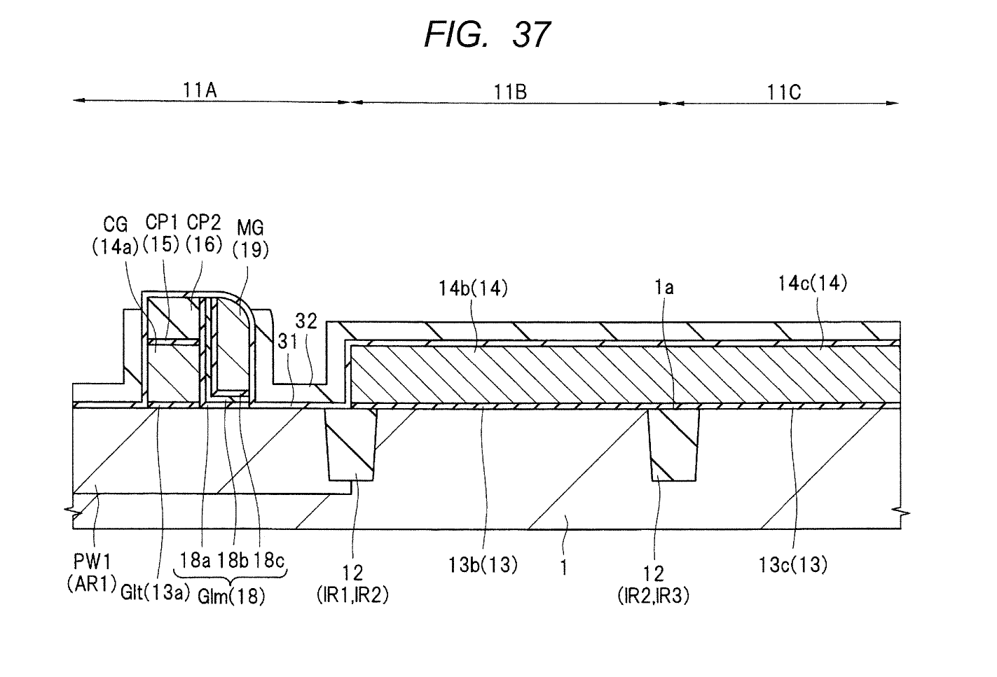

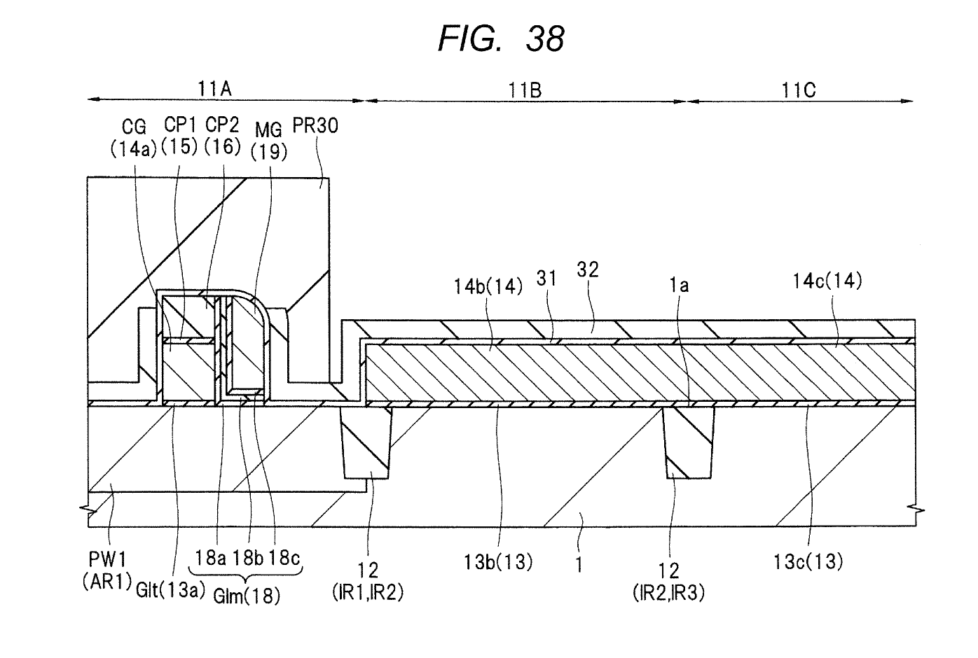

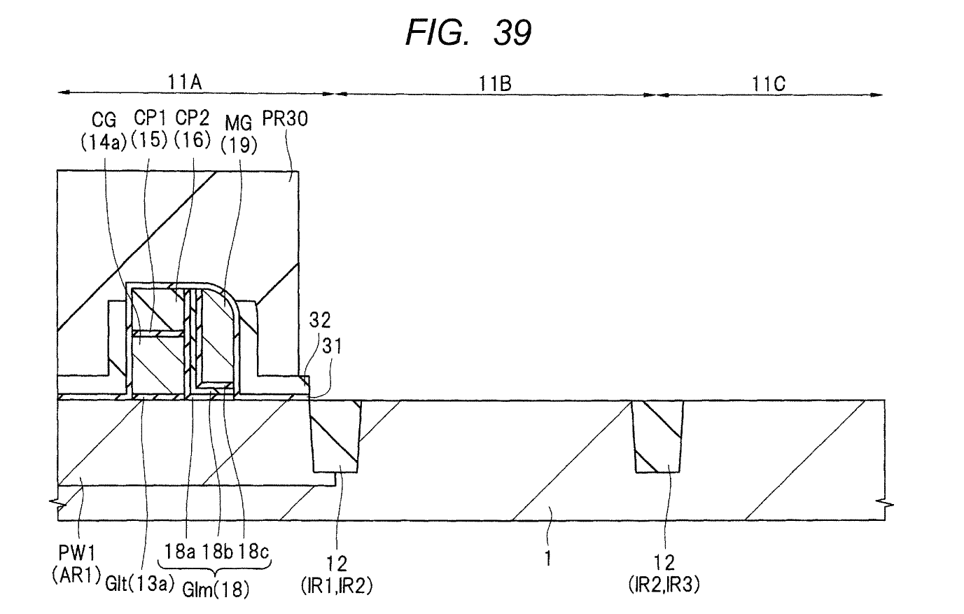

Next, as shown in FIG. 37, the coating film CF is etched to be removed. Then, as shown in FIG. 38, a resist film (photoresist film) PR30 is formed to cover the memory cell region 11A and have an opening in the peripheral circuit regions 11B and 11C. Using the resist film PR30 as an etching mask, the insulating films 32 and 31 and the conductive film 14 are etched by, e.g., dry etching or the like to be removed. This allows the portions of the conductive film 14 which are left in the peripheral circuit regions 11B and 11C to be completely removed, as shown in FIG. 39. That is, it is possible to remove the conductive film 14b from the peripheral circuit region 11B and remove the conductive film 14c from the peripheral circuit region 11C.

Steps S11 and S12 are performed to leave the insulating films 31 and 32 in the memory cell region 11A. As a result, in the case where, e.g., an insulating film 33 is formed in the steps (Steps S13 to S16) subsequent to Step S12 or the like, it is possible to prevent or inhibit a gate bird's beak from being formed as a result of the oxidation of the upper-layer portion of the part of the p-type well PW1 which is located adjacent to the control gate electrode CG or the memory gate electrode MG. Alternatively, in the case where, e.g., the insulating film 33 is formed in the steps (Steps S13 to S16) subsequent to Step S12 or the like, it is possible to prevent or inhibit, e.g., the gate length from varying as a result of the oxidation of the top surface of the control gate electrode CG or the memory gate electrode MG. This can prevent or inhibit the degradation of the properties of a nonvolatile memory and improve the performance of a semiconductor device including the nonvolatile memory.

The step of removing the conductive films 14b and 14c in Step S12 can also be performed at any time point, e.g., after Step S6 and before Step S12. However, by removing the conductive films 14b and 14c at step 12, that is, immediately before Step S13 described later, it is possible to protect the main surface 1a of each of the portions of the semiconductor substrate 1 where the p-type wells PW2 and PW3 are formed.

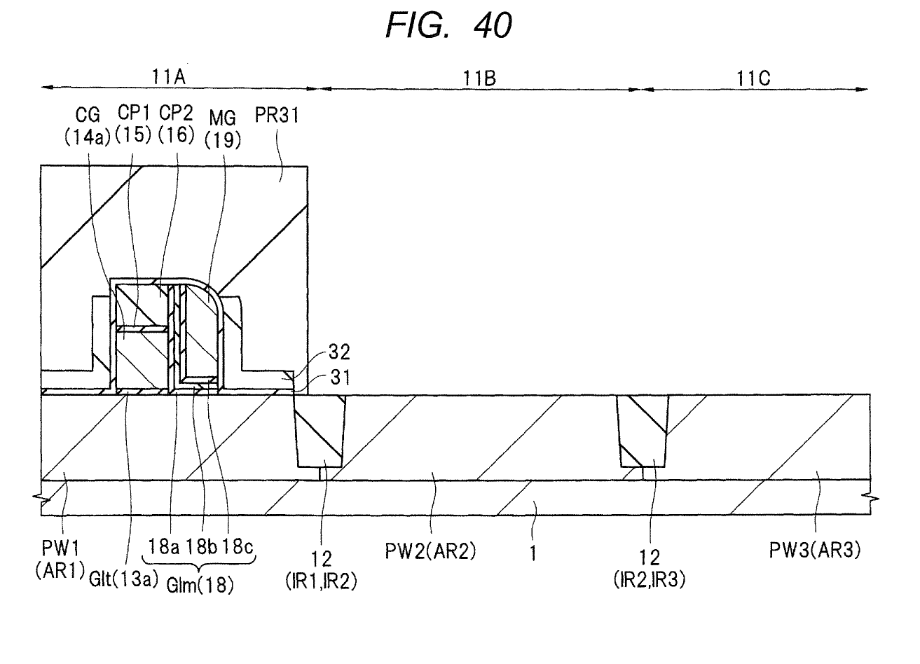

Next, as shown in FIG. 40, the p-type well PW2 is formed in the active region AR2 in the peripheral circuit region 11B, and the p-type well PW3 is formed in the active region AR3 in the peripheral circuit region 11C (Step S13 in FIG. 27). The p-type wells PW2 and PW3 can be formed by introducing a p-type impurity such as, e.g., boron (B) into the semiconductor substrate 1 by an ion implantation method or the like, similarly to the p-type well PW1. For example, using a resist film PR31 covering the memory cell region 11A and having an opening in the peripheral circuit regions 11B and 11C as a mask, a p-type impurity is ion-implanted into the semiconductor substrate 1. The p-type wells PW2 and PW3 are formed to extend from the main surface 1a of the semiconductor substrate 1 over predetermined depths.

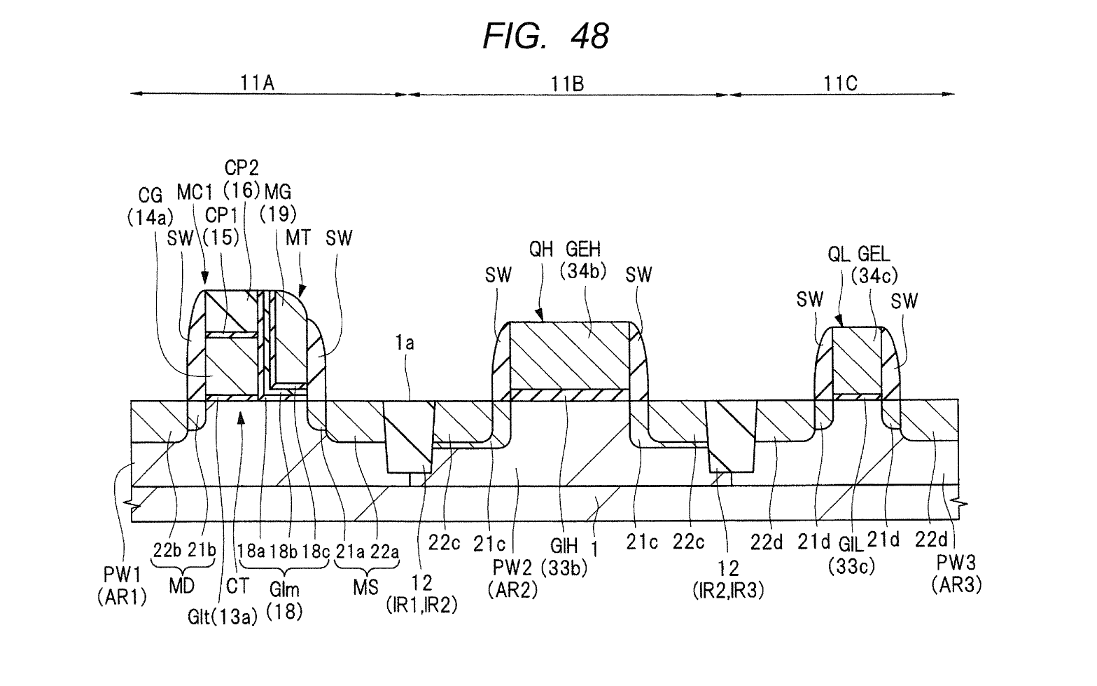

Preferably, a p-type impurity concentration in the p-type well PW2 is lower than a p-type impurity concentration in the p-type well PW3. This allows the drive voltage of the higher-breakdown-voltage MISFET QH (see FIG. 48 described later) to be higher than that of the lower-breakdown-voltage MISFET QL (see FIG. 48 described later). Next, the portion of the resist film PR30 which is left in the memory cell region 11A is removed.

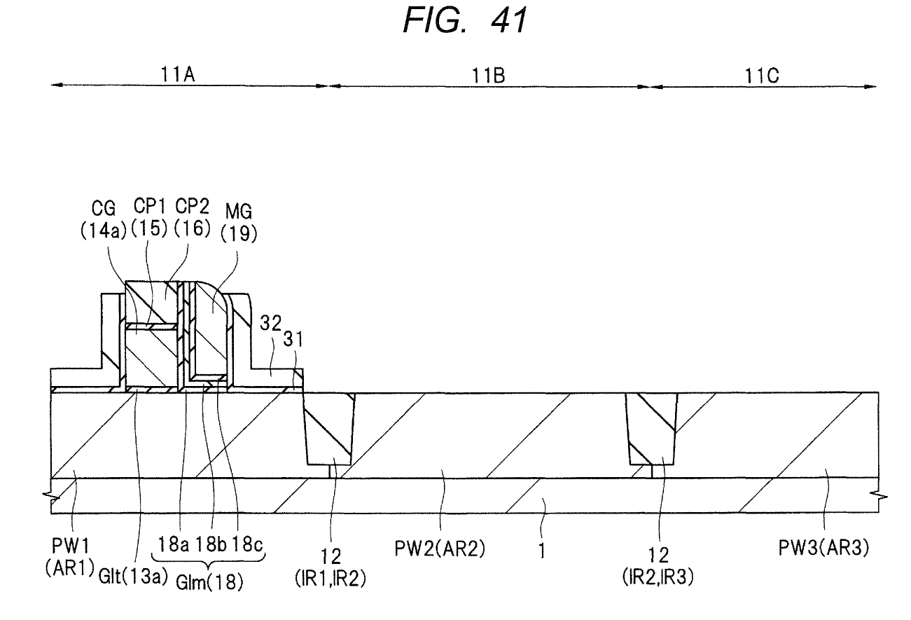

Next, a natural oxide film over the top surface of the semiconductor substrate 1 is removed by wet etching using, e.g., an aqueous hydrofluoric acid (HF) solution or the like. The top surface of the semiconductor substrate 1 is washed to be cleaned. This exposes the top surface of the semiconductor substrate 1, i.e., the top surfaces of the p-type wells PW2 and PW3 in the peripheral circuit regions 11B and 11C (FIG. 41).

Next, as shown in FIGS. 41 to 43, over the entire main surface 1a of the semiconductor substrate 1, the insulating films 33 and the conductive film 34 are formed (Step S14 in FIG. 27).

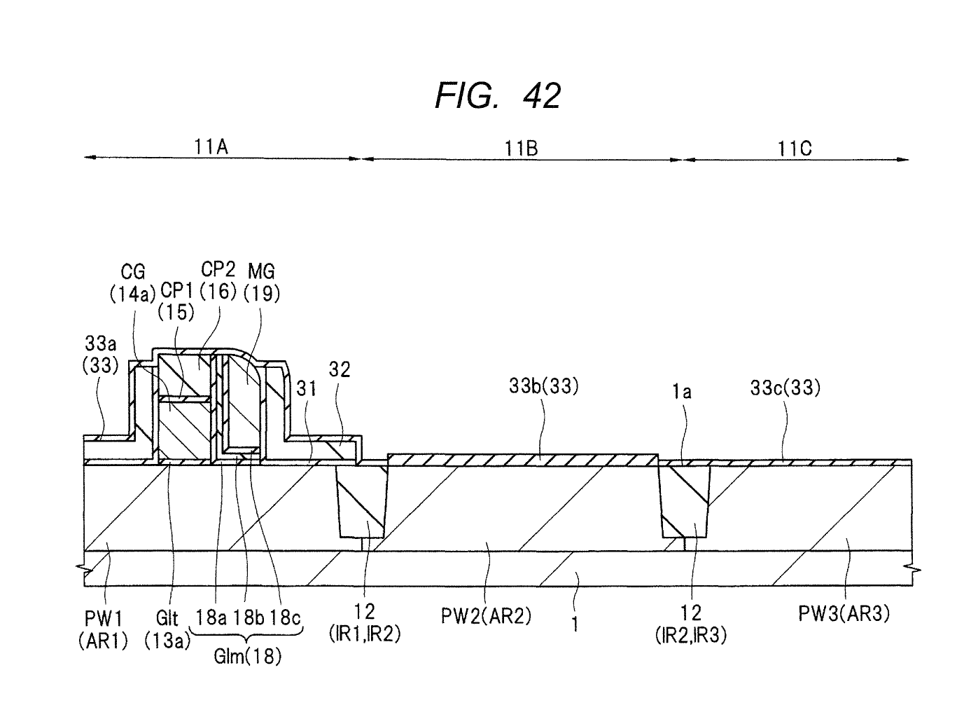

In Step S14, as shown in FIG. 41, the portion of the resist film PR30 which is left in the memory cell region 11A is removed and, as shown in FIG. 42, in each of the memory cell region 11A and the peripheral circuit regions 11B and 11C, over the main surface 1a of the semiconductor substrate 1, the insulating film 33 is formed. Of the insulating film 33, the portion formed in the memory cell region 11A is referred to as an insulating film 33a, the portion formed in the peripheral circuit region 11B is referred to as an insulating film 33b, and the portion formed in the peripheral circuit region 11C is referred to as an insulating film 33c. The insulating film 33b is formed in the same layer as that of the insulating film 33a. The insulating film 33c is formed in the same layer as that of the insulating film 33a. The insulating film 33b is for the gate insulating film GIH (see FIG. 48 described later) of the MISFET QH (see FIG. 48 described later). The insulating film 33c is for the gate insulating film GIL (see FIG. 48 described later) of the MISFET QL (see FIG. 48 described later). The insulating film 33b is formed over the p-type well PW2. The insulating film 33c is formed over the p-type well PW3.

In the example shown in FIG. 42, the insulating film 33b is formed integrally with the insulating film 33a, and the insulating film 33c is formed integrally with the insulating film 33a. However, the insulating film 33b may also be formed separately from the insulating film 33a, and the insulating film 33c may also be formed separately from the insulating film 33a.

As the insulating film 33 described above as the insulating film 33b, a silicon dioxide film, a silicon nitride film, a silicon oxynitride film, or a High-k film, i.e., high-dielectric-constant film can also be used. Examples of a material which can be used for the insulating film 33 are as described above for the insulating film 33b. The insulating film 33 can also be formed using a thermal oxidation method, a sputtering method, an ALD method, a CVD method, or the like.

As described above, the MISFET QH (see FIG. 48 described later) formed in the peripheral circuit region 11B is the higher-breakdown-voltage MISFET, and the MISFET QL (see FIG. 48 described later) formed in the peripheral circuit region 11C is the lower-breakdown-voltage MISFET. Accordingly, a thickness TIb of the insulating film 33b for the gate insulating film GIH (see FIG. 48 described later) is preferably larger than a thickness TIc of the insulating film 33c for the gate insulating film GIL (see FIG. 48 described later). In such a case, it is assumed that the insulating film 33b is made of a laminated film including an insulating film formed by oxidizing the upper surface of the p-type well PW2, and an insulating film formed by, e.g., a CVD method, and the insulating film 33c is made of an insulating film formed by oxidizing the upper surface of the p-type well PW3. Such a method allows the thickness TIb of the insulating film 33b to be larger than the thickness TIc of the insulating film 33c.

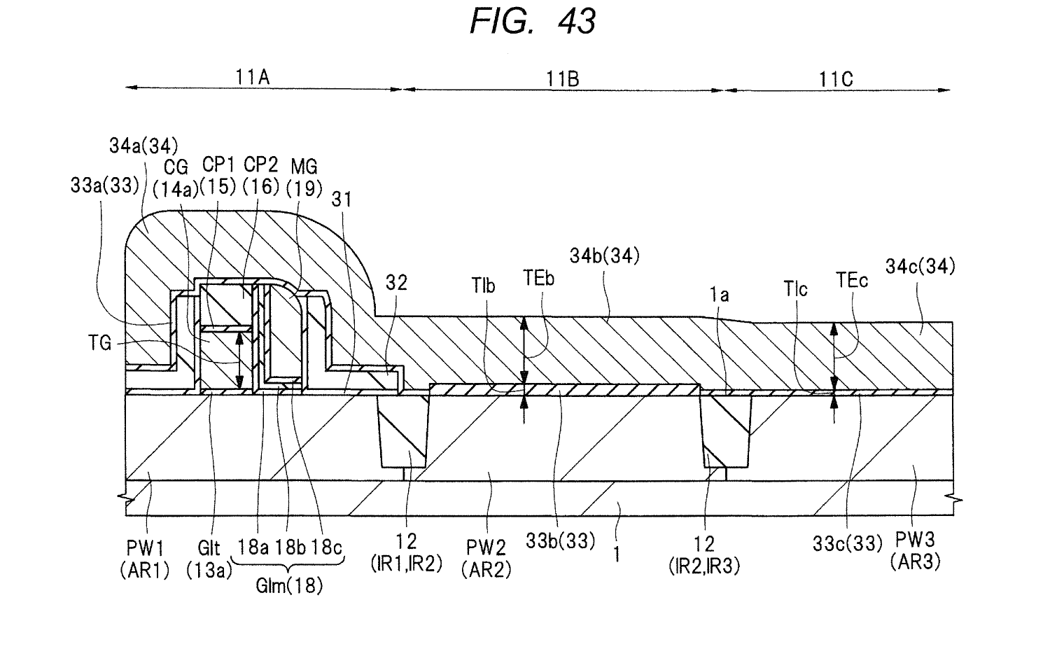

In Step S14, next, as shown in FIG. 43, in each of the memory cell region 11A and the peripheral circuit regions 11B and 11C, the conductive film 34 is formed over the insulating film 33. Of the conductive film 34, the portion formed in the memory cell region 11A is referred to as a conductive film 34a, the portion formed in the peripheral circuit region 11B is referred to as the conductive film 34b, and the portion formed in the peripheral circuit region 11C is referred to as the conductive film 34c. The conductive film 34b is formed in the same layer as that of the conductive film 34a. The conductive film 34c is formed in the same layer as that of the conductive film 34a. The conductive film 34b is for the gate electrode GEH (see FIG. 48 described later) of the MISFET QH (see FIG. 48 described later). The conductive film 34c is for the gate electrode GEL (see FIG. 48 described later) of the MISFET QL (see FIG. 48 described later).

In the example shown in FIG. 43, the conductive film 34b is formed integrally with the conductive film 34a, and the conductive film 34c is formed integrally with the conductive film 34a. However, the conductive film 34b may also be formed separately from the conductive film 34a, and the conductive film 34c may also be formed separately from the conductive film 34a.

Preferably, the conductive film 34 is made of a polycrystalline silicon film, i.e., a polysilicon film. The conductive film 34 can be formed using a CVD method or the like. The conductive film 34 is allowed to have a sufficient thickness to cover the insulating film 33. It may also be possible to deposit an amorphous silicon film as the conductive film 34 and then change the amorphous silicon film to a polycrystalline silicon film.

As the conductive film 34, a conductive film having a low resistivity due to, e.g., an n-type impurity such as phosphorus (P) or arsenic (As) or a p-type impurity such as boron (B) introduced therein is preferably used. The impurity can be introduced during or after the deposition of the conductive film 34. When the impurity is introduced during the deposition of the conductive film 34, by causing a gas for depositing the conductive film 34 to include a doping gas, the conductive film 34 into which the impurity has been introduced can be deposited. On the other hand, when the impurity is introduced after the deposition of the silicon film, the silicon film is deposited without intentional introduction of an impurity. Then, an impurity is introduced into the silicon film by an ion implantation method or the like to allow the conductive film 34 into which the impurity has been introduced to be formed.

A thickness TEc of the conductive film 34c can be set equal to a thickness TEb of the conductive film 34b. Each of the thickness TEb of the conductive film 34b and the thickness TEc of the conductive film 34c can be set different from a thickness TG of the control gate electrode CG.

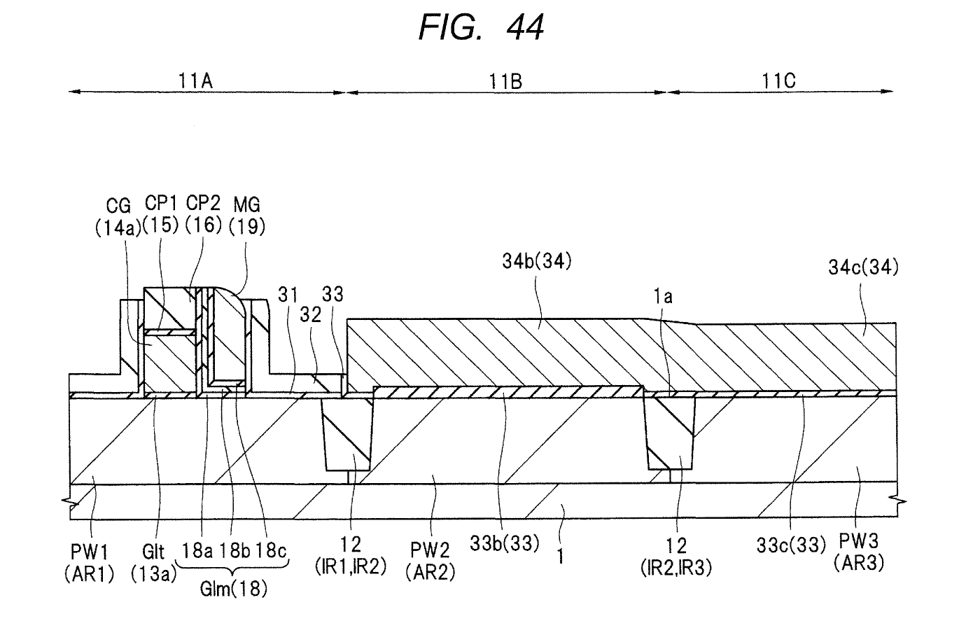

Next, as shown in FIG. 44, the conductive film 34 is removed from the memory cell region 11A (Step S15 in FIG. 27).

In Step S15, first, in each of the memory cell region 11A and the peripheral circuit regions 11B and 11C, a resist film (the illustration thereof is omitted) is formed so as to cover the conductive film 34. Then, the resist film is subjected to pattern exposure and then developed to be patterned. The resist film is removed from the memory cell region 11A and left in the peripheral circuit regions 11B and 11C. Thus, a resist pattern made of the portions of the resist film which are left in the peripheral circuit regions 11B and 11C is formed.

Next, using the resist pattern as an etching mask, the conductive film 34 is etched by, e.g., dry etching or the like to be removed. This can completely remove the portion of the insulating film 34 which is left in the memory cell region 11A, i.e., the conductive film 34a, as shown in FIG. 44. Then, the portions of the resist film which are left in the peripheral circuit regions 11B and 11C, i.e., the resist pattern is removed.

Note that, in Step S15, as shown in FIG. 44, when the conductive film 34 is removed from the memory cell region 11A, the insulating film 33 may also be removed together with the conductive film 34 from the memory cell region 11A.

Alternatively, when the conductive film 34 and the insulating film 33 are removed from the memory cell region 11A in Step S15, the portions of the insulating films 32 and 31 which are left in the memory cell region 11A may also be removed. However, in the case where the portions of the insulating films 32 and 31 which are left in the memory cell region 11A are removed when the conductive film 34 and the insulating film 33 are removed, it is preferable to form an insulating film corresponding to the insulating films 31 and 32 again in the memory cell region 11A before a process step in Step S16 described later is performed thereafter.

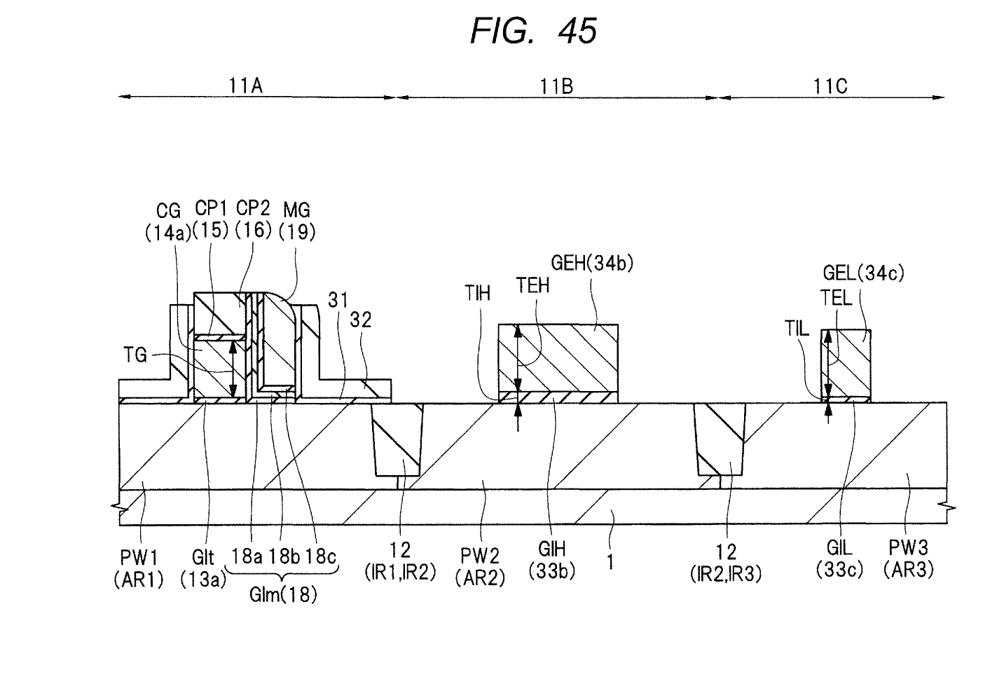

Next, as shown in FIG. 45, in the peripheral circuit regions 11B and 11C, the conductive pattern 34 is patterned (Step S16 in FIG. 27). In Step S16, in the peripheral circuit regions 11B and 11C, the conductive film 34 is patterned using, e.g., photolithography and etching.

First, over the entire main surface 1a of the semiconductor substrate 1, a resist film is formed. Then, in the area of the peripheral circuit region 11B other than the area thereof where the gate electrode GEH is to be formed, an opening is formed to extend through the resist film and reach the conductive film 34 while, in the area of the peripheral circuit region 11C other than the area thereof where the gate electrode GEL is to be formed, an opening is formed to extend through the resist film and reach the conductive film 34. Then, a resist pattern made of the resist film having the opening formed in the peripheral circuit regions 11B and 11C is formed. At this time, the portion of the conductive film 34b which is located in the area of the peripheral circuit region 11B where the gate electrode GEH is to be formed and the portion of the conductive film 34c which is located in the area of the peripheral circuit region 11C where the gate electrode GEL is to be formed are covered with the resist film. Also, the portion of the insulating film 32 which is left in the memory cell region 11A is covered with the resist film.

Next, using the resist pattern as an etching mask, the conductive film 34 is etched by, e.g., dry etching or the like to be patterned.

As a result, in the peripheral circuit region 11B, the gate electrode GEH made of the conductive film 34b is formed, and the gate insulating film GIH made of the insulating film 33b located between the gate electrode GEH and the p-type well RW2 of the semiconductor substrate 1 is formed. That is, in the peripheral circuit region 11B, the gate electrode GEH is formed over the p-type well PW2 of the semiconductor substrate 1 via the gate insulating film GIH.

Also, in the memory cell region 11C, the gate electrode GEL made of the conductive film 34c is formed, and the gate insulating film GIL made of the insulating film 33c located between the gate electrode GEL and the p-type well PW3 of the semiconductor substrate 1 is formed. That is, in the peripheral circuit region 11C, the gate electrode GEL is formed over the p-type well PW3 of the semiconductor substrate 1 via the gate insulating film GIL.

On the other hand, in the memory cell region 11A, the memory gate electrode MG and the control gate electrode CG are each covered with the resist pattern via the insulating films 31 and 32. Accordingly, the memory gate electrode MG and the control gate electrode CG are not etched. Then, the resist pattern, i.e., the resist film is removed.

Note that, in the peripheral circuit region 11B, the portion of the insulating film 33b which is uncovered with the gate electrode GEH can be removed by performing dry etching in Step S16 or performing wet etching after the dry etching in Step S16. Also, in the peripheral circuit region 11C, the portion of the insulating film 33c which is uncovered with the gate electrode GEL can be removed by performing dry etching in Step S16 or performing wet etching after the dry etching in Step S16.

As described above, when the thickness TIb (see FIG. 43) of the insulating film 33b is larger than the thickness TIc (see FIG. 43) of the insulating film 33c, the thickness TIH of the gate insulating film GIH made of the insulating film 33b is larger than the thickness TIL of the gate insulating film GIL made of the insulating film 33c. This allows the gate insulating film GIH to serve as the gate insulating film of the higher-breakdown-voltage MISFET QH (see FIG. 48 described later) and allows the gate insulating film GIL to serve as the gate insulating film of the lower-breakdown-voltage MISFET QL (see FIG. 48 described later).

Also, as stated previously, the thickness TEc (see FIG. 43) of the conductive film 34c can be set equal to the thickness TEb (see FIG. 43) of the conductive film 34b, and each of the thickness TEb of the conductive film 34b and the thickness TEc of the conductive film 34c can be set different from the film thickness TG of the control gate electrode CG. Therefore, the film thickness TEL of the gate electrode GEL made of the conductive film 34c can be set equal to the film thickness TEH of the gate electrode GEH made of the conductive film 34b, and each of the film thickness TEH of the gate electrode GEH and the film thickness TEL of the gate electrode GEL can be set different from the film thickness TG of the control gate electrode CG.

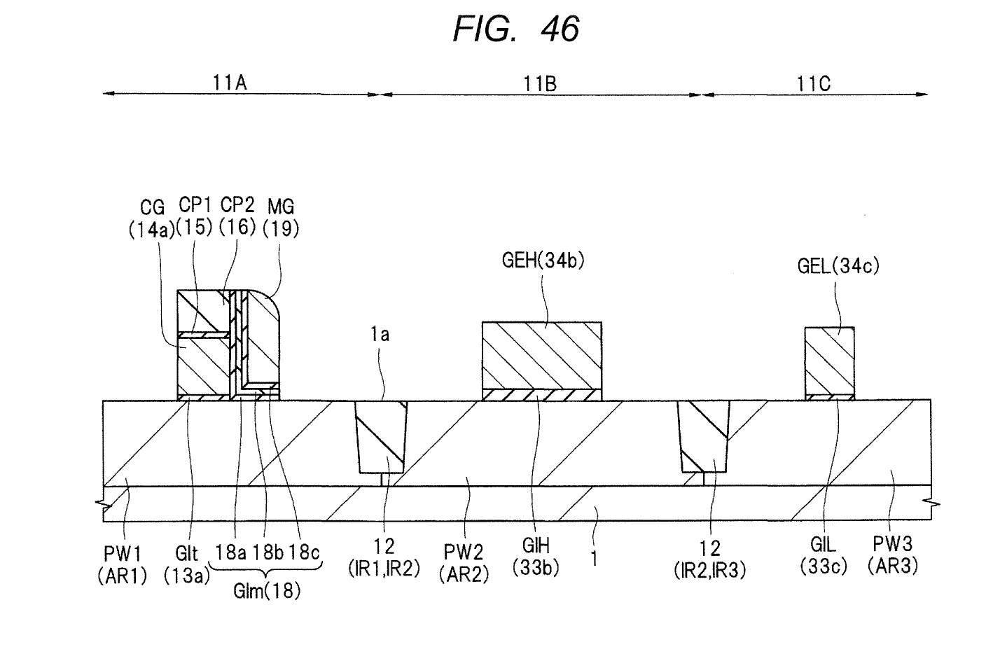

Next, as shown in FIG. 46, the insulating films 32 and 31 are removed (Step S17 in FIG. 27).

In Step S17, first, a resist film (the illustration thereof is omitted) is formed so as to cover the cap insulating film CP2, the control gate electrode CG, and the memory gate electrode MGE via the insulating films 31 and 32 in the memory cell region 11A. The resist film (the illustration thereof is omitted) is also formed so as to cover the gate electrode GEH in the peripheral circuit region 11B and cover the gate electrode GEL in the peripheral circuit region 11C.

Next, the resist film is subjected to pattern exposure and then developed to be patterned. Thus, the resist film is removed from the memory cell region 11A and left in the peripheral circuit regions 11B and 11C. In this manner, the resist pattern made of the portion of the resist film which is left in the peripheral circuit regions 11B and 11C is formed.

Next, using the resist pattern as an etching mask, the insulating films 32 and 31 are etched by, e.g., dry etching or the like to be removed. This can completely remove the portion of the insulating film 32 which is left in the memory cell region 11A and the portion of the insulating film 31 which is left in the memory cell region 11A, as shown in FIG. 46. Then, the portion of the resist film which is left in the peripheral circuit regions 11B and 11C, i.e., the resist pattern is removed.

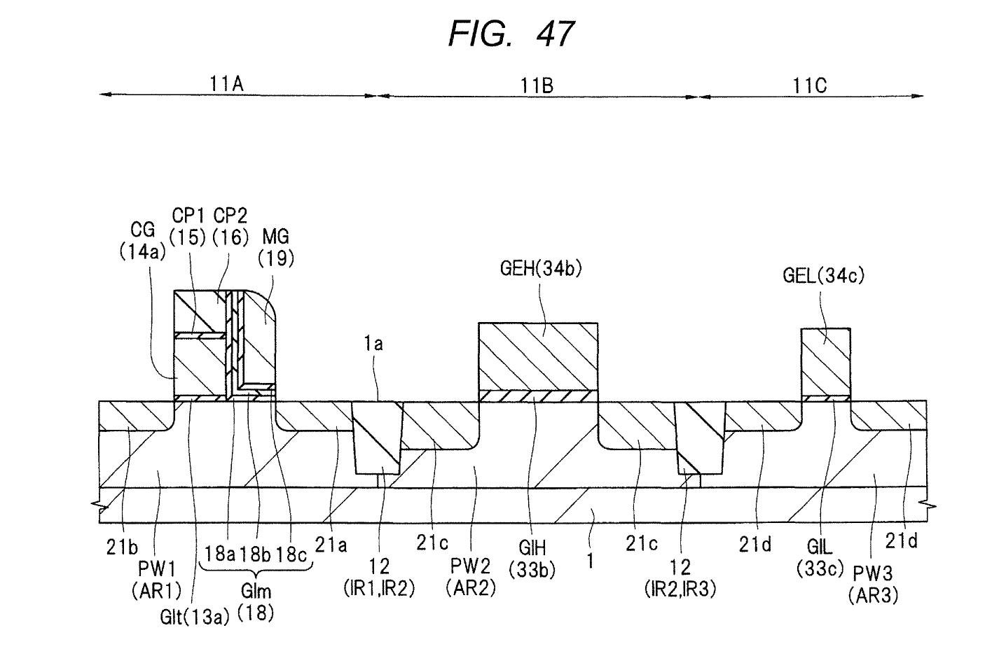

Next, as shown in FIG. 47, the n⁻-type semiconductor regions 21a, 21b, 21c, and 21d are formed using an ion implantation method or the like (Step S18 in FIG. 27). In Step S18, an n-type impurity such as, e.g., arsenic (As) or phosphorus (P) is introduced into the p-type wells PW1, PW2, and PW3 of the semiconductor substrate 1 using the control gate electrode CG, the memory gate electrode MG, and the gate electrodes GEH and GEL as a mask. Thus, the n⁻-type semiconductor regions 21a, 21b, 21c, and 21d are formed.

At this time, in the memory cell region 11A, the n⁻-type semiconductor region 21a is formed by self-alignment with the side surface of the memory gate electrode MG. Also, in the memory cell region 11A, the n⁻-type semiconductor region 21b is formed by self-alignment with the side surface of the control gate electrode CG. On the other hand, in the peripheral circuit region 11B, the n⁻-type semiconductor region 21c is formed by self-alignment with the side surface of the gate electrode GEH. In the peripheral circuit region 11C, the n⁻-type semiconductor region 21d is formed by self-alignment with the side surface of the gate electrode GEL.

In the example shown in FIG. 48, an implantation energy when the n⁻-type semiconductor region 21c is formed by an ion implantation method is set higher than an implantation energy when the n⁻-type semiconductor region 21d is formed by an ion implantation method. This allows the depth position of the lower surface of the n⁻-type semiconductor region 21c to be deeper than the depth position of the lower surface of the n⁻-type semiconductor region 21d.

Note that the n⁻-type semiconductor regions 21a, 21b, 21c, and 21d can also be formed by the same ion implantation step.

Next, as shown in FIG. 48, over the side wall of the control gate electrode CG, the side wall of the memory gate electrode MG, the side wall of the gate electrode GEH, and the side wall of the gate electrode GEL, the sidewall spacers SW are formed (Step S19 in FIG. 27).

First, over the entire main surface 1a of the semiconductor substrate 1, an insulating film for the sidewall spacers SW is formed and etched back by, e.g., anisotropic etching. Thus, over the sidewall of the control gate electrode CG, the side wall of the memory gate electrode MG, the side wall of the gate electrode GEH, and the side wall of the gate electrode GEL, the insulating film is selectively left to form the sidewall spacers SW. Each of the sidewall spacers SW is made of an insulating film such as a silicon dioxide film, a silicon nitride film, or a laminated film thereof.

Next, as shown in FIG. 48, the n⁺-type semiconductor regions 22a, 22b, 22c, and 22d are formed using an ion implantation method or the like (Step S20 in FIG. 27). In Step S20, an n-type impurity such as, e.g., arsenic (As) or phosphorus (P) is introduced into the p-type wells PW1, PW2, and PW3 of the semiconductor substrate 1 using the control gate electrode CG, the memory gate electrode MG, the gate electrodes GEH and GEL, and the sidewall spacers SW over the side walls thereof as a mask. Thus, the n⁺-type semiconductor regions 22a, 22b, 22c, and 22d are formed.

At this time, in the memory cell region 11A, the n⁺-type semiconductor region 22a is formed by self-alignment with the sidewall spacer SW over the side wall of the memory gate electrode MG. Also, in the memory cell region 11A, the n⁺-type semiconductor region 22b is formed by self-alignment with the sidewall spacer SW over the side wall of the control gate electrode CG. On the other hand, in the peripheral circuit region 11B, the n⁺-type semiconductor region 22c is formed by self-alignment with the sidewall spacers SW over the both side walls of the gate electrode GEH. In the peripheral circuit region 11C, the n⁺-type semiconductor region 22d is formed by self-alignment with the sidewall spacers SW over the both side walls of the gate electrode GEL. In this manner, LDD structures are formed.

In the present embodiment, an implantation energy when the n⁺-type semiconductor region 22c is formed by an ion implantation method is set generally equal to an implantation energy when the n⁺-type semiconductor region 22d is formed by an ion implantation method. This allows the depth position of the lower surface of the n⁺-type semiconductor region 22c to be generally equal to the depth position of the lower surface of the n⁺-type semiconductor region 22d. Therefore, it is possible to set the depth position of the lower surface of the n⁺-type semiconductor region 22c to be shallower than the depth position of the lower surface of the n⁻-type semiconductor region 21c and set the depth position of the lower surface of the n⁺-type semiconductor region 22d to be deeper than the depth position of the lower surface of the n⁻-type semiconductor region 21d.

Note that the n⁺-type semiconductor regions 22a, 22b, 22c, and 22d can also be formed by different ion implantation steps.

Thus, the n⁻-type semiconductor region 21a and the n⁺-type semiconductor region 22a having an impurity concentration higher than that of the n⁻-type semiconductor region 21a form the n-type semiconductor region MS functioning as the source region of the memory transistor MT. Also, the n⁻-type semiconductor region 21b and the n⁺-type semiconductor region 22b having an impurity concentration higher than that of the n⁻-type semiconductor region 21b form the n-type semiconductor region MD functioning as the drain region of the control transistor CT. The semiconductor region MS is formed in the upper-layer portion of the part of the p-type well PW1 which is located opposite to the control gate electrode CG relative to the memory gate electrode MG interposed therebetween in plan view. The semiconductor region MD is formed in the upper-layer portion of the part of the p-type well PW1 which is located opposite to the memory gate electrode MG relative to the control gate electrode CG interposed therebetween in plan view.

Then, activation anneal as heat treatment for activating the impurities introduced into the n⁻-type semiconductor regions 21a, 21b, 21c, and 21d, the n⁺-type semiconductor regions 22a, 22b, 22c, and 22d, and the like is performed.

As a result, as shown in FIG. 48, in the memory cell region 11A, the control transistor CT and the memory cell transistor MT are formed to form the memory cell MC1 as the nonvolatile memory. That is, the control gate electrode CG, the gate insulating film GIt, the memory gate electrode MG, and the gate insulating film GIm form the memory cell MC1 as the nonvolatile memory.

On the other hand, as shown in FIG. 48, in the peripheral circuit region 11B, the higher-breakdown-voltage MISFET QH is formed while, in the peripheral circuit region 11C, the lower-breakdown-voltage MISFET QL is formed. That is, the gate electrode GEH and the gate insulating film GIH form the higher-breakdown-voltage MISFET QH, and the gate electrode GEL and the gate insulating film GIL form the lower-breakdown-voltage MISFET QL.

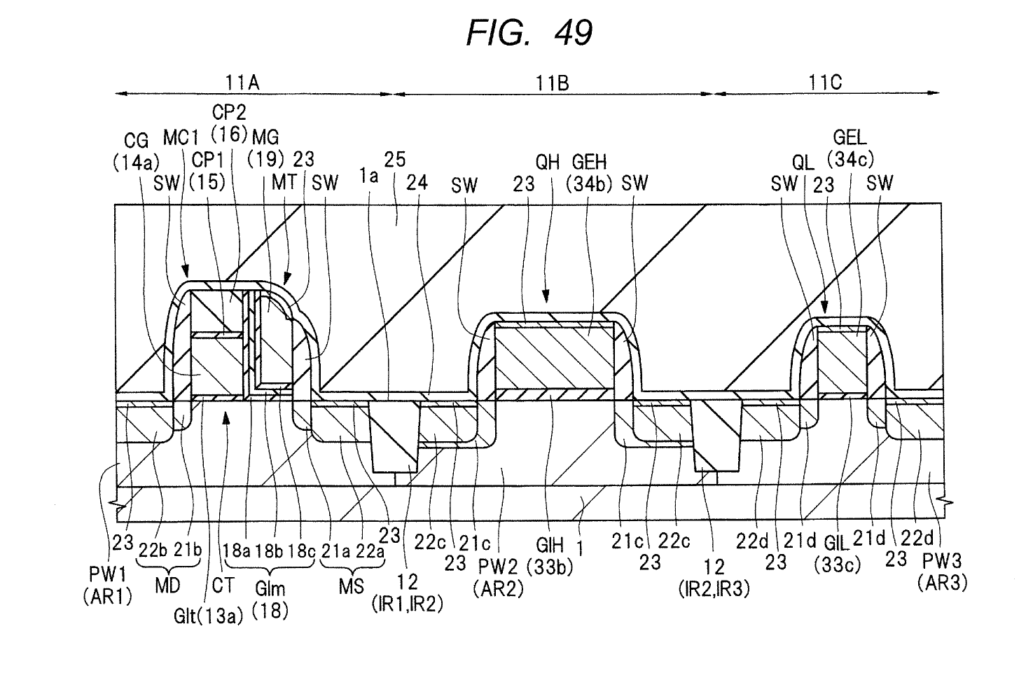

Next, as shown in FIG. 49, the metal silicide layers 23, the insulating film 24, and the interlayer insulating film 25 are formed (Step S21 in FIG. 27).

In Step S21, first, as shown in FIG. 49, the metal silicide layers 23 are formed. Over the entire main surface 1a of the semiconductor substrate 1, a metal film is formed so as to cover the cap insulating film CP2, the gate insulating film GIm, the memory gate electrode MG, the gate electrodes GEH and GEL, and the sidewall spacers SW. The metal film is made of, e.g., a cobalt (Co) film, a nickel (Ni) film, a nickel-platinum alloy film, or the like and can be formed using a sputtering method or the like. Then, heat treatment is performed on the semiconductor substrate 1 to cause the respective upper-layer portions of the n⁺-type semiconductor regions 22a, 22b, 22c, and 22d to react with the metal film. Thus, over the n⁺-type semiconductor regions 22a, 22b, 22c, and 22d, the respective metal silicide layers 23 are formed.

Each of the metal silicide layers 23 can be, e.g., a cobalt silicide layer, a nickel silicide layer, or a platinum-added nickel silicide layer. Then, the unreacted metal film is removed. By performing such a so-called salicide process, as shown in FIG. 49, over the n⁺-type semiconductor regions 22a, 22b, 22c, and 22d, the respective metal silicide layers 23 can be formed. Note that, over the memory gate electrode MG and the gate electrodes GEH and GEL also, the respective metal silicide layers 23 can be formed.

In Step S21, next, as shown in FIG. 49, the insulating film 24 is formed. The insulating film 24 is formed so as to cover the cap insulating film CP2, the gate insulating film GIm, the memory gate electrode MG, the gate electrodes GEH and GEL, and the sidewall spacers SW. The insulating film 24 is made of, e.g., a silicon nitride film. The insulating film 24 can be formed by, e.g., a CVD method.

In Step S21, next, as shown in FIG. 49, over the insulating film 24, the interlayer insulating film 25 is formed. The interlayer insulating film 25 is made of a single-layer silicon dioxide film, a laminated film including a silicon nitride film and a silicon dioxide film, or the like. After the interlayer insulating film 25 is formed by, e.g., a CVD method, the upper surface of the interlayer insulating film 25 is planarized.

Next, as shown in FIG. 23, the plugs PG are formed to extend through the interlayer insulating film 25 (Step S22 in FIG. 27). First, using a resist pattern (not shown) formed over the interlayer insulating film 25 using photolithography as an etching mask, the inter-layer insulating film 25 is dry-etched to be formed with the contact holes CNT. Then, in the contact holes CNT, the conductive plugs PG made of tungsten (W) or the like are formed as conductor portions.

To form the plugs PG, e.g., over the interlayer insulating film 25 including the inner surfaces of the contact holes CNT, a barrier conductor film made of, e.g., a titanium (Ti) film, a titanium nitride (TiN) film, or a laminated film thereof is formed. Then, over the barrier conductor film, a main conductor film made of a tungsten (W) film or the like is formed so as to be embedded in the contact holes CNT. The unneeded main conductor film and the unneeded barrier conductor film over the interlayer insulating film 25 are removed by a CMP (Chemical Mechanical Polishing) method, an etch-back method, or the like. Thus, the plugs PG can be formed. Note that, in FIG. 23, for simpler illustration, the barrier conductor film and the main conductor film which are included in the plugs PG are integrally shown.

The contact holes CNT and the plugs PG embedded therein are formed over the n⁺-type semiconductor regions 22a, 22b, 22c, and 22d, the control gate electrode CG, the memory gate electrodes MG, the gate electrodes GEH and GEL, and the like. At the bottom portion of each of the contact holes CNT, e.g., a part of the metal silicide layer 23 over the n⁺-type semiconductor regions 22a, 22b, 22c, or 22d, a part of the metal silicide layer 23 over the control gate electrode CG, or a part of the metal silicide layer 23 over the memory gate electrode 23 is exposed. Alternatively, at the bottom portion of each of the contact holes CNT, e.g., a part of the metal silicide layer 23 over the gate electrode GEH or the gate electrode GEL is exposed.

Note that FIG. 23 shows a cross section in which parts of the respective metal silicide layers 23 over the n⁺-type semiconductor regions 22a, 22b, 22c, and 22d are exposed at the bottom portions of the contact holes CNT and electrically coupled to the plugs PG embedded in the contact holes CNT.

In this manner, the semiconductor device in the present embodiment described above using FIG. 23 is manufactured. Note that, over the interlayer insulating film 25 in which the plugs PG are embedded, wires each using, e.g., copper (Cu) for a main conductive film can be formed using, e.g., a damascene technique, but the description thereof is omitted herein.

<About Variations in Properties of MISFETs Formed in Peripheral Circuit Regions>

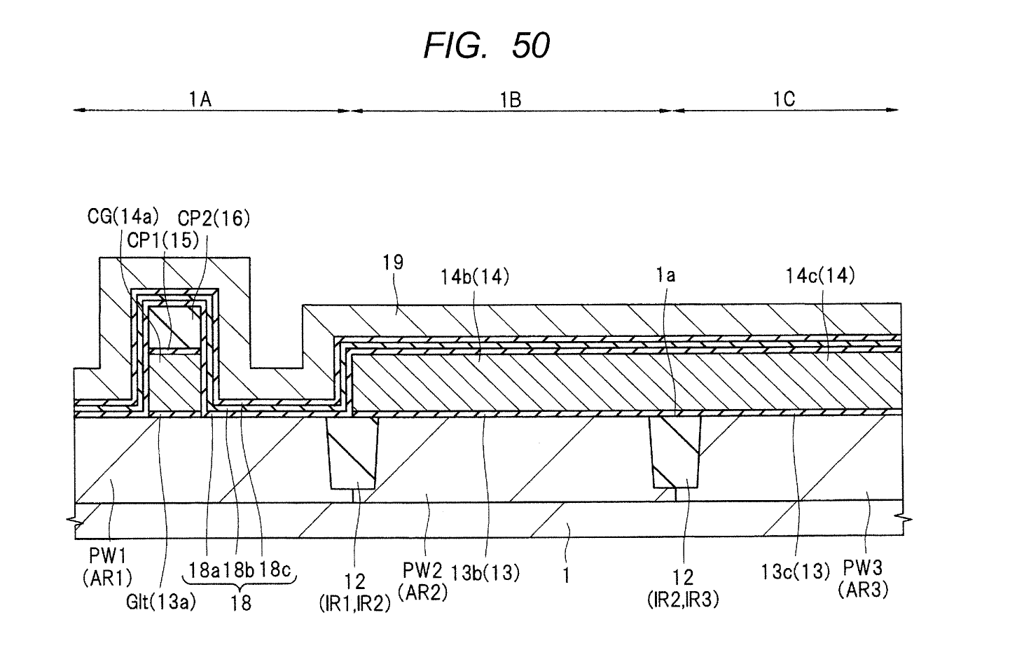

Next, a description will be given of variations in the properties of the MISFETs formed in the peripheral circuit regions in contrast to those in a method of manufacturing a semiconductor device in a comparative example. FIG. 50 is a main-portion cross-sectional view of the semiconductor device in the comparative example during the manufacturing process thereof.

In the method of manufacturing the semiconductor device in the comparative example, in the same manner as in the method of manufacturing the semiconductor device in Embodiment 2, process steps corresponding to Steps S1 and S2 in FIG. 26 are performed. Then, in the method of manufacturing the semiconductor device in the comparative example, unlike in the manufacturing process of the semiconductor device in Embodiment 2, a process step corresponding to Step S3 in FIG. 26 is performed to form the p-type well PW2 in the active region AR2 in the peripheral circuit region 11B and form the p-type well PW3 in the active region AR3 in the peripheral circuit region 11C.

In the method of manufacturing the semiconductor device in the comparative example, process steps corresponding to Steps S4 to S8 in FIG. 26 are subsequently performed to form the insulating film 18 as the ONO film and the conductive film 19, as shown in FIG. 50.

However, when the insulating film 18 as the ONO film is formed, as described above, high-temperature treatment at, e.g., about 1025° C. is performed. In the comparative example, prior to the formation of the insulating film 18, the p-type well PW3 as a semiconductor region has already been formed in the peripheral circuit region 11C. Accordingly, when the insulating film 18 is formed, the n-type impurity introduced in the p-type well PW3 is diffused at a high temperature to change an impurity concentration distribution in the p-type well PW3. As a result, the threshold voltage of the MISFET QL formed in the peripheral circuit region 11C or the like varies and the performance of the semiconductor device including the nonvolatile memory cannot be improved.

<Main Characteristic Features and Effects of Embodiment 2>

On the other hand, in the method of manufacturing the semiconductor device in Embodiment 2, in the memory cell region 11A, the control gate electrode CG made of the conductive film 14a is formed over the main surface 1a of the semiconductor substrate 1. Then, the insulating film 18 as the ONO film and the conductive film 19 are formed so as to cover the control gate electrode CG. The conductive film 19 is etched back to be left over the side wall of the control gate electrode CG via the insulating film 18 and form the memory gate electrode MG. Then, in the peripheral circuit region 11C, the p-type well PW3 is formed in the main surface 1a of the semiconductor substrate 1 and, over the p-type well PW3, the conductive film 34 is formed. Thereafter, the gate electrode GEL made of the conductive film 34 is formed.

In the step of forming the insulating film 18 as the ONO film, as described above, the high-temperature treatment at, e.g., 1025° C. is performed. Thus, according to the present embodiment, after the insulating film 18 is formed, the p-type well PW3 is formed. This can prevent the n-type impurity introduced in the p-type well PW3 from being diffused at a high temperature when the insulating film 18 is formed. This can prevent a change in the impurity concentration distribution in the p-type well PW3. Therefore, it is possible to prevent or inhibit the threshold voltage of the MISFET QL formed in the peripheral circuit region 11C or the like from varying and improve the performance of the semiconductor device including the nonvolatile memory.

Since the insulating film (silicon nitride film) 32 has been removed from over the memory cell MC1, in the same manner as in the case in Embodiment 1, the degradation of the properties of the memory cell MC due to H (hydrogen) in the silicon nitride film can be avoided. That is, it is possible to avoid the diffusion of H (hydrogen) in the silicon nitride film into the MISFET under a heat load during the formation of, e.g., the insulating film 33 or the like and inhibit the driving ability of the MISFET from deteriorating.

### Embodiment 3

In the present embodiment, a description will be given of various application examples of the foregoing embodiments.

### Application Example 1

In Embodiment 2, the p-type well PW2 is formed when the p-type well PW3 is formed after the formation of the memory gate electrode MG. However, the p-type wells PW1 and PW2 may also be formed prior to the formation of the memory gate electrode MG. In this case, e.g., the gate electrode GEH may also be formed using the conductive film 14b (see FIG. 29).

In such a case, when the insulating film 18 as the ONO film is formed, the p-type well PW2 has already been formed. Accordingly, the n-type impurity introduced in the p-type well PW2 may rather be diffused during the formation of the insulating film 18. However, even when the n-type impurity introduced in the p-type well PW2 is rather diffused, due to the gate length of the higher-breakdown-voltage MISFET QH which is longer than the gate length of the lower-breakdown-voltage MISFET QL or the like, a variation in the threshold voltage of the higher-breakdown-voltage MISFET QH is smaller than a variation in the threshold voltage of the lower-breakdown-voltage MISFET QL. That is, the properties of the higher-breakdown-voltage MISFET QH are less significantly affected by forming the insulating film 18 as the ONO film at a higher temperature than the properties of the lower-breakdown-voltage MISFET QL.

Accordingly, the gate electrode GEH of the higher-breakdown-voltage MISFET QH which is less affected by the high temperature when the insulating film 18 as the ONO film is formed is formed together with the control gate electrode CG of the memory cell MC1 prior to the formation of the insulating film 18. This can simplify the manufacturing process of the semiconductor device.

### Application Example 2

In Embodiment 2, the coating film CF is formed to cover the insulating film 32 in the peripheral circuit regions 11B and 11C and expose the insulating film 32 over the control gate electrode portion (the laminated film portion including the control gate electrode CG and the cap insulating film) in the memory cell region 11A (see FIG. 35). However, the coating film CF may also be formed so as to expose the insulating film 32 in the peripheral circuit regions 11B and 11C.

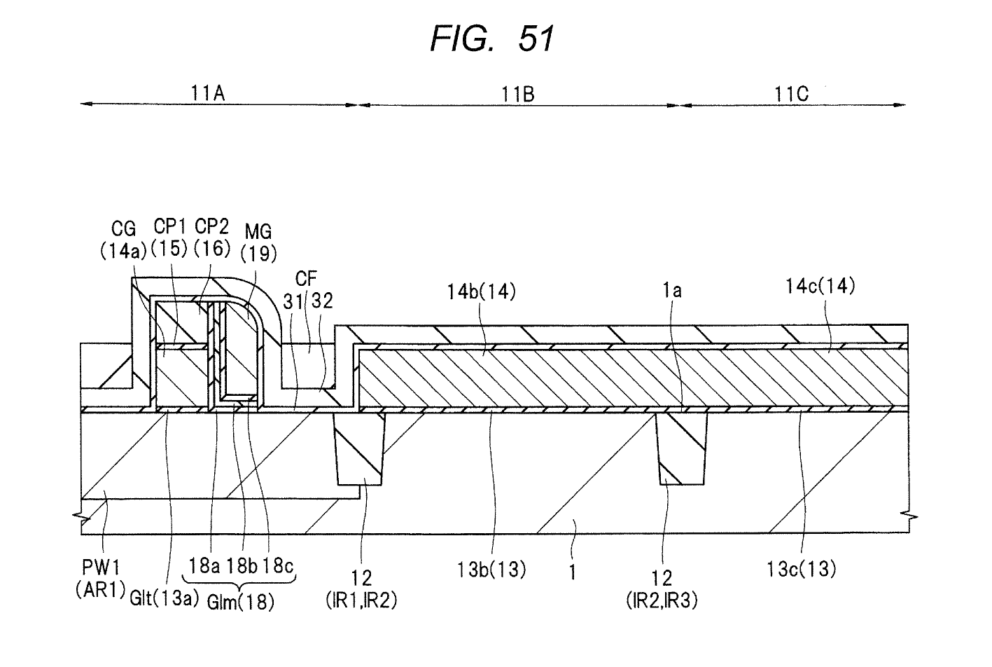

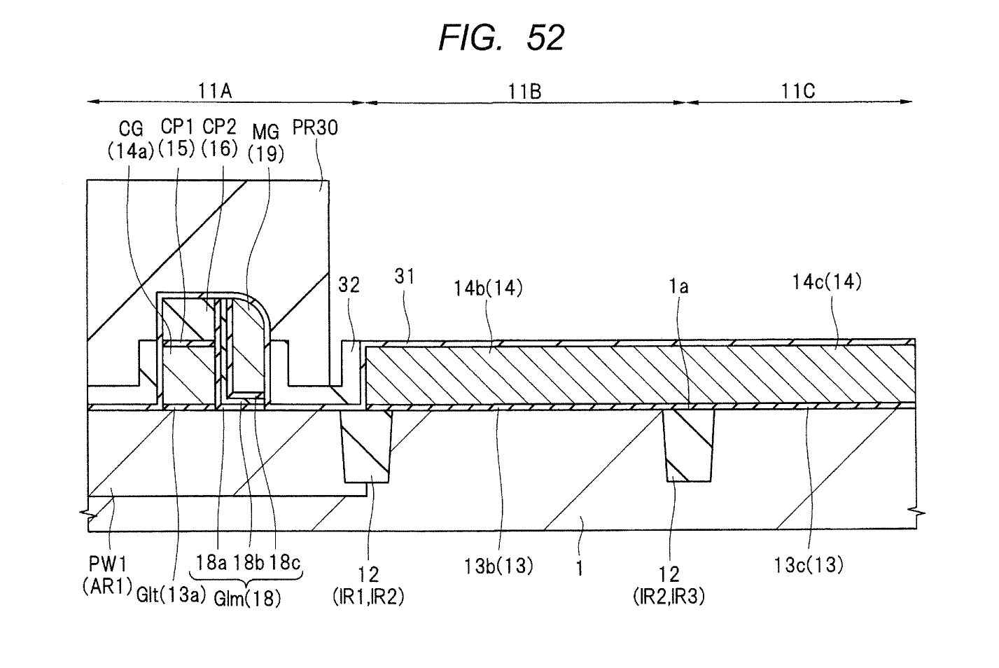

FIGS. 51 and 52 are main-portion cross-sectional views showing the manufacturing process of the semiconductor device in the present application example. As shown in FIG. 51, even though the insulating film 32 is exposed in the peripheral circuit regions 11B and 11C, the conductive film 14b and the like are subsequently removed using the resist film PR30 as a mask, as shown in FIG. 52. Accordingly, even though the insulating film 32 has been removed from the peripheral circuit regions 11B and 11C, there is no problem. However, since the insulating film 32 remains in an undesired shape over the side wall of the conductive film 14b, the coating film CF is more preferably formed so as to cover the insulating film 32 in the peripheral circuit regions 11B and 11C.

### Application Example 3

In Embodiment 2, the selective SMT described in Embodiment 1 may also be applied to each of the memory cell MC1 in the memory cell region 11A, the higher-breakdown-voltage MISFET QH in the peripheral circuit region 11B, and the lower-breakdown-voltage MISFET QL in the peripheral circuit region 11C.

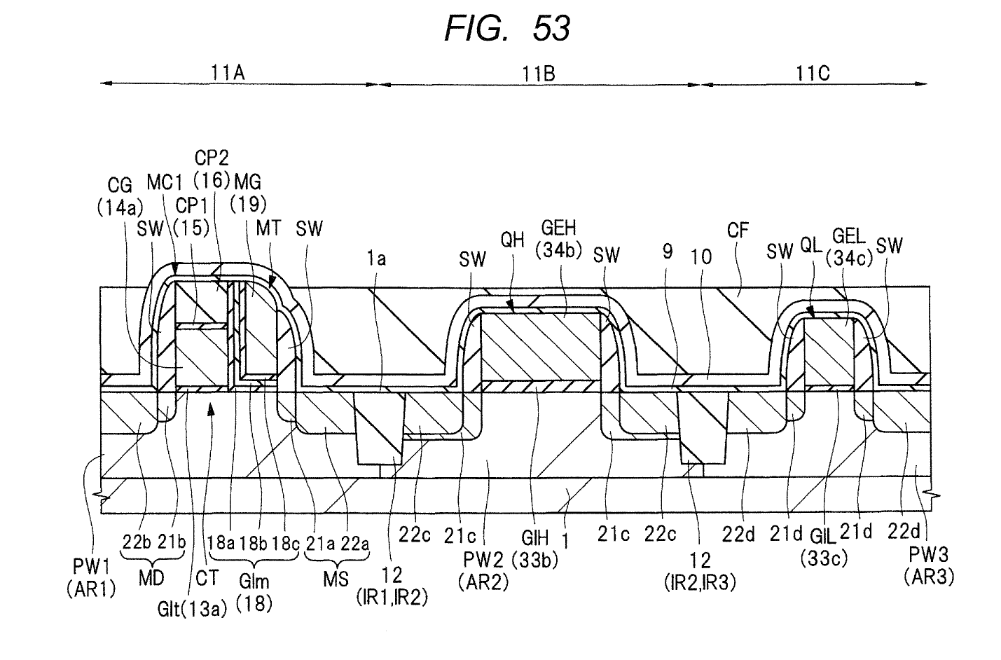

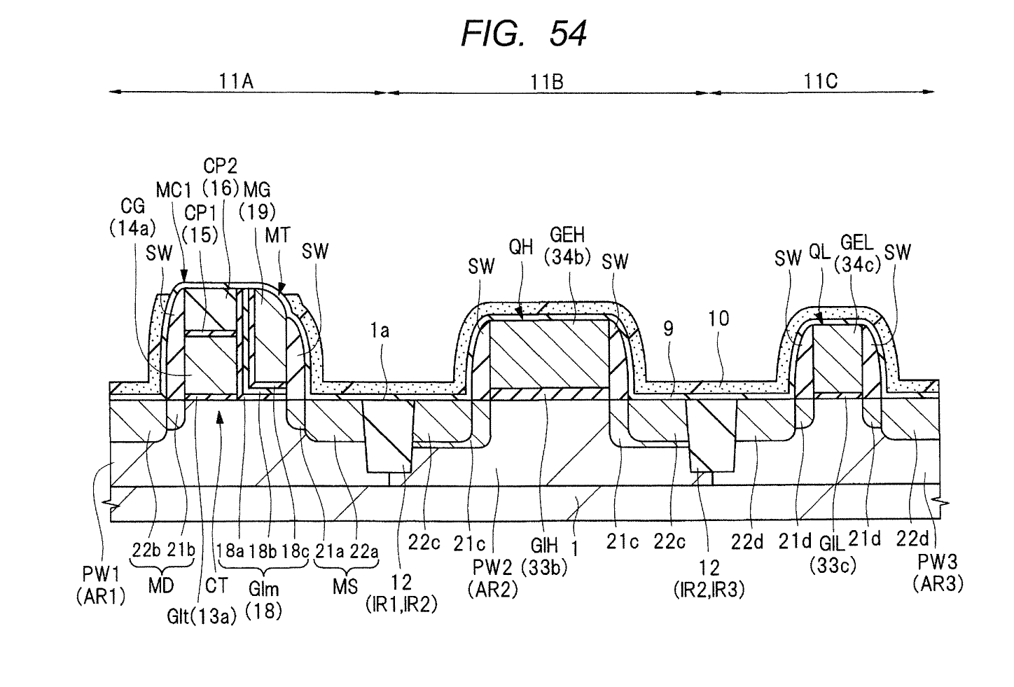

FIGS. 53 and 54 are main-portion cross-sectional views showing the manufacturing process of a semiconductor device in the present application example. As shown in FIG. 53, over the memory cell MC1, the higher-breakdown-voltage MISFET QH, and the lower-breakdown-voltage MISFET QL, in the same manner as in Embodiment 1, the stopper film 9 and the stress application film (silicon nitride film) 10 are formed in the same manner as in Embodiment 1. Then, in the same manner as in Embodiment 1, the coating film CF is formed. Using the coating film CF as a mask, the stress application film 10 is etched. Then, as shown in FIG. 54, heat treatment may also be performed to apply a stress to the higher-breakdown-voltage MISFET QH and the lower-breakdown-voltage MISFET QL. At this time, the stress application film 10 in the memory cell region 11A has been partially removed so that no stress is applied to the memory cell MC1.

Note that, in Embodiment 2, as has been described with reference to FIG. 49, over the memory cell MC1 in the memory cell region 11A, the higher-breakdown-voltage MISFET QH in the peripheral circuit region 11B, and the lower-breakdown-voltage MISFET QL in the peripheral circuit region 11C, the insulating film 24 made of a silicon nitride film has been formed by a CVD method. The silicon nitride film may also be removed from over the control gate electrode portion (laminated film portion including the control gate electrode CG and the cap insulating film). However, after the silicon nitride film is formed, heat treatment at a relatively high temperature (of, e.g., not less than 500° C.) is hardly performed. Therefore, the silicon nitride film covering the control gate electrode portion may also be left.

After the silicon nitride film covering the memory cells (MC and MC1) is thus formed, when heat treatment at a relatively high temperature (of, e.g., not less than 500° C.), or more effectively heat treatment at 1000° C. or higher is performed, the silicon nitride film is preferably partially removed, as described above in Embodiments 1 to 3.

### Application Example 4

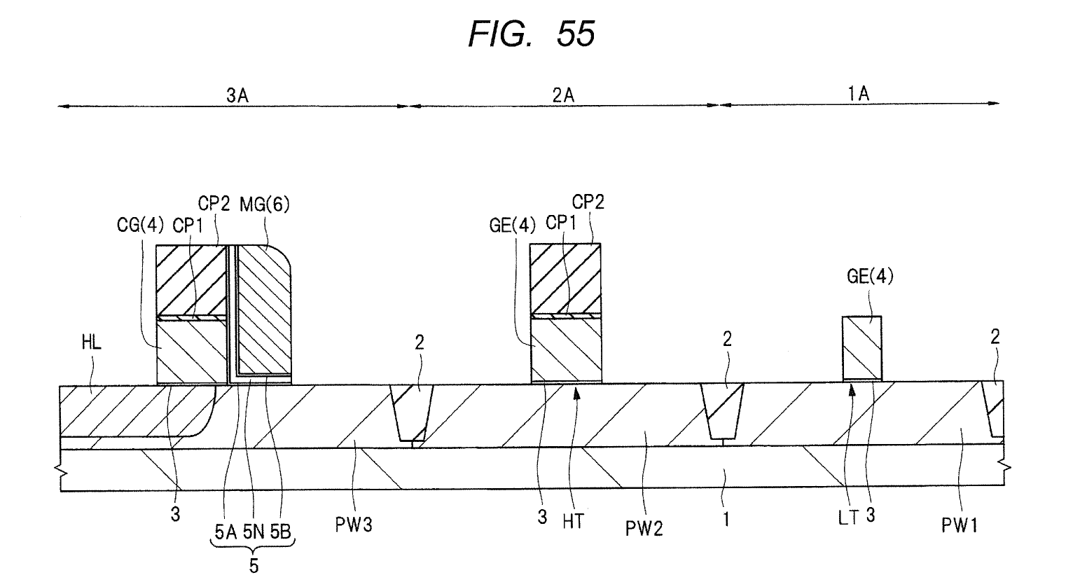

In Embodiment 1, the silicon nitride film CP2 and the silicon dioxide film CP1 have been removed from over the gate electrode GE of the MISFET (HT). However, the silicon nitride film CP2 and the silicon dioxide film CP1 may also be left over the gate electrode GE of the MISFET (HT). FIGS. 55 to 57 are main-portion cross-sectional views showing the manufacturing process of a semiconductor device in the present application example.

For example, in a state where the silicon nitride film CP2 and the silicon dioxide film CP1 are left over the silicon film 4 shown in FIG. 3, the subsequent process is performed. Then, as shown in FIG. 55, in the step of forming the gate electrode GE of the MISFET (HT), patterning is performed in a state where the silicon nitride film CP2, the silicon dioxide film CP1, and the silicon film 4 are stacked. Note that the silicon nitride film CP2 and the silicon dioxide film CP1 are removed from over the gate electrode GE of the MISFET (LT).

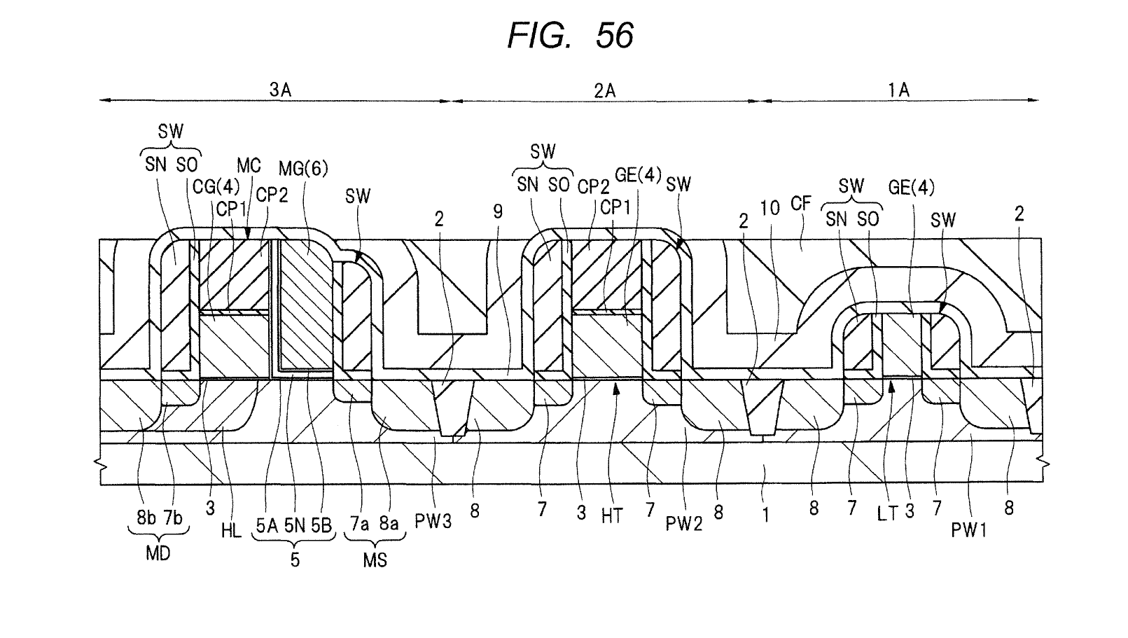

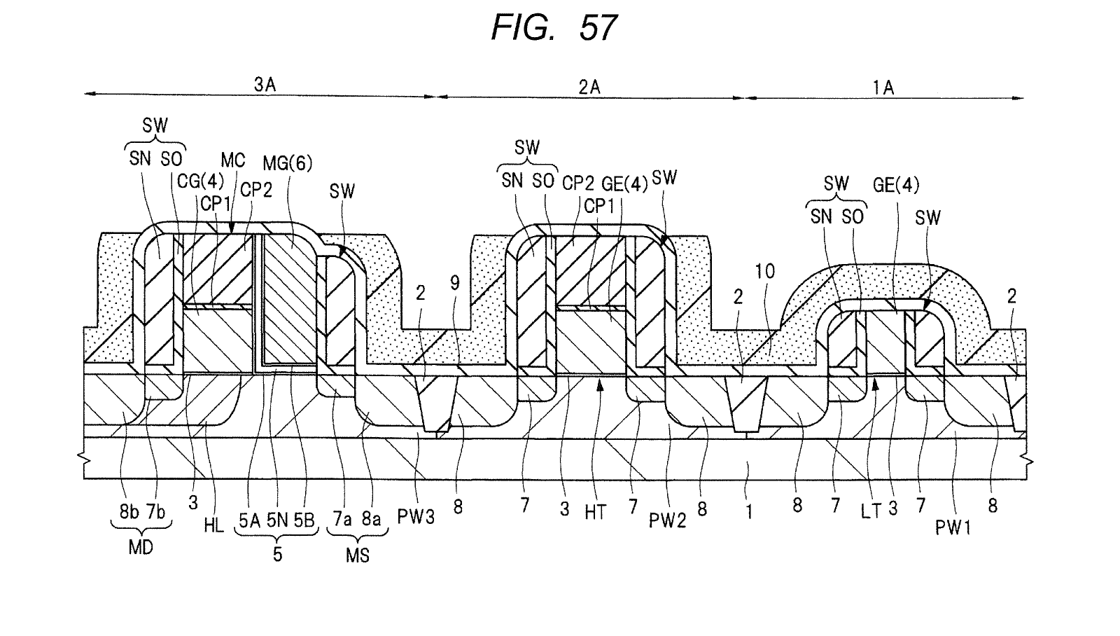

In this case, not only the control gate electrode portion (laminated film portion including the control gate electrode CG and the cap insulating film), but also the gate electrode portion (laminated film portion including the gate electrode GE and the cap insulating film) of the MISFET (HT) is higher (thicker) than the gate electrode GE of the MISFET (LT). Accordingly, when, as shown in FIG. 56, the stopper film 9 and the stress application film (silicon nitride film) 10 are formed over the MISFETs (LT) and (HT) and the memory cell MC and the stress application film 10 is etched using the coating film CF as a mask in the same manner as in the case in Embodiment 1, the stress application film 10 is removed from over the control gate electrode portion and the gate electrode portion of the MISFET (HT). In addition, as shown in FIG. 57, heat treatment is performed to apply a stress to the MISFET (LT) in the core MIS formation region 1A. At this time, since the stress application film 10 has been removed from over the control gate electrode portion and the gate electrode portion, no stress is applied to the memory cell MC and the MISFET (HT).

By thus increasing the height of the gate electrode portion of the MISFET (HT), it is possible to avoid the application of the SMT to the MISFET (HT).

Note that the height of the gate electrode portion has been increased herein by leaving the cap insulating film (the silicon nitride film CP2 and the silicon dioxide film CP1) over the gate electrode GE of the MISFET (HT). However, the height of the gate electrode portion of the MISFET (HT) may also be increased by increasing the film thickness of the gate electrode GE (the silicon film 4) without providing the cap insulating film. At this time, the control gate electrode portion may also be configured similarly to the gate electrode portion of the MISFET (HT). Such a configuration in which the height of the gate electrode portion of the MISFET (HT) is increased is also applicable to Embodiment 2.

While the invention achieved by the present inventors has been specifically described heretofore on the basis of the embodiments thereof, the present invention is not limited to the foregoing embodiments. It will be appreciated that various changes and modifications can be made in the invention within the scope not departing from the gist thereof. For example, the SMT process may also be performed after the silicide process.

What is claimed is:

1. A method of manufacturing a semiconductor device including a first MISFET disposed in a first region of a semiconductor substrate, and a nonvolatile memory cell disposed in a second region of the semiconductor substrate, the method comprising the steps of:
(a) providing the semiconductor substrate having a gate electrode included in the first MISFET and formed over the first region and having first and second gate electrodes and a first insulating film each included in the nonvolatile memory cell and formed over the second region, the first insulating film being formed with an internal charge storage portion;
(b) forming a silicon nitride film over the gate electrode and the first and second gate electrodes;
(c) removing the silicon nitride film from over the first and second gate electrodes to form an opening over the first and second gate electrodes; and
(d) after the step (c), in a state where the opening is formed in the silicon nitride film, heat treatment is performed.

2. The method of manufacturing the semiconductor device according to claim 1,
wherein the step (c) includes the steps of:
(c1) forming a coating film over the silicon nitride film; and
(c2) removing the silicon nitride film exposed from the coating film to form the opening.

3. The method of manufacturing the semiconductor device according to claim 2,
wherein the coating film is an antireflection film.

4. The method of manufacturing the semiconductor device according to claim 2,
wherein a bottom portion of the silicon nitride film over the first gate electrode is located at a position higher in level than that of a bottom portion of the silicon nitride film over the gate electrode, and
wherein the silicon nitride film over the gate electrode is covered with the coating film, while the silicon nitride film over the first gate electrode is exposed from the coating film.

5. The method of manufacturing the semiconductor device according to claim 4,
wherein, between the first gate electrode and the silicon nitride film, a second insulating film is disposed.

6. The method of manufacturing the semiconductor device according to claim 5,
wherein the second gate electrode is disposed over a side surface of a laminated film including the first gate electrode, and the second insulating film via the first insulating film, and
wherein the second gate electrode has a sidewall shape.

7. A method of manufacturing a semiconductor device including a first MISFET disposed in a first region of a semiconductor substrate, and a nonvolatile memory cell disposed in a second region of the semiconductor substrate, the method comprising the steps of:
(a) providing the semiconductor substrate having the first MISFET formed in the first region and having the nonvolatile memory cell formed in the second region;
(b) forming a silicon nitride film over the first MISFET and the nonvolatile memory cell;
(c) removing the silicon nitride film from over the nonvolatile memory cell to form an opening over the nonvolatile memory cell; and
(d) after the step (c), performing heat treatment to apply a stress to the first MISFET,
wherein the nonvolatile memory cell includes first and second gate electrodes, and a first insulating film formed with an internal charge storage portion.

8. The method of manufacturing the semiconductor device according to claim 7,
wherein the step (c) includes the steps of:
(c1) forming a coating film over the silicon nitride film; and
(c2) removing the silicon nitride film exposed from the coating film to form the opening.

9. The method of manufacturing the semiconductor device according to claim 8,
wherein the coating film is an antireflection film.

10. The method of manufacturing the semiconductor device according to claim 8,
wherein a bottom portion of the silicon nitride film over the first gate electrode is located at a position higher in level than that of a bottom portion of the silicon nitride film over a gate electrode of the first MISFET,
wherein the silicon nitride film over the gate electrode is covered with the coating film, and
wherein the silicon nitride film over the first gate electrode is exposed from the coating film.

11. The method of manufacturing the semiconductor device according to claim 10,
wherein, between the first gate electrode and the silicon nitride film, a second insulating film is disposed.

12. The method of manufacturing the semiconductor device according to claim 11,
wherein the second gate electrode is disposed over a side surface of a laminated film including the first gate electrode, and the second insulating film via the first insulating film, and
wherein the second gate electrode has a sidewall shape.

13. A method of manufacturing a semiconductor device including a first MISFET disposed in a first region of a semiconductor substrate, and a nonvolatile memory cell disposed in a second region of the semiconductor substrate, the method comprising the steps of:
(a) forming, over the second region of the semiconductor substrate, first and second gate electrodes included in the nonvolatile memory, and a first insulating film included in the nonvolatile memory and formed with an internal charge storage portion and forming, over the first region of the semiconductor substrate, a conductive film in the same layer as that of the first gate electrode;
(b) forming a silicon nitride film over the first and second gate electrodes and the conductive film;
(c) removing the silicon nitride film from over the first and second gate electrodes to form an opening over the first and second gate electrodes;
(d) removing the conductive film to form a first semiconductor region having a first conductivity type in the first region of the semiconductor substrate;
(e) after the step (c), in a state where the opening is formed in the silicon nitride film, performing heat treatment on the semiconductor substrate to form a gate insulating film of the first MISFET over the first semiconductor region; and
(f) forming, over the gate insulating film, a gate electrode of the first MISFET.

14. The method of manufacturing the semiconductor device according to claim 13, further comprising the step of:
before the step (a), forming a second semiconductor region having the first conductivity type in the second region of the semiconductor substrate.

15. The method of manufacturing the semiconductor device according to claim 14, further comprising the step of:
(g) after the step (f), forming source/drain regions of the first MISFET and source/drain regions of the nonvolatile memory cell.

16. The method of manufacturing the semiconductor device according to claim 13,
wherein the step (c) includes the steps of:
(c1) forming a coating film over the silicon nitride film; and
(c2) removing the silicon nitride film exposed from the coating film to form the opening.

17. The method of manufacturing the semiconductor device according to claim 16,
wherein the coating film is an antireflection film.

18. The method of manufacturing the semiconductor device according to claim 17,
wherein a bottom portion of the silicon nitride film over the first gate electrode is located at a position higher in level than that of a bottom portion of the silicon nitride film over the gate electrode,
wherein the silicon nitride film over the gate electrode is covered with the coating film, and
wherein the silicon nitride film over the first gate electrode is exposed from the coating film.

19. The method of manufacturing the semiconductor device according to claim 18,
wherein, between the first gate electrode and the silicon nitride film, a second insulating film is disposed.

20. The method of manufacturing the semiconductor device according to claim 19,
wherein the second gate electrode is disposed over a side surface of a laminated film including the first gate electrode, and the second insulating film via the first insulating film, and
wherein the second gate electrode has a sidewall shape.
